(19) United States
(12) Patent Application Publication
(10) Pub. No.: US 2013/0334518 A1
(43) Pub. Date: Dec. 19, 2013

(54) COMPOUND AND ORGANIC ELECTRICAL ELEMENT USING SAME, AND ELECTRONIC DEVICE AND HEAT-RESISTANCE MEASURING METHOD THEREWITH

(71) Applicants: Yongwook Park, Anyang-si (KR); Bumsung Lee, Cheonan-si (KR); Soungyun Mun, Yongin-si (KR); Junghwan Park, Seoul (KR); Jungcheol Park, Seongnam-si (KR); Kiwon Kim, Suwon-si (KR); Jeongkeun Park, Seongnam-si (KR); Hwasoon Jung, Chuncheon-si (KR); Heesun Ji, Seongnam-si (KR)

(72) Inventors: Yongwook Park, Anyang-si (KR); Bumsung Lee, Cheonan-si (KR); Soungyun Mun, Yongin-si (KR); Junghwan Park, Seoul (KR); Jungcheol Park, Seongnam-si (KR); Kiwon Kim, Suwon-si (KR); Jeongkeun Park, Seongnam-si (KR); Hwasoon Jung, Chuncheon-si (KR); Heesun Ji, Seongnam-si (KR)

(73) Assignee: DUKSAN HIGH METAL CO., LTD., Ulsan (KR)

(21) Appl. No.: 13/982,333

(22) PCT Filed: Feb. 2, 2012
(86) PCT No.: PCT/KR2012/000808

§ 371 Date: Jul. 29, 2013

(30) Foreign Application Priority Data
Feb. 16, 2011 (KR) 10-2011-0013876

(51) Int. Cl. H01L 51/00

(52) U.S. Cl. CPC H01L 51/006
USPC 257/40; 564/427

(57) ABSTRACT

The present invention provides a diphenyl diamine derivative which is a combination of a nitrogen-containing diphenyl fluorenyl group and a spiro fluorenyl group; an organic electroluminescent device using the same; and a display apparatus which uses the organic electroluminescent device.

### TECHNICAL FIELD

The present invention relates to a compound, an organic electronic element using the same, an electronic device thereof, and a heat resistance measuring method.

### BACKGROUND ART

A flat panel display element performs a very important role of supporting an advanced image information society that has recently quickly grown. Especially, an organic electronic element that can be operated at a low voltage in a self-emission manner is excellent in a viewing angle and a contrast ratio, compared to liquid crystal display device (the most widely used flat panel display device). Also, the organic electronic element does not require a backlight, and thus can be manufactured in such a manner that it can have a light weight and a thin thickness. Also, it is advantageous in view of power consumption. Furthermore, it has been spotlighted as a next generation display device due to a high response speed, and a wide color reproduction range.

In general, an organic electronic element has an anode, an organic thin film including a light emitting area, and a cathode which are sequentially formed on a glass substrate. Herein, the organic thin film may include not only a light emitting layer (EML) but also a hole injection layer (HIL), a hole transport layer (HTL), an electron transport layer (ETL) or an electron injection layer (EIL). For light emission of a light emitting layer, it may further include an electron blocking layer (EBL) or a hole blocking layer (HBL).

When the organic electronic element with such a structure is applied with an electric field, holes are injected from the anode, and electrons are injected from the cathode. The injected holes and electrons are transferred from the hole transport layer and the electron transport layer, respectively, and recombined in the light emitting layer so as to form light emitting exitons.

The formed light emitting exitons are transited to ground states while emitting light. Herein, in order to increase the efficiency and stability of a light emission state, a light emitting pigment (guest) may be doped in the light emitting layer (host).

In order to utilize such an organic electronic element in various displays, life span of a device is most important. At present, much research on improvement of the life span of an organic electronic element has been conducted.

### DISCLOSURE OF INVENTION

### Technical Problem

An object of the present invention to improve electrical stability, luminous efficiency, device life span, and manufacturing efficiency of an organic electronic element.

The present invention has been made to provide a material for hole injection/transport layers, and an organic electronic element including the same, in which the material requires a low operating voltage, and has a high heat resistance and a long life span.

### Solution to Problem

In accordance with an aspect of the present invention, there is provided a compound that is represented by any one of Formulas below or includes two or more of at least one of Formulas below.

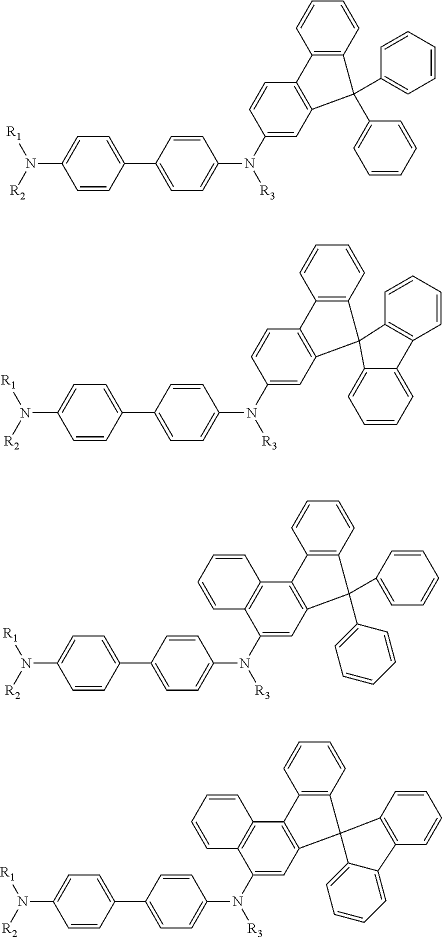

In accordance with another aspect of the present invention, there is provided an organic electrical device and an electronic device thereof, in which the organic electrical device includes an organic material layer including the compound.

### Advantageous Effects

According to the present invention, it is possible to improve electrical stability, luminous efficiency, device life span and manufacturing efficiency of an organic electronic element.

The present invention provides a material for hole injection/transport layers, an organic electronic element including the same, and an electronic device thereof in which the material requires a low operating voltage, and has a high heat resistance and a long life span.

### BRIEF DESCRIPTION OF DRAWINGS

FIGS. 1 to 6 show examples of an organic electro-luminescence element which can employ a compound according to the present invention.

### MODE FOR INVENTION

Hereinafter, exemplary embodiments of the present invention will be described with reference to the accompanying drawings. In the following description, the same elements will be designated by the same reference numerals although they are shown in different drawings. Further, in the following description of the present invention, a detailed description of known functions and configurations incorporated herein will be omitted when it may make the subject matter of the present invention rather unclear.

In addition, terms, such as first, second, A, B, (a), (b) or the like may be used herein when describing components of the present invention. Each of these terminologies is not used to define an essence, order or sequence of a corresponding component but used merely to distinguish the corresponding component from other component(s). It should be noted that if it is described in the specification that one component is “connected,” “coupled” or “joined” to another component, a third component may be “connected,” “coupled,” and “joined” between the first and second components, although the first component may be directly connected, coupled or joined to the second component.

The present invention relates to a material for hole injection/transport layers, an organic light emitting element including the same, and an electronic device thereof in which the material requires a low operating voltage.

A flat panel display element performs a very important role of supporting an advanced image information society that has recently quickly grown mainly in the internet field. Especially, an organic electro-luminescence element (organic EL element) that can be operated at a low voltage in a self-emission manner is excellent in a viewing angle and a contrast ratio, compared to a liquid crystal display (LCD) (the most widely used flat panel display element). Also, the organic electro-luminescence element does not require a backlight, and thus can be manufactured in such a manner that it can have a light weight and a thin thickness. Also, it is advantageous in view of power consumption. Furthermore, it has been spotlighted as a next generation display device due to a high response speed, and a wide color reproduction range.

In general, an organic electro-luminescence element has an anode including a transparent electrode, an organic thin film including a light emitting area, and a metal electrode (cathode) which are sequentially formed on a glass substrate. Herein, the organic thin film may include not only a light emitting layer (EML) but also a hole injection layer (HIL), a hole transport layer (HTL), an electron transport layer (ETL) or an electron injection layer (EIL). For light emission of a light emitting layer, it may further include an electron blocking layer (EBL) or a hole blocking layer (HBL).

When the organic electro-luminescence element with such a structure is applied with an electric field, holes are injected from the anode, and electrons are injected from the cathode. The injected holes and electrons are transferred from the hole transport layer and the electron transport layer, respectively, and recombined in the light emitting layer so as to form light emitting exitons.

The formed light emitting exitons are transited to ground states while emitting light. Herein, in order to increase the efficiency and stability of a light emission state, a light emitting pigment (guest) may be doped in the light emitting layer (host).

In order to utilize such an organic light emitting element in various displays, the life span of a device is most important. At present, much research on improvement of the life span of an organic light emitting element has been conducted. Especially, in order to achieve a long life span of an organic electro-luminescence element, much research on an organic material to be inserted into a hole transport layer or a buffer layer has been conducted. For this, it is required to develop a hole injection layer material capable of improving the hole mobility from the anode to the organic layer, which has high uniformity and low crystallinity during formation of a thin film after its deposition.

Also, it is required to develop a hole injection layer material that can delay penetration/diffusion of metal oxide from an anode electrode (ITO) to an organic layer (one cause of life span reduction of an organic light emitting element), and has a stable property against Joule heating caused by device operation, that is, a high glass transition temperature.

Also, it has been reported that a low glass transition temperature of a hole transport layer material has a high effect on a device's life span according to deterioration of uniformity of a thin film surface during operation. Also, in the formation of an OLED device, a deposition method is mainly used. Thus, it is required to develop a highly heat-resistant material that can stand for a long time in such a deposition method.

Especially, in a currently used organic light emitting element, in order to improve the manufacturing efficiency, two material requirements are important. First, a material for both a hole injection layer and a hole transport layer can be used to simplify a device structure and to improve the manufacturing efficiency. Such a structure has to have a high hole mobility according to the increase in the layered thickness, and also requires a high deposition speed, that is, a high heat resistance, so as to improve the manufacturing efficiency of manufacturing time.

It is known that a material having a high hole mobility may have a tertiary amine including fluorene in the molecular structure. In the fluorene, two phenyl groups are cyclized while phenyl groups are positioned on a molecular structural plane. In other words, the fluorene has a structure in which electron delocalization can be easily induced, and thus shows a hole mobility.

Meanwhile, the fluorene structure has a serious problem in thermostability, and the reason is described in the mechanism below.

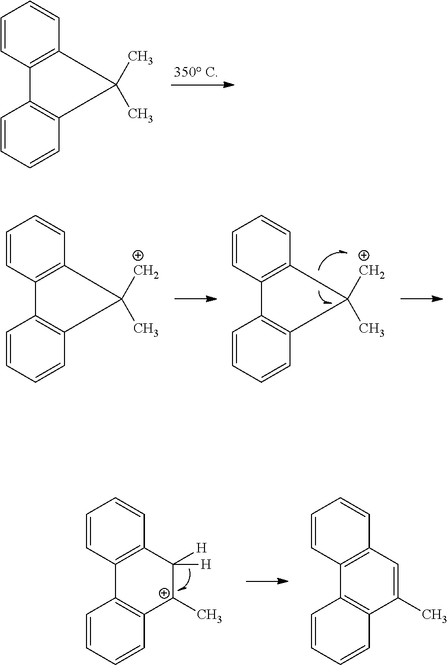

As described above, at high temperature, in a methyl group adjacent to a fluorene linking group, dehydrogenation occurs and a cation is formed. Then, due to the characteristic of becoming a more thermodynamically stable hexagonal aromatic ring, the fluorene structure is deformed. In order to complement this characteristic, the present invention provides a thermostability test method by using various fluorene derivatives noted in Table below.

According to an embodiment of the present invention, a heat resistance measuring (or test) method is used to test thermostability. The method includes the steps of: measuring an initial purity of a compound or a derivative; leaving the compound or the derivative at a reference temperature or more for a reference time or more; measuring a purity of the compound or the derivative; and measuring the difference (decrease) from a specific peak area observed after measurement of the initial purity, to the specific peak area observed after measurement of the purity.

Specifically, according to an embodiment of the present invention, a heat resistance measuring (or test) method is used to test thermostability. The method includes the steps of: measuring an initial purity of a fluorene derivative by HPLC (High Performance Liquid Chromatography); leaving the fluorene derivative at a reference temperature or more for a reference time or more; measuring a purity of the fluorene derivative by HPLC; and measuring the difference (decrease) from a specific peak area observed after measurement of the initial purity, to the specific peak area observed after measurement of the purity.

Herein, the derivative may be left at 350° C. for 12 hours.

Specifically, on each of compounds F-1 to F-7, an initial purity was measured by HPLC. Then, it was left at the same temperature (350° C.) for 12 hours, and subjected to HPLC measurement. Then, a decrease of a specific peak area observed after initial purity measurement was measured.

According to an embodiment of the present invention, the thermostability measuring (or test) method may be applied to not only the above described fluorene compound, but also compounds as described with reference to Formulas 1 to 4 and Tables 1 to 4, and other compounds unrepresented in this specification.

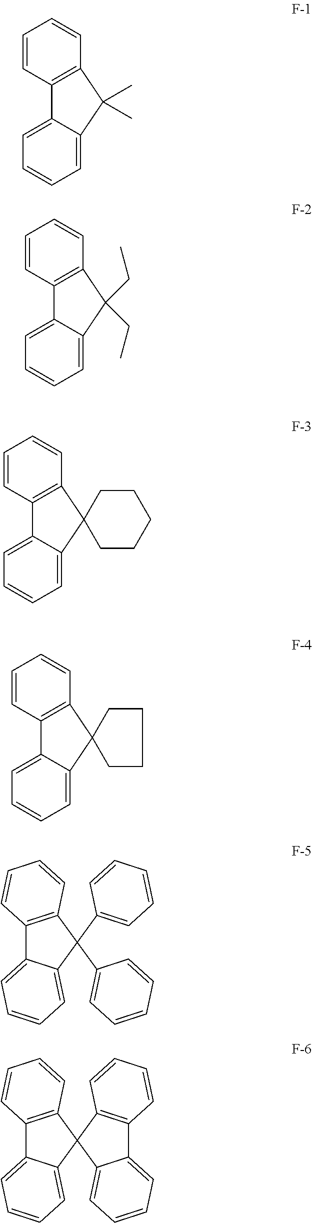

| Sample | F-1 | F-2 | F-3 | F-4 | F-6 | F-7 |
|---|---|---|---|---|---|---|
| Initial purity | 99.95% | 99.94% | 99.96% | 99.89% | 99.93% | 99.95% |
| Temperature | 350° C. | 350° C. | 350° C. | 350° C. | 350° C. | 350° C. |
| Time | 12.0 hr | 12.0 hr | 12.0 hr | 12.0 hr | 12.0 hr | 12.0 hr |
| Subsequent | 75.75% | 64.25% | 67.85% | 63.23% | 98.15% | 95.15% |
| purity | | | | | | |
| Deformation | 24.20% | 35.69% | 32.11% | 36.66% | 1.78% | 4.80% |
| ratio | | | | | | |

Such a heat resistance measuring method was used to measure F-1 to F-6. As a result, when there was hydrogen at a position adjacent to a fluorene linking group (F-1 to F4), purity decrease was significant. Especially, in F-2, F-3, and F-4, purity decrease was more significant, because hydrogen adjacent to a linking group is included in secondary carbon and thus a cation can be easily generated.

The inventive compound is an arylamine compound including a fluorene derivative, which has a subsequent purity of 90% or more in a thermostability test, and may be an arylamine compound with a deformation ratio of less than 9%.

Accordingly, in order to increase the hole mobility, fluorene may have a structure of F-6 and F-7, in which there is no hydrogen in the carbon adjacent to a linking group. This characteristic was employed in a biphenyldiamine-type structure having a relatively high hole mobility so as to develop a hole transport layer material with a high hole mobility.

Especially, recently, Korean Patent No. 10-2010-0106626 discloses asymmetric diphenyl diamine. However, it was found that from among asymmetric structures disclosed in the patent, all of exemplified fluorene structures showed a low heat resistance in the test result of a heat resistance test method according to an embodiment of the present invention. Thus, in actuality, it is difficult to use the compound in the manufacturing of an organic electro-luminescence element. Especially, it was found that the application of the compound is more difficult in view of a recently required condition (manufacturing efficiency, that is, high heat resistance).

Accordingly, the inventors of the present invention invented a compound with a structure of Formulas 1 to 4, such as F-6 to F-7, in which there is no hydrogen in carbon adjacent to a linking group of a fluorene cycle, wherein the compound has a biphenyl diamine structure for securing a high hole mobility, and a high heat resistance structure based on a heat resistance test method according to an embodiment of the present invention.

Then, an organic electro-luminescence element was manufactured. Through measurement, it was found that it has a high hole mobility, a high heat resistance, and a long life span and requires a low operating voltage.

The present invention provides a compound that is represented by any one of Formulas 1 to 4 or includes two or more of at least one of Formulas 1 to 4 below.

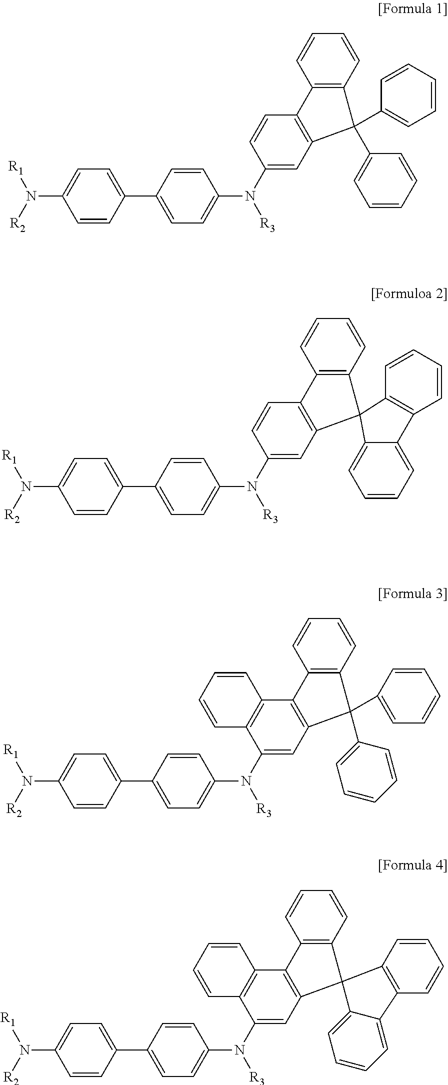

In Formulas, R₁, R₂, and R₃ each are independently
a C₆˜C₂₀ aryl group substituted or unsubstituted with at least one group selected from the group including hydrogen, halogen, an amino group, a nitrile group, a nitro group, a C₁˜C₂₀ alkyl group, a C₁˜C₂₀ alkoxy group, a C₁˜C₂₀ alkylamine group, a C₁˜C₂₀ alkylthiophene group, a C₆˜C₂₀ arylthiophene group, a C₂˜C₂₀ alkenyl group, a C₂˜C₂₀ alkynyl group, a C₃˜C₂₀ cycloalkyl group, a C₆˜C₂₀ aryl group substituted with deuterium, a C₆˜C₂₀ aryl group, a C₈˜C₂₀ arylalkenyl group, a silane group, a boron group, a germanium group, and a C₅˜C₂₀ heterocyclic group; and
a C₆˜C₂₀ aryl thiophene group substituted or unsubstituted with at least one group selected from the group including hydrogen, halogen, an amino group, a nitrile group, a nitro group, a C₁˜C₂₀ alkyl group, a C₁˜C₂₀ alkoxy group, a C₁˜C₂₀ alkylamine group, a C₁˜C₂₀ alkylthiophene group, a C₆˜C₂₀ aryl thiophene group, a C₂˜C₂₀ alkenyl group, a C₂˜C₂₀ alkynyl group, a C₃˜C₂₀ cycloalkyl group, a C₆˜C₂₀ aryl group substituted with deuterium, a C₆˜C₂₀ aryl group, a C₈˜C₂₀ arylalkenyl group, a silane group, a boron group, a germanium group, and a C₅˜C₂₀ heterocyclic group.

In Formulas 1 to 4, the substitutes, although not mentioned above, may be substituted or unsubstituted again. In other words, the substitutes may be substituted with other substituents or other substitutes again.

Herein, in R₁ and R₂, adjacent substituents are combined with each other to form a substituted or unsubstituted saturated or unsaturated cycle (or ring), for example, an aliphatic, aromatic, or heteroaromatic cyclic or polycyclic ring.

From among Formula 1, Formula 2, Formula 3, and Formula 4, same Formulas or different Formulas may be combined to include two or more Formula structures. Herein, two or more Formula structures indicate that compounds having the structure of the Formula are directly linked to each other without a linking group. In this case, from among Formula 1, Formula 2, Formula 3, and Formula 4, same or different Formulas are directly linked to each other so as to include two or more Formula structures.

According to another embodiment of the present invention, two or more Formula structures indicate that the compound includes at least one selected from the group including alkane having a bivalent or multivalent linking group, cycloalkane having a bivalent or multivalent linking group; an aryl compound having bivalent or multivalent linking group; and nitrogen, sulfur, oxygen atoms, and also indicate that two or more of the structure of Formula 1 can be linked to a pentagonal or hexagonal heteroaryl compound having a bivalent or multivalent linking group; an oxygen atom, a sulfur atom, a substituted or unsubstituted nitrogen atom, or a substituted or unsubstituted phosphorous atom. In this case, from among Formula 1, Formula 2, Formula 3, and Formula 4, same or different Formulas can be linked to each other so as to include two or more Formula structures.

In Formulas 1 to 4, a heterocyclic group includes as a heteroatom, O, N or S. The number of carbon atoms is not particularly limited, but is preferably in a range of 2-60. Examples of the heterocyclic group may include a thiophene group, a furan group, a pyrrole group, an imidazole group, a thiazole group, an oxazole group, an oxadiazole group, a triazole group, a pyridyl group, a bipyridyl group, a triazine group, an acridine group, a pyridazine group, a quinolinyl group, an isoquinoline group, an indole group, a carbazole group, a benzoxazole group, a benzimidazole group, a benzthiazole group, a benzcarbazole group, a benzthiophene group, a dibenzothiophene group, a benzfuranyl group, a dibenzofuranyl group, and the like, but, the present invention is not limited thereto.

Meanwhile, the compound having the structure may be used in a soluble process. In other words, through a soluble process of the compound, an organic material layer of an organic electronic element can be formed. In other words, when the compound is used as an organic material layer, the organic material layer may be manufactured with a smaller number of layers by using various polymer materials by means of a soluble process or a solvent process (e.g., spin coating, dip coating, doctor blading, screen printing, inkjet printing or thermal transfer) instead of deposition.

Herein, R₁, R₂, and R₃ each may be independently at least one selected from groups below, but, the present invention is not limited thereto.

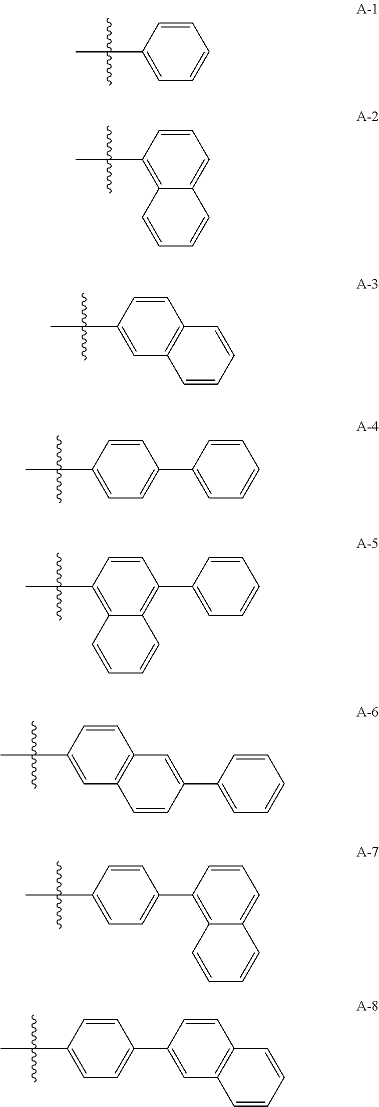

Herein, specifically, the compound represented by Formula 1 may be represented by any one of compounds noted in Table 1 below, but, the present invention is not limited thereto. For example, in Table 1, compound 1-1-1-1 may have A-1 (phenyl groups) as R₁, R₂, and R₃, compound 1-1-1-2 may have A-1 (phenyl groups) as R₁, and R₂, A-2 (naphthyl group) as R₃ and compound I-2-4-8 may have A-2 as R₁, A-4 as R₂, and A-8 as R₃. In these compounds, R₁, R₂, and R₃ each, as described above, may be independently substituted with at least one selected from the group including hydrogen, halogen, an amino group, a nitrile group, a nitro group, a C₁˜C₂₀ alkyl group, a C₁˜C₂₀ alkoxy group, a C₁˜C₂₀ alkylamine group, a C₁˜C₂₀ alkylthiophene group, a C₆˜C₂₀ aryl thiophene group, a C₂˜C₂₀ alkenyl group, a C₂˜C₂₀ alkynyl group, a C₃˜C₂₀ cycloalkyl group, a C₆˜C₂₀ aryl group substituted with deuterium, a C₆˜C₂₀ aryl group, a C₈˜C₂₀ arylalkenyl group, a silane group, a boron group, a germanium group, and a C₅˜C₂₀ heterocyclic group.

TABLE 1

| compound | Formula | R1 | R2 | R3 |
|---|---|---|---|---|
| 1-1-1-1 | Formula 1 | A-1 | A-1 | A-1 |
| 1-1-1-2 | Formula 1 | A-1 | A-1 | A-2 |
| 1-1-1-3 | Formula 1 | A-1 | A-1 | A-3 |
| 1-1-1-4 | Formula 1 | A-1 | A-1 | A-4 |
| 1-1-1-5 | Formula 1 | A-1 | A-1 | A-5 |
| 1-1-1-6 | Formula 1 | A-1 | A-1 | A-6 |
| 1-1-1-7 | Formula 1 | A-1 | A-1 | A-7 |
| 1-1-1-8 | Formula 1 | A-1 | A-1 | A-8 |
| 1-1-2-1 | Formula 1 | A-1 | A-2 | A-1 |
| 1-1-2-2 | Formula 1 | A-1 | A-2 | A-2 |
| 1-1-2-3 | Formula 1 | A-1 | A-2 | A-3 |
| 1-1-2-4 | Formula 1 | A-1 | A-2 | A-4 |
| 1-1-2-5 | Formula 1 | A-1 | A-2 | A-5 |
| 1-1-2-6 | Formula 1 | A-1 | A-2 | A-6 |
| 1-1-2-7 | Formula 1 | A-1 | A-2 | A-7 |
| 1-1-2-8 | Formula 1 | A-1 | A-2 | A-8 |
| 1-1-3-1 | Formula 1 | A-1 | A-3 | A-1 |
| 1-1-3-2 | Formula 1 | A-1 | A-3 | A-2 |
| 1-1-3-3 | Formula 1 | A-1 | A-3 | A-3 |
| 1-1-3-4 | Formula 1 | A-1 | A-3 | A-4 |
| 1-1-3-5 | Formula 1 | A-1 | A-3 | A-5 |
| 1-1-3-6 | Formula 1 | A-1 | A-3 | A-6 |
| 1-1-3-7 | Formula 1 | A-1 | A-3 | A-7 |
| 1-1-3-8 | Formula 1 | A-1 | A-3 | A-8 |
| 1-1-4-1 | Formula 1 | A-1 | A-4 | A-1 |
| 1-1-4-2 | Formula 1 | A-1 | A-4 | A-2 |
| 1-1-4-3 | Formula 1 | A-1 | A-4 | A-3 |
| 1-1-4-4 | Formula 1 | A-1 | A-4 | A-4 |
| 1-1-4-5 | Formula 1 | A-1 | A-4 | A-5 |
| 1-1-4-6 | Formula 1 | A-1 | A-4 | A-6 |
| 1-1-4-7 | Formula 1 | A-1 | A-4 | A-7 |
| 1-1-4-8 | Formula 1 | A-1 | A-4 | A-8 |
| 1-2-2-1 | Formula 1 | A-2 | A-2 | A-1 |
| 1-2-2-2 | Formula 1 | A-2 | A-2 | A-2 |
| 1-2-2-3 | Formula 1 | A-2 | A-2 | A-3 |
| 1-2-2-4 | Formula 1 | A-2 | A-2 | A-4 |
| 1-2-2-5 | Formula 1 | A-2 | A-2 | A-5 |
| 1-2-2-6 | Formula 1 | A-2 | A-2 | A-6 |
| 1-2-2-7 | Formula 1 | A-2 | A-2 | A-7 |
| 1-2-2-8 | Formula 1 | A-2 | A-2 | A-8 |
| 1-2-3-1 | Formula 1 | A-2 | A-3 | A-1 |
| 1-2-3-2 | Formula 1 | A-2 | A-3 | A-2 |
| 1-2-3-3 | Formula 1 | A-2 | A-3 | A-3 |
| 1-2-3-4 | Formula 1 | A-2 | A-3 | A-4 |
| 1-2-3-5 | Formula 1 | A-2 | A-3 | A-5 |
| 1-2-3-6 | Formula 1 | A-2 | A-3 | A-6 |
| 1-2-3-7 | Formula 1 | A-2 | A-3 | A-7 |
| 1-2-3-8 | Formula 1 | A-2 | A-3 | A-8 |
| 1-2-4-1 | Formula 1 | A-2 | A-4 | A-1 |
| 1-2-4-2 | Formula 1 | A-2 | A-4 | A-2 |
| 1-2-4-3 | Formula 1 | A-2 | A-4 | A-3 |
| 1-2-4-4 | Formula 1 | A-2 | A-4 | A-4 |
| 1-2-4-5 | Formula 1 | A-2 | A-4 | A-5 |
| 1-2-4-6 | Formula 1 | A-2 | A-4 | A-6 |
| 1-2-4-7 | Formula 1 | A-2 | A-4 | A-7 |
| 1-2-4-8 | Formula 1 | A-2 | A-4 | A-8 |
| 1-3-3-1 | Formula 1 | A-3 | A-3 | A-1 |
| 1-3-3-2 | Formula 1 | A-3 | A-3 | A-2 |
| 1-3-3-3 | Formula 1 | A-3 | A-3 | A-3 |
| 1-3-3-4 | Formula 1 | A-3 | A-3 | A-4 |
| 1-3-3-5 | Formula 1 | A-3 | A-3 | A-5 |
| 1-3-3-6 | Formula 1 | A-3 | A-3 | A-6 |
| 1-3-3-7 | Formula 1 | A-3 | A-3 | A-7 |
| 1-3-3-8 | Formula 1 | A-3 | A-3 | A-8 |
| 1-3-4-1 | Formula 1 | A-3 | A-4 | A-1 |
| 1-3-4-2 | Formula 1 | A-3 | A-4 | A-2 |
| 1-3-4-3 | Formula 1 | A-3 | A-4 | A-3 |
| 1-3-4-4 | Formula 1 | A-3 | A-4 | A-4 |
| 1-3-4-5 | Formula 1 | A-3 | A-4 | A-5 |
| 1-3-4-6 | Formula 1 | A-3 | A-4 | A-6 |
| 1-3-4-7 | Formula 1 | A-3 | A-4 | A-7 |
| 1-3-4-8 | Formula 1 | A-3 | A-4 | A-8 |
| 1-4-4-1 | Formula 1 | A-4 | A-4 | A-1 |
| 1-4-4-2 | Formula 1 | A-4 | A-4 | A-2 |
| 1-4-4-3 | Formula 1 | A-4 | A-4 | A-3 |
| 1-4-4-4 | Formula 1 | A-4 | A-4 | A-4 |
| 1-4-4-5 | Formula 1 | A-4 | A-4 | A-5 |
| 1-4-4-6 | Formula 1 | A-4 | A-4 | A-6 |
| 1-4-4-7 | Formula 1 | A-4 | A-4 | A-7 |
| 1-4-4-8 | Formula 1 | A-4 | A-4 | A-8 |

Specifically, the compound represented by Formula 2 may be represented by any one of compounds noted in Table 2 below, but, the present invention is not limited thereto.

In these compounds, R₁, R₂, and R₃ each, as described above, may be independently substituted with at least one selected from the group including hydrogen, halogen, an amino group, a nitrile group, a nitro group, a C₁˜C₂₀ alkyl group, a C₁˜C₂₀ alkoxy group, a C₁˜C₂₀ alkylamine group, a C₁˜C₂₀ alkylthiophene group, a C₆˜C₂₀ aryl thiophene group, a C₂˜C₂₀ alkenyl group, a C₂˜C₂₀ alkynyl group, a C₃˜C₂₀ cycloalkyl group, a C₆˜C₂₀ aryl group substituted with deuterium, a C₆˜C₂₀ aryl group, a C₈˜C₂₀ arylalkenyl group, a silane group, a boron group, a germanium group, and a C₅˜C₂₀ heterocyclic group.

TABLE 2

| Compound | Formula | R1 | R2 | R3 |
|---|---|---|---|---|
| 2-1-1-1 | Formula 2 | A-1 | A-1 | A-1 |
| 2-1-1-2 | Formula 2 | A-1 | A-1 | A-2 |
| 2-1-1-3 | Formula 2 | A-1 | A-1 | A-3 |
| 2-1-1-4 | Formula 2 | A-1 | A-1 | A-4 |
| 2-1-1-5 | Formula 2 | A-1 | A-1 | A-5 |
| 2-1-1-6 | Formula 2 | A-1 | A-1 | A-6 |
| 2-1-1-7 | Formula 2 | A-1 | A-1 | A-7 |
| 2-1-1-8 | Formula 2 | A-1 | A-1 | A-8 |
| 2-1-2-1 | Formula 2 | A-1 | A-2 | A-1 |
| 2-1-2-2 | Formula 2 | A-1 | A-2 | A-2 |
| 2-1-2-3 | Formula 2 | A-1 | A-2 | A-3 |
| 2-1-2-4 | Formula 2 | A-1 | A-2 | A-4 |
| 2-1-2-5 | Formula 2 | A-1 | A-2 | A-5 |
| 2-1-2-6 | Formula 2 | A-1 | A-2 | A-6 |
| 2-1-2-7 | Formula 2 | A-1 | A-2 | A-7 |
| 2-1-2-8 | Formula 2 | A-1 | A-2 | A-8 |
| 2-1-3-1 | Formula 2 | A-1 | A-3 | A-1 |
| 2-1-3-2 | Formula 2 | A-1 | A-3 | A-2 |
| 2-1-3-3 | Formula 2 | A-1 | A-3 | A-3 |
| 2-1-3-4 | Formula 2 | A-1 | A-3 | A-4 |
| 2-1-3-5 | Formula 2 | A-1 | A-3 | A-5 |
| 2-1-3-6 | Formula 2 | A-1 | A-3 | A-6 |
| 2-1-3-7 | Formula 2 | A-1 | A-3 | A-7 |
| 2-1-3-8 | Formula 2 | A-1 | A-3 | A-8 |
| 2-1-4-1 | Formula 2 | A-1 | A-4 | A-1 |
| 2-1-4-2 | Formula 2 | A-1 | A-4 | A-2 |
| 2-1-4-3 | Formula 2 | A-1 | A-4 | A-3 |
| 2-1-4-4 | Formula 2 | A-1 | A-4 | A-4 |
| 2-1-4-5 | Formula 2 | A-1 | A-4 | A-5 |
| 2-1-4-6 | Formula 2 | A-1 | A-4 | A-6 |
| 2-1-4-7 | Formula 2 | A-1 | A-4 | A-7 |
| 2-1-4-8 | Formula 2 | A-1 | A-4 | A-8 |
| 2-2-2-1 | Formula 2 | A-2 | A-2 | A-1 |
| 2-2-2-2 | Formula 2 | A-2 | A-2 | A-2 |
| 2-2-2-3 | Formula 2 | A-2 | A-2 | A-3 |
| 2-2-2-4 | Formula 2 | A-2 | A-2 | A-4 |
| 2-2-2-5 | Formula 2 | A-2 | A-2 | A-5 |
| 2-2-2-6 | Formula 2 | A-2 | A-2 | A-6 |
| 2-2-2-7 | Formula 2 | A-2 | A-2 | A-7 |
| 2-2-2-8 | Formula 2 | A-2 | A-2 | A-8 |
| 2-2-3-1 | Formula 2 | A-2 | A-3 | A-1 |
| 2-2-3-2 | Formula 2 | A-2 | A-3 | A-2 |
| 2-2-3-3 | Formula 2 | A-2 | A-3 | A-3 |
| 2-2-3-4 | Formula 2 | A-2 | A-3 | A-4 |
| 2-2-3-5 | Formula 2 | A-2 | A-3 | A-5 |
| 2-2-3-6 | Formula 2 | A-2 | A-3 | A-6 |
| 2-2-3-7 | Formula 2 | A-2 | A-3 | A-7 |
| 2-2-3-8 | Formula 2 | A-2 | A-3 | A-8 |
| 2-2-4-1 | Formula 2 | A-2 | A-4 | A-1 |
| 2-2-4-2 | Formula 2 | A-2 | A-4 | A-2 |
| 2-2-4-3 | Formula 2 | A-2 | A-4 | A-3 |
| 2-2-4-4 | Formula 2 | A-2 | A-4 | A-4 |
| 2-2-4-5 | Formula 2 | A-2 | A-4 | A-5 |
| 2-2-4-6 | Formula 2 | A-2 | A-4 | A-6 |
| 2-2-4-7 | Formula 2 | A-2 | A-4 | A-7 |
| 2-2-4-8 | Formula 2 | A-2 | A-4 | A-8 |
| 2-3-3-1 | Formula 2 | A-3 | A-3 | A-1 |
| 2-3-3-2 | Formula 2 | A-3 | A-3 | A-2 |
| 2-3-3-3 | Formula 2 | A-3 | A-3 | A-3 |
| 2-3-3-4 | Formula 2 | A-3 | A-3 | A-4 |
| 2-3-3-5 | Formula 2 | A-3 | A-3 | A-5 |
| 2-3-3-6 | Formula 2 | A-3 | A-3 | A-6 |
| 2-3-3-7 | Formula 2 | A-3 | A-3 | A-7 |
| 2-3-3-8 | Formula 2 | A-3 | A-3 | A-8 |
| 2-3-4-1 | Formula 2 | A-3 | A-4 | A-1 |
| 2-3-4-2 | Formula 2 | A-3 | A-4 | A-2 |
| 2-3-4-3 | Formula 2 | A-3 | A-4 | A-3 |
| 2-3-4-4 | Formula 2 | A-3 | A-4 | A-4 |
| 2-3-4-5 | Formula 2 | A-3 | A-4 | A-5 |
| 2-3-4-6 | Formula 2 | A-3 | A-4 | A-6 |
| 2-3-4-7 | Formula 2 | A-3 | A-4 | A-7 |
| 2-3-4-8 | Formula 2 | A-3 | A-4 | A-8 |
| 2-4-4-1 | Formula 2 | A-4 | A-4 | A-1 |
| 2-4-4-2 | Formula 2 | A-4 | A-4 | A-2 |
| 2-4-4-3 | Formula 2 | A-4 | A-4 | A-3 |
| 2-4-4-4 | Formula 2 | A-4 | A-4 | A-4 |
| 2-4-4-5 | Formula 2 | A-4 | A-4 | A-5 |
| 2-4-4-6 | Formula 2 | A-4 | A-4 | A-6 |
| 2-4-4-7 | Formula 2 | A-4 | A-4 | A-7 |
| 2-4-4-8 | Formula 2 | A-4 | A-4 | A-8 |

Specifically, the compound represented by Formula 3 may be represented by any one of compounds noted in Table 3 below, but, the present invention is not limited thereto.

In these compounds, R₁, R₂, and R₃ each, as described above, may be independently substituted with at least one selected from the group including hydrogen, halogen, an amino group, a nitrile group, a nitro group, a C₁˜C₂₀ alkyl group, a C₁˜C₂₀ alkoxy group, a C₁˜C₂₀ alkylamine group, a C₁˜C₂₀ alkylthiophene group, a C₆˜C₂₀ aryl thiophene group, a C₂˜C₂₀ alkenyl group, a C₂˜C₂₀ alkynyl group, a C₃˜C₂₀ cycloalkyl group, a C₆˜C₂₀ aryl group substituted with deuterium, a C₆˜C₂₀ aryl group, a C₈˜C₂₀ arylalkenyl group, a silane group, a boron group, a germanium group, and a C₅˜C₂₀ heterocyclic group.

TABLE 3

| Compound | Formula | R1 | R2 | R3 |
|---|---|---|---|---|
| 3-1-1-1 | Formula 3 | A-1 | A-1 | A-1 |
| 3-1-1-2 | Formula 3 | A-1 | A-1 | A-2 |
| 3-1-1-3 | Formula 3 | A-1 | A-1 | A-3 |
| 3-1-1-4 | Formula 3 | A-1 | A-1 | A-4 |
| 3-1-1-5 | Formula 3 | A-1 | A-1 | A-5 |
| 3-1-1-6 | Formula 3 | A-1 | A-1 | A-6 |
| 3-1-1-7 | Formula 3 | A-1 | A-1 | A-7 |
| 3-1-1-8 | Formula 3 | A-1 | A-1 | A-8 |
| 3-1-2-1 | Formula 3 | A-1 | A-2 | A-1 |
| 3-1-2-2 | Formula 3 | A-1 | A-2 | A-2 |
| 3-1-2-3 | Formula 3 | A-1 | A-2 | A-3 |
| 3-1-2-4 | Formula 3 | A-1 | A-2 | A-4 |
| 3-1-2-5 | Formula 3 | A-1 | A-2 | A-5 |
| 3-1-2-6 | Formula 3 | A-1 | A-2 | A-6 |
| 3-1-2-7 | Formula 3 | A-1 | A-2 | A-7 |
| 3-1-2-8 | Formula 3 | A-1 | A-2 | A-8 |
| 3-1-3-1 | Formula 3 | A-1 | A-3 | A-1 |
| 3-1-3-2 | Formula 3 | A-1 | A-3 | A-2 |
| 3-1-3-3 | Formula 3 | A-1 | A-3 | A-3 |
| 3-1-3-4 | Formula 3 | A-1 | A-3 | A-4 |
| 3-1-3-5 | Formula 3 | A-1 | A-3 | A-5 |
| 3-1-3-6 | Formula 3 | A-1 | A-3 | A-6 |
| 3-1-3-7 | Formula 3 | A-1 | A-3 | A-7 |
| 3-1-3-8 | Formula 3 | A-1 | A-3 | A-8 |
| 3-1-4-1 | Formula 3 | A-1 | A-4 | A-1 |
| 3-1-4-2 | Formula 3 | A-1 | A-4 | A-2 |
| 3-1-4-3 | Formula 3 | A-1 | A-4 | A-3 |
| 3-1-4-4 | Formula 3 | A-1 | A-4 | A-4 |
| 3-1-4-5 | Formula 3 | A-1 | A-4 | A-5 |
| 3-1-4-6 | Formula 3 | A-1 | A-4 | A-6 |
| 3-1-4-7 | Formula 3 | A-1 | A-4 | A-7 |
| 3-1-4-8 | Formula 3 | A-1 | A-4 | A-8 |
| 3-2-2-1 | Formula 2 | A-2 | A-2 | A-1 |
| 3-2-2-2 | Formula 2 | A-2 | A-2 | A-2 |
| 3-2-2-3 | Formula 2 | A-2 | A-2 | A-3 |
| 3-2-2-4 | Formula 2 | A-2 | A-2 | A-4 |
| 3-2-2-5 | Formula 2 | A-2 | A-2 | A-5 |
| 3-2-2-6 | Formula 2 | A-2 | A-2 | A-6 |
| 3-2-2-7 | Formula 2 | A-2 | A-2 | A-7 |
| 3-2-2-8 | Formula 2 | A-2 | A-2 | A-8 |
| 3-2-3-1 | Formula 2 | A-2 | A-3 | A-1 |
| 3-2-3-2 | Formula 2 | A-2 | A-3 | A-2 |
| 3-2-3-3 | Formula 2 | A-2 | A-3 | A-3 |
| 3-2-3-4 | Formula 2 | A-2 | A-3 | A-4 |
| 3-2-3-5 | Formula 2 | A-2 | A-3 | A-5 |
| 3-2-3-6 | Formula 2 | A-2 | A-3 | A-6 |
| 3-2-3-7 | Formula 2 | A-2 | A-3 | A-7 |
| 3-2-3-8 | Formula 2 | A-2 | A-3 | A-8 |
| 3-2-4-1 | Formula 2 | A-2 | A-4 | A-1 |
| 3-2-4-2 | Formula 2 | A-2 | A-4 | A-2 |
| 3-2-4-3 | Formula 2 | A-2 | A-4 | A-3 |
| 3-2-4-4 | Formula 2 | A-2 | A-4 | A-4 |
| 3-2-4-5 | Formula 2 | A-2 | A-4 | A-5 |
| 3-2-4-6 | Formula 2 | A-2 | A-4 | A-6 |
| 3-2-4-7 | Formula 2 | A-2 | A-4 | A-7 |
| 3-2-4-8 | Formula 2 | A-2 | A-4 | A-8 |
| 3-3-3-1 | Formula 3 | A-3 | A-3 | A-1 |
| 3-3-3-2 | Formula 3 | A-3 | A-3 | A-2 |
| 3-3-3-3 | Formula 3 | A-3 | A-3 | A-3 |
| 3-3-3-4 | Formula 3 | A-3 | A-3 | A-4 |
| 3-3-3-5 | Formula 3 | A-3 | A-3 | A-5 |
| 3-3-3-6 | Formula 3 | A-3 | A-3 | A-6 |
| 3-3-3-7 | Formula 3 | A-3 | A-3 | A-7 |
| 3-3-3-8 | Formula 3 | A-3 | A-3 | A-8 |
| 3-3-4-1 | Formula 3 | A-3 | A-4 | A-1 |
| 3-3-4-2 | Formula 3 | A-3 | A-4 | A-2 |
| 3-3-4-3 | Formula 3 | A-3 | A-4 | A-3 |
| 3-3-4-4 | Formula 3 | A-3 | A-4 | A-4 |
| 3-3-4-5 | Formula 3 | A-3 | A-4 | A-5 |
| 3-3-4-6 | Formula 3 | A-3 | A-4 | A-6 |
| 3-3-4-7 | Formula 3 | A-3 | A-4 | A-7 |
| 3-3-4-8 | Formula 3 | A-3 | A-4 | A-8 |
| 3-4-4-1 | Formula 2 | A-4 | A-4 | A-1 |
| 3-4-4-2 | Formula 2 | A-4 | A-4 | A-2 |
| 3-4-4-3 | Formula 2 | A-4 | A-4 | A-3 |
| 3-4-4-4 | Formula 2 | A-4 | A-4 | A-4 |
| 3-4-4-5 | Formula 2 | A-4 | A-4 | A-5 |
| 3-4-4-6 | Formula 2 | A-4 | A-4 | A-6 |
| 3-4-4-7 | Formula 2 | A-4 | A-4 | A-7 |
| 3-4-4-8 | Formula 2 | A-4 | A-4 | A-8 |

Specifically, the compound represented by Formula 4 may be represented by any one of compounds noted in Table 4 below, but, the present invention is not limited thereto.

In these compounds, R₁, R₂, and R₃ each, as described above, may be independently substituted with at least one selected from the group including hydrogen, halogen, an amino group, a nitrile group, a nitro group, a C₁˜C₂₀ alkyl group, a C₁˜C₂₀ alkoxy group, a C₁˜C₂₀ alkylamine group, a C₁˜C₂₀ alkylthiophene group, a C₆˜C₂₀ aryl thiophene group, a C₂˜C₂₀ alkenyl group, a C₂˜C₂₀ alkynyl group, a C₃˜C₂₀ cycloalkyl group, a C₆˜C₂₀ aryl group substituted with deuterium, a C₆˜C₂₀ aryl group, a C₈˜C₂₀ arylalkenyl group, a silane group, a boron group, a germanium group, and a C₅˜C₂₀ heterocyclic group.

TABLE 4

| Compound | Formula | R1 | R2 | R3 |
|---|---|---|---|---|
| 4-1-1-1 | Formula 4 | A-1 | A-1 | A-1 |
| 4-1-1-2 | Formula 4 | A-1 | A-1 | A-2 |
| 4-1-1-3 | Formula 4 | A-1 | A-1 | A-3 |
| 4-1-1-4 | Formula 4 | A-1 | A-1 | A-4 |
| 4-1-1-5 | Formula 4 | A-1 | A-1 | A-5 |
| 4-1-1-6 | Formula 4 | A-1 | A-1 | A-6 |
| 4-1-1-7 | Formula 4 | A-1 | A-1 | A-7 |
| 4-1-1-8 | Formula 4 | A-1 | A-1 | A-8 |
| 4-1-2-1 | Formula 4 | A-1 | A-2 | A-1 |
| 4-1-2-2 | Formula 4 | A-1 | A-2 | A-2 |
| 4-1-2-3 | Formula 4 | A-1 | A-2 | A-3 |
| 4-1-2-4 | Formula 4 | A-1 | A-2 | A-4 |
| 4-1-2-5 | Formula 4 | A-1 | A-2 | A-5 |
| 4-1-2-6 | Formula 4 | A-1 | A-2 | A-6 |
| 4-1-2-7 | Formula 4 | A-1 | A-2 | A-7 |
| 4-1-2-8 | Formula 4 | A-1 | A-2 | A-8 |
| 4-1-3-1 | Formula 4 | A-1 | A-3 | A-1 |
| 4-1-3-2 | Formula 4 | A-1 | A-3 | A-2 |
| 4-1-3-3 | Formula 4 | A-1 | A-3 | A-3 |
| 4-1-3-4 | Formula 4 | A-1 | A-3 | A-4 |
| 4-1-3-5 | Formula 4 | A-1 | A-3 | A-5 |
| 4-1-3-6 | Formula 4 | A-1 | A-3 | A-6 |
| 4-1-3-7 | Formula 4 | A-1 | A-3 | A-7 |
| 4-1-3-8 | Formula 4 | A-1 | A-3 | A-8 |
| 4-1-4-1 | Formula 4 | A-1 | A-4 | A-1 |
| 4-1-4-2 | Formula 4 | A-1 | A-4 | A-2 |
| 4-1-4-3 | Formula 4 | A-1 | A-4 | A-3 |
| 4-1-4-4 | Formula 4 | A-1 | A-4 | A-4 |
| 4-1-4-5 | Formula 4 | A-1 | A-4 | A-5 |
| 4-1-4-6 | Formula 4 | A-1 | A-4 | A-6 |
| 4-1-4-7 | Formula 4 | A-1 | A-4 | A-7 |
| 4-1-4-8 | Formula 4 | A-1 | A-4 | A-8 |
| 4-2-2-1 | Formula 2 | A-2 | A-2 | A-1 |
| 4-2-2-2 | Formula 2 | A-2 | A-2 | A-2 |
| 4-2-2-3 | Formula 2 | A-2 | A-2 | A-3 |
| 4-2-2-4 | Formula 2 | A-2 | A-2 | A-4 |
| 4-2-2-5 | Formula 2 | A-2 | A-2 | A-5 |
| 4-2-2-6 | Formula 2 | A-2 | A-2 | A-6 |
| 4-2-2-7 | Formula 2 | A-2 | A-2 | A-7 |
| 4-2-2-8 | Formula 2 | A-2 | A-2 | A-8 |
| 4-2-3-1 | Formula 2 | A-2 | A-3 | A-1 |
| 4-2-3-2 | Formula 2 | A-2 | A-3 | A-2 |
| 4-2-3-3 | Formula 2 | A-2 | A-3 | A-3 |
| 4-2-3-4 | Formula 2 | A-2 | A-3 | A-4 |
| 4-2-3-5 | Formula 2 | A-2 | A-3 | A-5 |
| 4-2-3-6 | Formula 2 | A-2 | A-3 | A-6 |
| 4-2-3-7 | Formula 2 | A-2 | A-3 | A-7 |
| 4-2-3-8 | Formula 2 | A-2 | A-3 | A-8 |
| 4-2-4-1 | Formula 2 | A-2 | A-4 | A-1 |
| 4-2-4-2 | Formula 2 | A-2 | A-4 | A-2 |
| 4-2-4-3 | Formula 2 | A-2 | A-4 | A-3 |
| 4-2-4-4 | Formula 2 | A-2 | A-4 | A-4 |
| 4-2-4-5 | Formula 2 | A-2 | A-4 | A-5 |
| 4-2-4-6 | Formula 2 | A-2 | A-4 | A-6 |
| 4-2-4-7 | Formula 2 | A-2 | A-4 | A-7 |
| 4-2-4-8 | Formula 2 | A-2 | A-4 | A-8 |
| 4-3-3-1 | Formula 4 | A-3 | A-3 | A-1 |
| 4-3-3-2 | Formula 4 | A-3 | A-3 | A-2 |
| 4-3-3-3 | Formula 4 | A-3 | A-3 | A-3 |
| 4-3-3-4 | Formula 4 | A-3 | A-3 | A-4 |
| 4-3-3-5 | Formula 4 | A-3 | A-3 | A-5 |
| 4-3-3-6 | Formula 4 | A-3 | A-3 | A-6 |
| 4-3-3-7 | Formula 4 | A-3 | A-3 | A-7 |
| 4-3-3-8 | Formula 4 | A-3 | A-3 | A-8 |
| 4-3-4-1 | Formula 4 | A-3 | A-4 | A-1 |
| 4-3-4-2 | Formula 4 | A-3 | A-4 | A-2 |
| 4-3-4-3 | Formula 4 | A-3 | A-4 | A-3 |
| 4-3-4-4 | Formula 4 | A-3 | A-4 | A-4 |
| 4-3-4-5 | Formula 4 | A-3 | A-4 | A-5 |
| 4-3-4-6 | Formula 4 | A-3 | A-4 | A-6 |
| 4-3-4-7 | Formula 4 | A-3 | A-4 | A-7 |
| 4-3-4-8 | Formula 4 | A-3 | A-4 | A-8 |
| 4-4-4-1 | Formula 2 | A-4 | A-4 | A-1 |
| 4-4-4-2 | Formula 2 | A-4 | A-4 | A-2 |
| 4-4-4-3 | Formula 2 | A-4 | A-4 | A-3 |
| 4-4-4-4 | Formula 2 | A-4 | A-4 | A-4 |
| 4-4-4-5 | Formula 2 | A-4 | A-4 | A-5 |
| 4-4-4-6 | Formula 2 | A-4 | A-4 | A-6 |
| 4-4-4-7 | Formula 2 | A-4 | A-4 | A-7 |
| 4-4-4-8 | Formula 2 | A-4 | A-4 | A-8 |

Furthermore, in Tables 1 to 4, the substitutes, although not mentioned above, may be substituted or unsubstituted again. In other words, the substitutes may be substituted with other substituents or other substitutes again.

The organic electronic elements in which compounds, as described with reference to Formulas 1 to 4 and Tables 1 to 4, can be employed, may include, for example, an organic light-emitting diode (OLED), an organic solar cell, an organic photo conductor (OPC) drum, an organic transistor (organic TFT), and the like.

As one example of the organic electronic elements in which compounds, as described with reference to Formulas 1 to 4 and Tables 1 to 4, can be used, an organic light-emitting diode (OLED) will be described below, but the present invention is not limited thereto. The above described compound may be applied to various organic electronic elements.

In another embodiment of the present invention, there is provided an organic electronic element (organic electro-luminescence element) including a first electrode, a second electrode, and an organic material layer interposed between these electrodes, in which at least one of organic material layers includes the compounds represented by Formulas 1 to 4 and Tables 1 to 4. Also, the inventive compound may be used for various purposes in an organic electro-luminescence electronic device according to the kinds and properties of a substituent.

The inventive compound can be freely modified by a core and a substitute, and thus can be employed in various layers as well as a host of a phosphorescent or fluorescent light emitting layer.

Also, the organic electro-luminescence element may have a reverse structure in which on a substrate, a cathode, one or more organic material layers and an anode are sequentially layered.

Also, the organic material layers of the organic electro-luminescence element may include a hole injection layer, a hole transport layer, a light emitting layer, and an electron injection and/or transport layer.

Also, the organic material layer of the organic electro-luminescence element may include a light emitting layer, and the light emitting layer may include the compound represented by any one of Formulas 1 to 4. Herein, the compound represented by any one of Formulas 1 to 4 may perform a role as a host of the light emitting layer.

Also, the organic material layer of the organic electro-luminescence element may include an electron transport and/or injection layer, and the electron transport and/or injection layer may include the compound represented by any one of Formulas 1 to 4.

Also, the organic material layer of the organic electro-luminescence element may include a layer for both hole transport and light emission, and the layer may include the compound represented by any one of Formulas 1 to 4.

Also, the organic material layer of the organic electro-luminescence element may include a layer for both light emission and electron transport, and the layer may include the compound represented by any one of Formulas 1 to 4.

An organic material layer including the inventive compound represented by any one of Formulas 1 to 4 may include the compound represented by any one of Formulas 1 to 4, as a host, and another organic compound, a metal, or a metal compound, as a dopant.

The inventive organic electro-luminescence element may include not only an organic material layer including the compound represented by any one of Formulas 1 to 4, but also a hole injection layer or a hole transport layer that includes a compound including an arylamino group, a carbazole group, or a benzcarbazole group.

The inventive organic electronic element can be manufactured by a conventional organic electronic element manufacturing method and materials conventionally known in the art as long as one or more organic material layers are formed by the above described compounds.

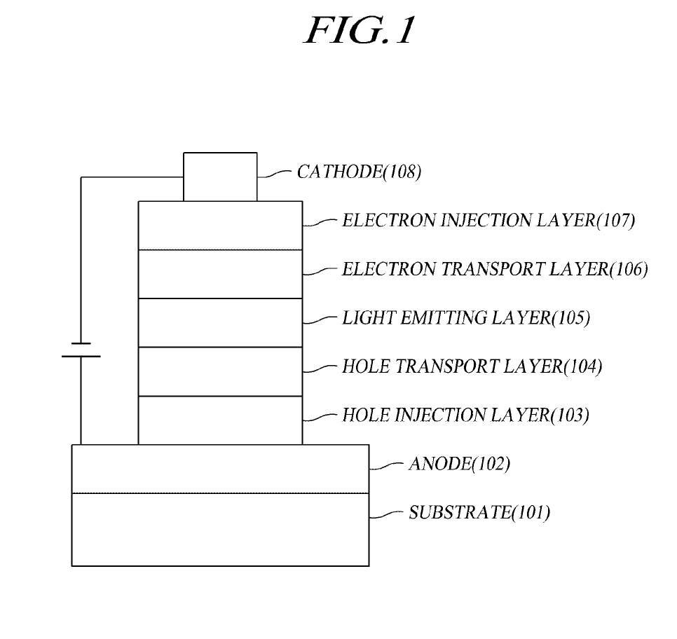

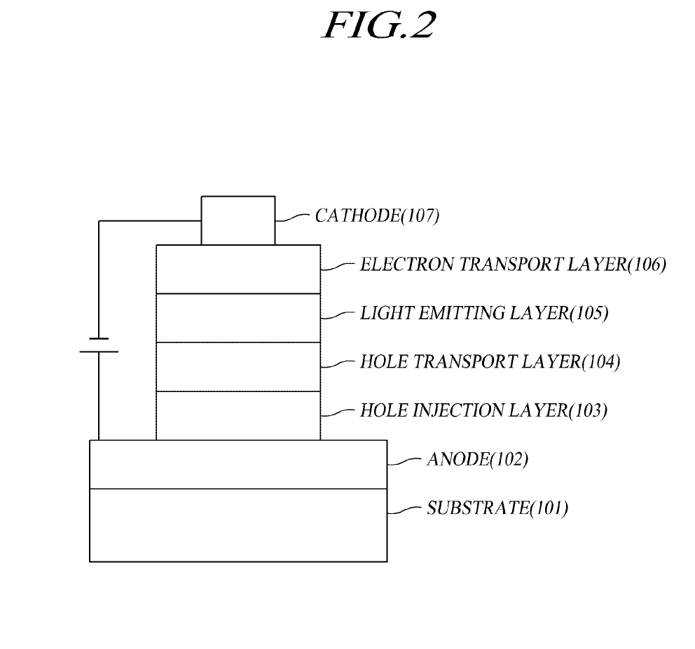

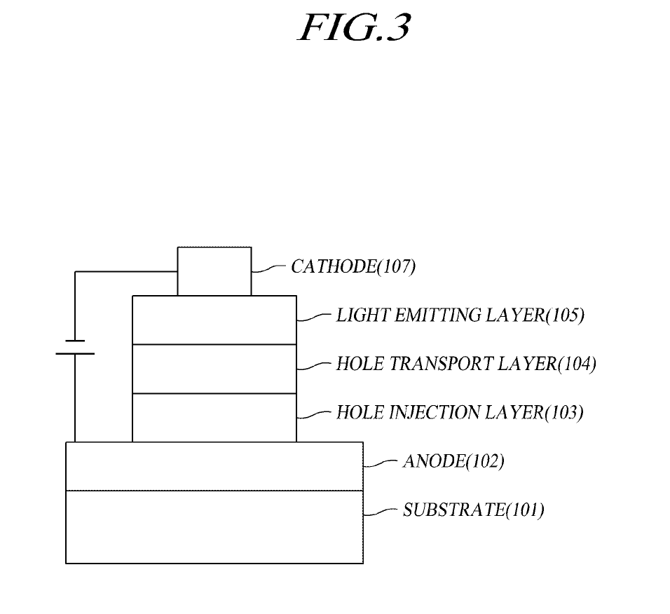

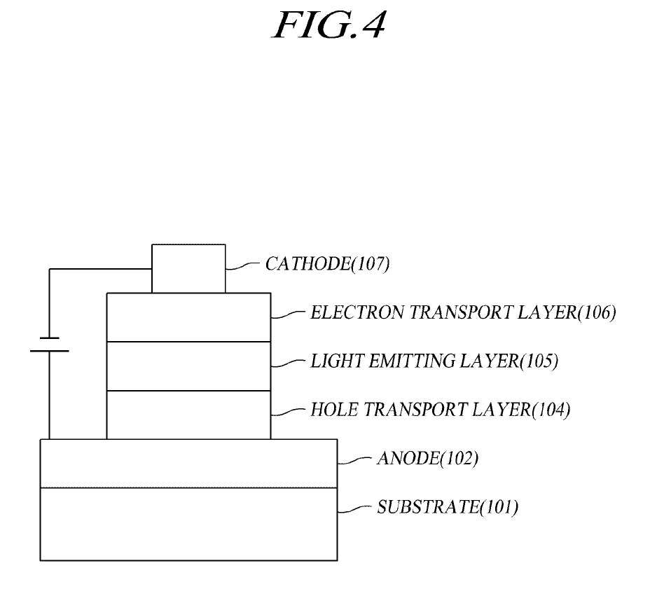

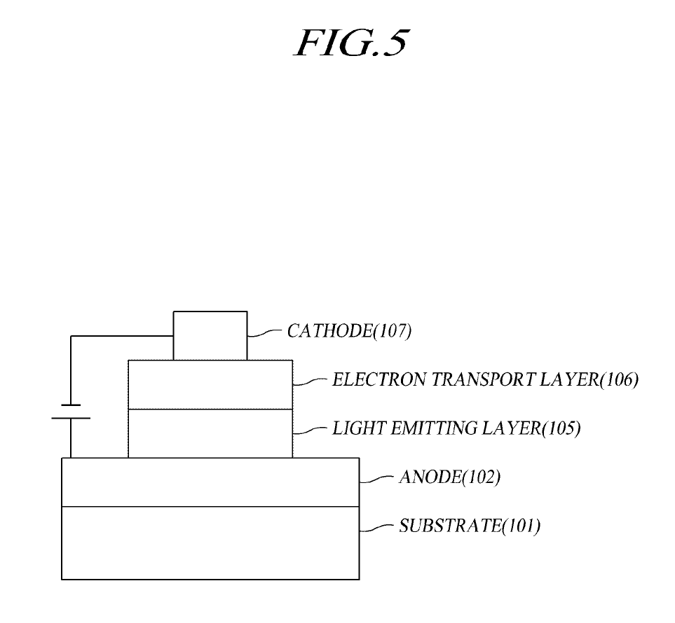

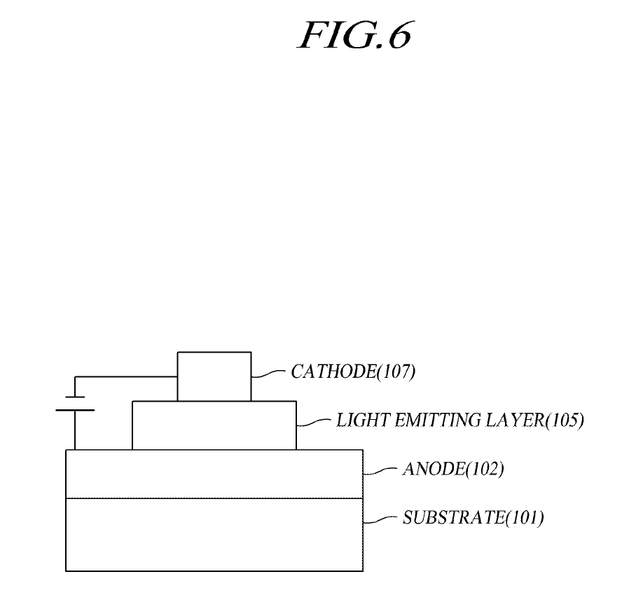

FIGS. 1 to 6 show examples of an organic electro-luminescence element which can employ a compound according to the present invention.

The organic electro-luminescence element according to another embodiment of the present invention may be manufactured by means of a manufacturing method and materials conventionally known in the art in such a manner that it can have a conventionally known structure, except that at least one of organic material layers including a hole injection layer, a hole transport layer, a light emitting layer, an electron transport layer, and an electron injection layer is formed in such a manner that it can include the compounds represented by Formulas 1 to 4 and Tables 1 to 4.

The structures of the organic electro-luminescence element according to another embodiment of the present invention are shown in FIGS. 1 to 6, but the present invention is not limited to the structures. Herein, the reference numeral 101 indicates a substrate, 102 indicates an anode, 103 indicates a hole injection layer (HIL), 104 indicates a hole transport layer (HTL), 105 indicates a light emitting layer (EML), 106 indicates an electron injection layer (EIL), 107 indicates an electron transport layer (ETL), and 108 indicates a cathode. Although not shown, such an organic electro-luminescence element may further include a hole blocking layer (HBL) for blocking movement of holes, an electron blocking layer (EBL) for blocking movement of electrons, a light emission assisting layer for supporting or assisting light emission, and a protective layer. The protective layer may be formed in such a manner that it, as an uppermost layer, can protect an organic material layer or a cathode.

Herein, the compound, as described with reference to Formulas 1 to 4, and Tables 1 to 4, may be included in at least one of organic material layers including a hole injection layer, a hole transport layer, a light emitting layer, and an electron transport layer. Specifically, the compound, as described with reference to Formulas 1 to 4, and Tables 1 to 4, may be substituted for at least one of a hole injection layer, a hole transport layer, a light emitting layer, an electron transport layer, an electron injection layer, a hole blocking layer, an electron blocking layer, an light emission assisting layer, and a protective layer, or may be used in combination with these layers. Of course, the compound may be used for not only one layer of the organic material layers but also two or more layers.

Especially, the compound, as described with reference to Formulas 1 to 4, and Tables 1 to 4 may be used as a material for hole injection, hole transport, electron injection, electron transport, light emission, and passivation (capping). Especially, it may be used alone as a light emitting material, a host or a dopant in host/dopant, and may be used as a hole injection layer or a hole transport layer.

For example, in manufacturing of the organic electro-luminescence element according to another embodiment of the present invention, a metal, a conductive metal oxide, or an alloy thereof is deposited on a substrate by means of PVD (physical vapor deposition) such as sputtering or e-beam evaporation so as to form an anode, and then an organic material layer including a hole injection layer, a hole transport layer, a light emitting layer, an electron transport layer, and an electron injection layer is formed thereon, and a material used as a cathode is deposited thereon.

Besides, on a substrate, a cathode material, an organic material layer, and an anode material may be sequentially deposited so as to provide an organic electronic element. The organic material layer may be formed in a multi-layered structure including a hole injection layer, a hole transport layer, a light emitting layer, an electron transport layer, and an electron injection layer, but the present invention is not limited thereto. It may be formed in a single layer structure. Further, the organic material layer may be manufactured with a smaller number of layers by using various polymer materials by means of a soluble process or a solvent process (e.g., spin coating, dip coating, doctor blading, screen printing, inkjet printing, or thermal transfer) instead of deposition.

In the organic electro-luminescence element according to another embodiment of the present invention, the above described compound may be used in a soluble process such as a spin coating process or an ink jet process.

The substrate is a support for the organic electro-luminescence element, and may employ a silicon wafer, a quartz or glass plate, a metal plate, a plastic film or sheet.

On the substrate, an anode is positioned. Such an anode allows holes to be injected into a hole injection layer positioned thereon. As an anode material, a material having a high work function is preferably used so that injection of holes into an organic material layer can be smoothly carried out. Specific examples of an anode material used for the present invention may include: metals (such as vanadium, chromium, copper, zinc, gold) or alloys thereof; metal oxides such as zinc oxide, indium oxide, indium tin oxide (ITO), indium zinc oxide (IZO); a metal-oxide combination such as ZnO:Al or SnO₂:Sb; and conductive polymers such as poly(3-methylthiophene), poly[3,4-(ethylene-1,2-dioxy)thiophene](PEDT), polypyrrole and polyaniline, but the present invention is not limited thereto.

On the anode, a hole injection layer is positioned. A material for such a hole injection layer is required to have a high efficiency for injecting holes from an anode, and to be able to efficiently transport the injected holes. For this, the material has a low ionization potential, a high transparency against visible light, and a high stability for holes.

As a hole injection material, a material into which holes can be efficiently injected from an anode at a low voltage is used. Preferably, HOMO (highest occupied molecular orbital) of the hole injection material ranges from a work function of an anode material to HOMO of adjacent organic material layers. Specific examples of the hole injection material may include metal porphyrine-, oligothiophene-, and arylamine-based organic materials, hexanitrile hexaazatriphenylene- and quinacridone-based organic materials, perylene-based organic materials, and anthraquinone-, polyaniline-, and polythiophene-based conductive polymers, but the present invention is not limited thereto.

On the hole injection layer, a hole transport layer is positioned. Such a hole transport layer receives holes transferred from the hole injection layer and transfers them to an organic light emitting layer positioned thereon. Further, the hole transport layer has a high hole mobility and a high hole stability and performs a role of blocking electrons. Besides these general requirements, it requires heat-resistance against a device when applied for an automobile display, and thus is preferably made of a material having a glass transition temperature (Tg) of 70° C. or more. The examples of a material satisfying these conditions may include NPD (or NPB), spiro-arylamine-based compound, perylene-arylamine-based compound, azacycloheptatriene compound, bis(diphenylvinylphenyl)anthracene, silicongermaniumoxide compound, silicon-based arylamine compound, and the like.

On the hole transport layer, an organic light emitting layer is positioned. Such an organic light emitting layer is made of a material having a high quantum efficiency, in which holes and electrons which are injected from an anode and a cathode, respectively, are recombined so as to emit light. As a light emitting material, a material allowing holes and electrons transferred from a hole transport layer and an electron transport layer, respectively, to be combined so as to emit visible light is used. Preferably, a material having a high quantum efficiency against fluorescence or phosphorescence is used.

As a material or a compound satisfying these conditions, for a green color, Alq3 may be used, and for a blue color, Balq (8-hydroxyquinoline beryllium salt), DPVBi (4,4′-bis(2,2-diphenylethenyl)-1,1′-biphenyl) based material, Spiro material, spiro-DPVBi (Spiro-4,4′-bis(2,2-diphenylethenyl)-1,1′-biphenyl), LiPBO (2-(2-benzoxazoyl)-phenol lithium salt), bis(diphenylvinylphenylvinyl)benzene, aluminum-quinoline metal complex, imidazole, thiazol and oxazole-metal complex, or the like may be used. In order to improve the luminous efficiency of a blue color, perylene, and BczVBi (3,3′[(1,1′-biphenyl)-4,4′-diyldi-2,1-ethenediyl]bis(9-ethyl)-9H-carbazole; DSA (distrylamine)) may be doped in a small amount. For a red color, a green light emitting material may be doped with DCJTB ([2-(1,1-dimethylethyl)-6-[2-(2,3,6,7-tetrahydro-1,1,7,7-tetramethyl-1H,5H-benzo(ij)quinolizin-9-yl)ethenyl]-4H-pyran-4-ylidene]-propanedinitrile) in a small amount. When a process such as inkjet printing, roll coating, spin coating, is used to form a light emitting layer, polyphenylenevinylene (PPV)-based polymer or poly fluorene may be used for an organic light emitting layer.

On the organic light emitting layer, an electron transport layer is positioned. Such an electron transport layer requires a material which has a high efficiency for electrons injected from a cathode positioned thereon, and can efficiently transport the injected electrons. For this, a material having a high electron affinity, a high electron mobility, and a high electron stability is required. The examples of an electron transport material satisfying these conditions may include Al complex of 8-hydroxyquinoline; complex including Alq₃; organic radical compound; and hydroxyflavone-metal complex, but the present invention is not limited thereto.

On the electron transport layer, an electron injection layer is layered. The electron injection layer may be manufactured by using a metal complex compound (such as Balq, Alq3, Be(bq)2, Zn(BTZ)2, Zn(phq)2, PBD, spiro-PBD, TPBI, and Tf-6P) or a low molecular material including an aromatic compound having an imidazole ring or a boron compound. Herein, the electron injection layer may be formed in a thickness range of 100 Å to 300 Å.

On the electron injection layer, a cathode is positioned. Such a cathode performs a role of injecting electrons into the electron injection layer. As a material for the cathode, the same material as that used for an anode may be used. In order to achieve efficient electron injection, a metal having a low work function is more preferable. Especially, metals such as tin, magnesium, indium, calcium, sodium, lithium, aluminum, silver, or alloys thereof may be used. Further, a double-layered electrode (e.g., lithium fluoride and aluminum, lithium oxide and aluminum, and strontium oxide and aluminum) with a thickness of 100 μm or less may be used.

As described above, the compound as described with reference to Formulas 1 to 4 and Tables 1 to 4 may be used as a hole injection material, a hole transport material, a light emitting material, an electron transport material and an electron injection material, which are appropriate for fluorescent and phosphorescent elements of all colors (such as red, green, blue, white). Also, the compound may be used as a material of a host (or a dopant) of various colors.

The organic electro-luminescence element according to the present invention may be manufactured in a front luminescent type, a rear luminescent type, or a both-side luminescent type according to its materials.

Meanwhile, the present invention provides a terminal which includes a display device and a control part for driving the display device, the display device including the above described organic electronic element. The terminal means a wired/wireless communication terminal which is currently used or will be used in the future. The above described terminal according to the present invention may be a mobile communication terminal such as a cellular phone, and may include all kinds of terminals such as a PDA, an electronic dictionary, a PMP, a remote control, a navigation unit, a game player, various kinds of TVs, and various kinds of computers.

### EXAMPLE

Hereinafter, the present invention will be described more specifically with reference to Preparation Examples and Experimental Examples. However, the following examples are only for illustrative purposes and are not intended to limit the scope of the invention.

### Preparation Example

Hereinafter, Preparation Examples or Synthesis Examples of the compounds represented by Formulas 1 to 4 and Tables 1 to 4 will be described.

However, since there are many compounds represented by Formulas 1 to 4 and Tables 1 to 4, some compounds from among the compounds will be exemplified. A person skilled in the art of the invention should realize that other compounds can be prepared through Preparation Examples as described below although they are not exemplified.

Hereinafter, compounds were synthesized according to the above described synthesis method, and were employed in an organic material layer of an organic electronic element, e.g., an organic electro-luminescence element. Then, they were compared to generally used compounds.

General Synthesis Method of Formula 1

Intermediate 1 (Sub 1) is generally synthesized according to Reaction Scheme 1 below.

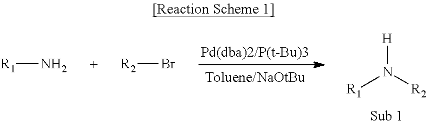

Intermediate 2 (Sub 2) is generally synthesized according to Reaction Scheme 2 below.

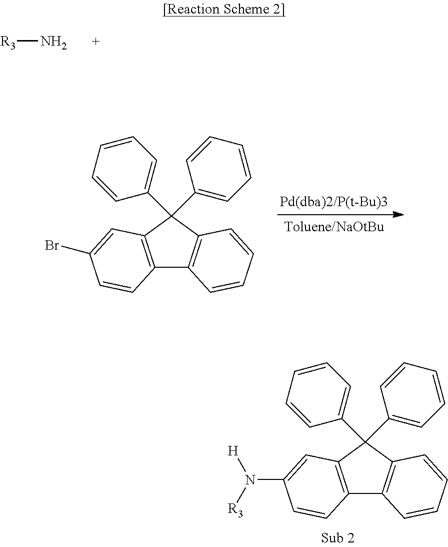

The prepared intermediate 1 (Sub 1) and the intermediate (Sub 2) were sequentially reacted with dibromo diphenyl. Then, intermediate 1 (Sub 1) was linked to the intermediate 2 (Sub 2) so as to synthesize a compound of Formula 1.

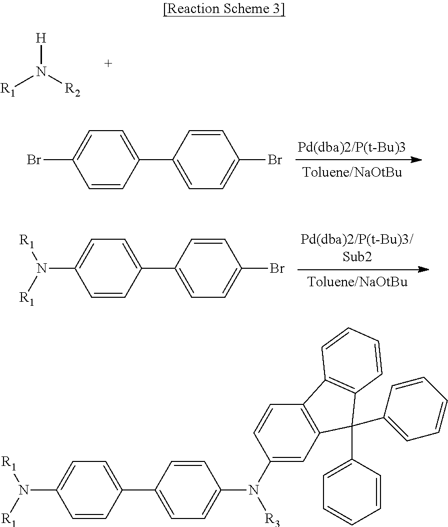

Also, into a core structure with the above described structure, various substituents can be introduced so that a compound having a peculiar characteristic of the introduced substituent can be synthesized. For example, in the manufacturing of an organic electronic element such as an organic light emitting element, substituents used for a hole injection layer material, a hole transport layer material, a light emitting layer material, and an electron transport layer material can be introduced into the structure so that materials satisfying requirements of respective organic material layers can be prepared.

Herein, initial reagents (amino compound) used for substitution of R₁, R₂, and R₃ in Reaction Scheme 3 are noted in Table 5 below, and other initial reagents (bromo compound) are noted in Table 6 below.

TABLE 5

| | |
|---|---|
| 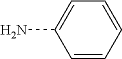 | A-1N |
| 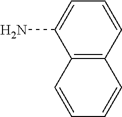 | A-2N |
| 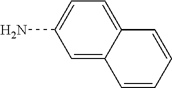 | A-3N |
| 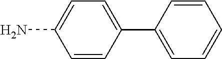 | A-4N |
| 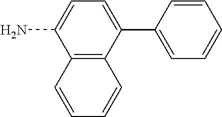 | A-5N |
| 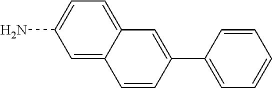 | A-6N |
| 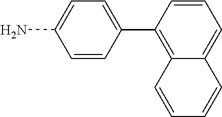 | A-7N |
| 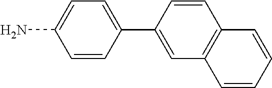 | A-8N |

TABLE 6

| | |
|---|---|
| 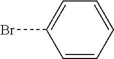 | A-1B |
| 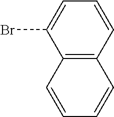 | A-2B |
| 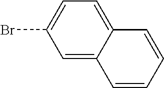 | A-3B |
| 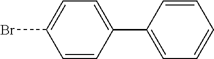 | A-4B |
| 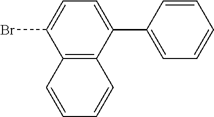 | A-5B |
| 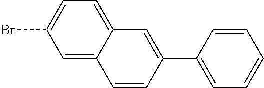 | A-6B |
| 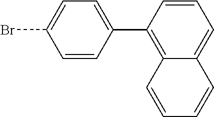 | A-7B |
| 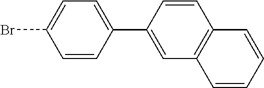 | A-8B |

Hereinafter, synthesis methods of compounds (1-1-1-1) to (4-4-4-8) noted in Tables 1 to 4 will be described in detail.

Herein, as described above, in compounds (1-1-1-1) to (4-4-4-8) noted in Tables 1 to 4, R₁, R₂, and R₃ each may be independently substituted with at least one selected from the group including hydrogen, halogen, an amino group, a nitrile group, a nitro group, a C₁˜C₂₀ alkyl group, a C₁˜C₂₀ alkoxy group, a C₁˜C₂₀ alkylamine group, a C₁˜C₂₀ alkylthiophene group, a C₆˜C₂₀ aryl thiophene group, a C₂˜C₂₀ alkenyl group, a C₂˜C₂₀ alkynyl group, a C₃˜C₂₀ cycloalkyl group, a C₆˜C₂₀ aryl group substituted with deuterium, a C₆˜C₂₀ aryl group, a C₈˜C₂₀ arylalkenyl group, a silane group, a boron group, a germanium group, and a C₅˜C₂₀ heterocyclic group. Also, initial reagents noted in Tables 5 and 6 may be substitutively used in the synthesis method of compounds (1-1-1-1) to (1-8-4-8) noted in Tables 1 to 4. The synthesis methods are the same as those in compounds (1-1-1-1) to (4-4-4-8) noted in Tables 1 to 4 except initial reagents. Thus, their description will be omitted. However, the synthesis methods are also included in this specification. For example, in a case where in A-1N of Table 5, one hydrogen in a phenyl group is substituted with a nitro group, the same process as the synthesis method of compound (1-1-1-1) may be carried out except that nitro A-1N is used as an initial reagent.

Synthesis Method of Compound (1-1-1-1)

Sub 1 Synthesis (A-1N+A-1B):

Aniline (A-1, amino compound) (18.6 g, 200 mmol) and bromobenzene (A-1, bromo compound (31.4 200 mmol) were mixed with toluene (1000 mL), and added with Pd(dba)2 (6 g, 14 mmol), P(t-Bu)3 (1.4 g, 7 mol), and NaOtBu (29.6 g, 300 mmol), followed by reflux-stirring for 24 hours. After the reaction was completed, the reaction product was extracted with ether and water. The organic layer was dried with MgSO₄ and concentrated. Then, the produced organic layer was purified by silica gel column and recrystallized to give a required compound.

Sub 2 Synthesis:

aniline (18.6 g, 200 mmol) and bromodiphenylfluorene (DPF-Br) (79.4 g 200 mmol) were mixed with toluene (1000 mL), and added with Pd(dba)2 (6 g, 14 mmol), P(t-Bu)3 (1.4 g, 7 mol), and NaOtBu (29.6 g, 300 mmol), followed by reflux-stirring for 24 hours. After the reaction was completed, the reaction product was extracted with ether and water. The organic layer was dried with MgSO₄ and concentrated. Then, the produced organic layer was purified by silica gel column and recrystallized to give a required compound.

Sub 1+Sub 2 Synthesis:

Sub 1 (16.9 g, 100 mmol) and dibromo diphenyl (156 g, 50 mmol) were mixed with toluene (1000 mL), and then added with Pd(dba)2 (3 g, 7 mmol), P(t-Bu)3 (0.7 g, 3.5 mol), and NaOtBu (14.8 g, 150 mmol), followed by reflux-stirring for 24 hours. After the reaction was completed, the reaction product was extracted with ether and water. The organic layer was dried with MgSO₄ and concentrated. Then, the produced organic layer was purified by silica gel column and recrystallized to give a required compound.

The obtained compound (50 mmol) was added with Sub 2 (20.45 g, 50 mmol), Pd(dba)2 (3 g, 7 mmol), P(t-Bu)3 (0.7 g, 3.5 mol), and NaOtBu (14.8 g, 150 mmol), followed by reflux-stirring for 24 hours. After the reaction was completed, the reaction product was extracted with ether and water. The organic layer was dried with MgSO₄ and concentrated. Then, the produced organic layer was purified by silica gel column and recrystallized to give a required compound. The obtained compound was measured by HRMS (High-Resolution Mass Spectrometry) [m/z 730.94 (M+)].

Compound (1-1-1-2) Synthesis Method.

Sub 1 synthesis (A-1N+A-1B) was carried out in the same manner as described in Sub 1 synthesis used in the synthesis method of the compound (1-1-1-1).

Sub 2 Synthesis:

A-2N (200 mmol) and bromodiphenylfluorene (DPF-Br) (79.4 g 200 mmol) were mixed with toluene (1000 mL), and added with Pd(dba)2 (6 g, 14 mmol), P(t-Bu)3 (1.4 g, 7 mol), and NaOtBu (29.6 g, 300 mmol), followed by reflux-stirring for 24 hours. After the reaction was completed, the reaction product was extracted with ether and water. The organic layer was dried with MgSO₄ and concentrated. Then, the produced organic layer was purified by silica gel column and recrystallized to give a required compound.

Sub 1+Sub 2 Synthesis:

Sub 1 (16.9 g, 100 mmol) and dibromo diphenyl (156 g, 50 mmol) were mixed with toluene (1000 mL), and added with Pd(dba)2 (3 g, 7 mmol), P(t-Bu)3 (0.7 g, 3.5 mol), and NaOtBu (14.8 g, 150 mmol), followed by reflux-stirring for 24 hours.

After the reaction was completed, the reaction product was extracted with ether and water. The organic layer was dried with MgSO₄ and concentrated. Then, the produced organic layer was purified by silica gel column and recrystallized to give a required compound.

Then, the obtained compound (50 mmol) was added with Sub 2 (50 mmol), Pd(dba)2 (3 g, 7 mmol), P(t-Bu)3 (0.7 g, 3.5 mol), and NaOtBu (14.8 g, 150 mmol), followed by reflux-stirring for 24 hours.

After the reaction was completed, the reaction product was extracted with ether and water. The organic layer was dried with MgSO₄ and concentrated. Then, the produced organic layer was purified by silica gel column and recrystallized to give a required compound. The obtained compound was measured by HRMS [m/z 781.05 (M+)].

Compound (1-1-1-3) Synthesis Method.

Sub 1 synthesis (A-1N+A-1B) was carried out in the same manner as described in Sub 1 synthesis used in the synthesis method of the compound (1-1-1-1).

Sub 2 Synthesis:

A-3N (200 mmol) and bromodiphenylfluorene (DPF-Br) (79.4 g 200 mmol) were mixed with toluene (1000 mL), and added with Pd(dba)2 (6 g, 14 mmol), P(t-Bu)3 (1.4 g, 7 mol), and NaOtBu (29.6 g, 300 mmol), followed by reflux-stirring for 24 hours.

After the reaction was completed, the reaction product was extracted with ether and water. The organic layer was dried with MgSO₄ and concentrated. Then, the produced organic layer was purified by silica gel column and recrystallized to give a required compound.

Sub 1+Sub 2 Synthesis:

Sub 1 (16.9 g, 100 mmol) and dibromo diphenyl (156 g, 50 mmol) were mixed with toluene (1000 mL), and added with Pd(dba)2 (3 g, 7 mmol), P(t-Bu)3 (0.7 g, 3.5 mol), and NaOtBu (14.8 g, 150 mmol), followed by reflux-stirring for 24 hours.

After the reaction was completed, the reaction product was extracted with ether and water. The organic layer was dried with MgSO₄ and concentrated. Then, the produced organic layer was purified by silica gel column and recrystallized to give a required compound.

Then, the obtained compound (50 mmol) was added with Sub 2 (50 mmol), Pd(dba)2 (3 g, 7 mmol), P(t-Bu)3 (0.7 g, 3.5 mol), and NaOtBu (14.8 g, 150 mmol), followed by reflux-stirring for 24 hours.

After the reaction was completed, the reaction product was extracted with ether and water. The organic layer was dried with MgSO₄ and concentrated. Then, the produced organic layer was purified by silica gel column and recrystallized to give a required compound.

Then, the obtained compound was measured by HRMS [m/z 781.25 (M+)].

Compound (1-1-1-4) Synthesis Method.

Sub 1 synthesis (A-1N+A-1B) was carried out in the same manner as described in Sub 1 synthesis used in the synthesis method of the compound (1-1-1-1).

Sub 2 Synthesis:

A-4N (200 mmol) and bromodiphenylfluorene (DPF-Br) (79.4 g 200 mmol) were mixed with toluene (1000 mL), and added with Pd(dba)2 (6 g, 14 mmol), P(t-Bu)3 (1.4 g, 7 mol), and NaOtBu (29.6 g, 300 mmol), followed by reflux-stirring for 24 hours.

After the reaction was completed, the reaction product was extracted with ether and water. The organic layer was dried with MgSO₄ and concentrated. Then, the produced organic layer was purified by silica gel column and recrystallized to give a required compound.

Sub 1+Sub 2 Synthesis:

Sub 1 (16.9 g, 100 mmol) and dibromo diphenyl (156 g, 50 mmol) were mixed with toluene (1000 mL), and added with Pd(dba)2 (3 g, 7 mmol), P(t-Bu)3 (0.7 g, 3.5 mol), and NaOtBu (14.8 g, 150 mmol), followed by reflux-stirring for 24 hours.

After the reaction was completed, the reaction product was extracted with ether and water. The organic layer was dried with MgSO₄ and concentrated. Then, the produced organic layer was purified by silica gel column and recrystallized to give a required compound.

Then, the obtained compound (50 mmol) was added with Sub (50 mmol), Pd(dba)2 (3 g, 7 mmol), P(t-Bu)3 (0.7 g, 3.5 mol), and NaOtBu (14.8 g, 150 mmol), followed by reflux-stirring for 24 hours.

After the reaction was completed, the reaction product was extracted with ether and water. The organic layer was dried with MgSO₄ and concentrated. Then, the produced organic layer was purified by silica gel column and recrystallized to give a required compound.

Then, the obtained compound was measured by HRMS [m/z 807.09 (M+)].

Compound (1-1-1-5) Synthesis Method.

Sub 1 synthesis (A-1N+A-1B) was carried out in the same manner as described in Sub 1 synthesis used in the synthesis method of the compound (1-1-1-1).

Sub 2 Synthesis:

A-5N (200 mmol) and bromodiphenylfluorene (DPF-Br) (79.4 g 200 mmol) were mixed with toluene (1000 mL), and added with Pd(dba)2 (6 g, 14 mmol), P(t-Bu)3 (1.4 g, 7 mol), and NaOtBu (29.6 g, 300 mmol), followed by reflux-stirring for 24 hours.

After the reaction was completed, the reaction product was extracted with ether and water. The organic layer was dried with MgSO₄ and concentrated. Then, the produced organic layer was purified by silica gel column and recrystallized to give a required compound.

Sub 1+Sub 2 Synthesis:

Sub 1 (16.9 g, 100 mmol) and dibromo diphenyl (156 g, 50 mmol) were mixed with toluene (1000 mL), and added with Pd(dba)2 (3 g, 7 mmol), P(t-Bu)3 (0.7 g, 3.5 mol), and NaOtBu (14.8 g, 150 mmol), followed by reflux-stirring for 24 hours.

After the reaction was completed, the reaction product was extracted with ether and water. The organic layer was dried with MgSO₄ and concentrated. Then, the produced organic layer was purified by silica gel column and recrystallized to give a required compound.

Then, the obtained compound (50 mmol) was added with Sub 2 (50 mmol), Pd(dba)2 (3 g, 7 mmol), P(t-Bu)3 (0.7 g, 3.5 mol), and NaOtBu (14.8 g, 150 mmol), followed by reflux-stirring for 24 hours.

After the reaction was completed, the reaction product was extracted with ether and water. The organic layer was dried with MgSO₄ and concentrated. Then, the produced organic layer was purified by silica gel column and recrystallized to give a required compound.

Then, the obtained compound was measured by HRMS [m/z 857.11 (M+)].

Compound (1-1-1-6) Synthesis Method.

Sub 1 synthesis (A-1N+A-1B): was carried out in the same manner as described in Sub 1 synthesis used in the synthesis method of the compound (1-1-1-1).

Sub 2 Synthesis:

A-6N (200 mmol) and bromodiphenylfluorene (DPF-Br) (79.4 g 200 mmol) were mixed with toluene (1000 mL), and added with Pd(dba)2 (6 g, 14 mmol), P(t-Bu)3 (1.4 g, 7 mol), and NaOtBu (29.6 g, 300 mmol), followed by reflux-stirring for 24 hours. After the reaction was completed, the reaction product was extracted with ether and water. The organic layer was dried with MgSO₄ and concentrated. Then, the produced organic layer was purified by silica gel column and recrystallized to give a required compound.

Sub 1+Sub 2 Synthesis:

Sub 1 (16.9 g, 100 mmol) and dibromo diphenyl (156 g, 50 mmol) were mixed with toluene (1000 mL), and added with Pd(dba)2 (3 g, 7 mmol), P(t-Bu)3 (0.7 g, 3.5 mol), and NaOtBu (14.8 g, 150 mmol), followed by reflux-stirring for 24 hours.

After the reaction was completed, the reaction product was extracted with ether and water. The organic layer was dried with MgSO₄ and concentrated. Then, the produced organic layer was purified by silica gel column and recrystallized to give a required compound.

Then, the obtained compound (50 mmol) was added with Sub 2 (50 mmol), Pd(dba)2 (3 g, 7 mmol), P(t-Bu)3 (0.7 g, 3.5 mol), and NaOtBu (14.8 g, 150 mmol), followed by reflux-stirring for 24 hours.

After the reaction was completed, the reaction product was extracted with ether and water. The organic layer was dried with MgSO₄ and concentrated. Then, the produced organic layer was purified by silica gel column and recrystallized to give a required compound.

Then, the compound was measured by HRMS [m/z 857.21 (M+)].

Compound (1-1-1-7) Synthesis Method.

Sub 1 synthesis (A-1N+A-1B) was carried out in the same manner as described in Sub 1 synthesis used in the synthesis method of the compound (1-1-1-1).

Sub 2 Synthesis:

A-7N (200 mmol) and bromodiphenylfluorene (DPF-Br) (79.4 g 200 mmol) were mixed with toluene (1000 mL), and added with Pd(dba)2 (6 g, 14 mmol), P(t-Bu)3 (1.4 g, 7 mol), and NaOtBu (29.6 g, 300 mmol), followed by reflux-stirring for 24 hours. After the reaction was completed, the reaction product was extracted with ether and water. The organic layer was dried with MgSO₄ and concentrated. Then, the produced organic layer was purified by silica gel column and recrystallized to give a required compound.

Sub 1+Sub 2 Synthesis:

Sub 1 (16.9 g, 100 mmol) and dibromo diphenyl (156 g, 50 mmol) were mixed with toluene (1000 mL), and added with Pd(dba)2 (3 g, 7 mmol), P(t-Bu)3 (0.7 g, 3.5 mol), and NaOtBu (14.8 g, 150 mmol), followed by reflux-stirring for 24 hours.

After the reaction was completed, the reaction product was extracted with ether and water. The organic layer was dried with MgSO₄ and concentrated. Then, the produced organic layer was purified by silica gel column and recrystallized to give a required compound.

Then, the compound (50 mmol) was added with Sub 2 (50 mmol), Pd(dba)2 (3 g, 7 mmol), P(t-Bu)3 (0.7 g, 3.5 mol), and NaOtBu (14.8 g, 150 mmol), followed by reflux-stirring for 24 hours.

After the reaction was completed, the reaction product was extracted with ether and water. The organic layer was dried with MgSO₄ and concentrated. Then, the produced organic layer was purified by silica gel column and recrystallized to give a required compound.

Then, the compound was measured by HRMS [m/z 857.19 (M+)].

Compound (1-1-1-8) Synthesis Method.

Sub 1 synthesis (A-1N+A-1B) was carried out in the same manner as described in Sub 1 synthesis used in the synthesis method of the compound (1-1-1-1).

Sub 2 Synthesis:

A-8N (200 mmol) and bromodiphenylfluorene (DPF-Br) (79.4 g 200 mmol) were mixed with toluene (1000 mL), and added with Pd(dba)2 (6 g, 14 mmol), P(t-Bu)3 (1.4 g, 7 mol), and NaOtBu (29.6 g, 300 mmol), followed by reflux-stirring for 24 hours. After the reaction was completed, the reaction product was extracted with ether and water. The organic layer was dried with MgSO₄ and concentrated. Then, the produced organic layer was purified by silica gel column and recrystallized to give a required compound.

Sub 1+Sub 2 Synthesis:

Sub 1 (16.9 g, 100 mmol) and dibromo diphenyl (156 g, 50 mmol) were mixed with toluene (1000 mL), and added with Pd(dba)2 (3 g, 7 mmol), P(t-Bu)3 (0.7 g, 3.5 mol), and NaOtBu (14.8 g, 150 mmol), followed by reflux-stirring for 24 hours.

After the reaction was completed, the reaction product was extracted with ether and water. The organic layer was dried with MgSO₄ and concentrated. Then, the produced organic layer was purified by silica gel column and recrystallized to give a required compound.

Then, the compound (50 mmol) was added with Sub 2 (50 mmol), Pd(dba)2 (3 g, 7 mmol), P(t-Bu)3 (0.7 g, 3.5 mol), and NaOtBu (14.8 g, 150 mmol), followed by reflux-stirring for 24 hours.

After the reaction was completed, the reaction product was extracted with ether and water. The organic layer was dried with MgSO₄ and concentrated. Then, the produced organic layer was purified by silica gel column and recrystallized to give a required compound.

Then, the compound was measured by HRMS [m/z 857.14 (M+)].

Compound (1-1-2-1) Synthesis Method.

Sub 1 Synthesis:

Aniline (A-1, amino compound) (18.6 g, 200 mmol) and bromo compound (A-2B, 200 mmol) were mixed with toluene (1000 mL), and added with Pd(dba)2 (6 g, 14 mmol), P(t-Bu)3 (1.4 g, 7 mol), and NaOtBu (29.6 g, 300 mmol), followed by reflux-stirring for 24 hours. After the reaction was completed, the reaction product was extracted with ether and water. The organic layer was dried with MgSO₄ and concentrated. Then, the produced organic layer was purified by silica gel column and recrystallized to give a required compound.

Sub 2 Synthesis: A-1N (200 mmol) and bromodiphenylfluorene (DPF-Br) (79.4 g 200 mmol) were mixed with toluene (1000 mL), and added with Pd(dba)2 (6 g, 14 mmol), P(t-Bu)3 (1.4 g, 7 mol), and NaOtBu (29.6 g, 300 mmol), followed by reflux-stirring for 24 hours. After the reaction was completed, the reaction product was extracted with ether and water. The organic layer was dried with MgSO₄ and concentrated. Then, the produced organic layer was purified by silica gel column and recrystallized to give a required compound.

Sub 1+Sub 2 Synthesis:

Sub 1 (100 mmol) and dibromo diphenyl (156 g, 50 mmol) were mixed with toluene (1000 mL), and added with Pd(dba)2 (3 g, 7 mmol), P(t-Bu)3 (0.7 g, 3.5 mol), and NaOtBu (14.8 g, 150 mmol), followed by reflux-stirring for 24 hours.

After the reaction was completed, the reaction product was extracted with ether and water. The organic layer was dried with MgSO₄ and concentrated. Then, the produced organic layer was purified by silica gel column and recrystallized to give a required compound.

Then, the compound (50 mmol) was added with Sub 2 (50 mmol), Pd(dba)2 (3 g, 7 mmol), P(t-Bu)3 (0.7 g, 3.5 mol), and NaOtBu (14.8 g, 150 mmol), followed by reflux-stirring for 24 hours.

After the reaction was completed, the reaction product was extracted with ether and water. The organic layer was dried with MgSO₄ and concentrated. Then, the produced organic layer was purified by silica gel column and recrystallized to give a required compound.

Then, the compound was measured by HRMS [m/z 781.01 (M+)].

Compound (1-1-2-2) Synthesis Method.

Sub 1 synthesis was carried out in the same manner as described in Sub 1 synthesis used in the synthesis method of the compound (1-1-2-1).

Sub 2 Synthesis:

A-2N (200 mmol) and bromodiphenylfluorene (DPF-Br) (79.4 g 200 mmol) were mixed with toluene (1000 mL), and added with Pd(dba)2 (6 g, 14 mmol), P(t-Bu)3 (1.4 g, 7 mol), and NaOtBu (29.6 g, 300 mmol), followed by reflux-stirring for 24 hours. After the reaction was completed, the reaction product was extracted with ether and water. The organic layer was dried with MgSO₄ and concentrated. Then, the produced organic layer was purified by silica gel column and recrystallized to give a required compound.

Sub 1+Sub 2 Synthesis:

Sub 1 (100 mmol) and dibromo diphenyl (156 g, 50 mmol) were mixed with toluene (1000 mL), and added with Pd(dba)2 (3 g, 7 mmol), P(t-Bu)3 (0.7 g, 3.5 mol), and NaOtBu (14.8 g, 150 mmol), followed by reflux-stirring for 24 hours.

After the reaction was completed, the reaction product was extracted with ether and water. The organic layer was dried with MgSO₄ and concentrated. Then, the produced organic layer was purified by silica gel column and recrystallized to give a required compound.

Then, the compound (50 mmol) was added with Sub 2 (50 mmol), Pd(dba)2 (3 g, 7 mmol), P(t-Bu)3 (0.7 g, 3.5 mol), and NaOtBu (14.8 g, 150 mmol), followed by reflux-stirring for 24 hours.

After the reaction was completed, the reaction product was extracted with ether and water. The organic layer was dried with MgSO₄ and concentrated. Then, the produced organic layer was purified by silica gel column and recrystallized to give a required compound.

Then, the compound was measured by HRMS [m/z 831.07 (M+)].

Compound (1-1-2-3) Synthesis Method.

Sub 1 synthesis was carried out in the same manner as described in Sub 1 synthesis used in the synthesis method of the compound (1-1-2-1).

Sub 2 Synthesis: A-3N (200 mmol) and bromodiphenylfluorene (DPF-Br) (79.4 g 200 mmol) were mixed with toluene (1000 mL), and added with Pd(dba)2 (6 g, 14 mmol), P(t-Bu)3 (1.4 g, 7 mol), and NaOtBu (29.6 g, 300 mmol), followed by reflux-stirring for 24 hours. After the reaction was completed, the reaction product was extracted with ether and water. The organic layer was dried with MgSO₄ and concentrated. Then, the produced organic layer was purified by silica gel column and recrystallized to give a required compound.

Sub 1+Sub 2 Synthesis:

Sub 1 (100 mmol) and dibromo diphenyl (156 g, 50 mmol) were mixed with toluene (1000 mL), and added with Pd(dba)2 (3 g, 7 mmol), P(t-Bu)3 (0.7 g, 3.5 mol), and NaOtBu (14.8 g, 150 mmol), followed by reflux-stirring for 24 hours.

After the reaction was completed, the reaction product was extracted with ether and water. The organic layer was dried with MgSO₄ and concentrated. Then, the produced organic layer was purified by silica gel column and recrystallized to give a required compound.

Then, the compound (50 mmol) was added with Sub 2 (50 mmol), Pd(dba)2 (3 g, 7 mmol), P(t-Bu)3 (0.7 g, 3.5 mol), and NaOtBu (14.8 g, 150 mmol), followed by reflux-stirring for 24 hours.

After the reaction was completed, the reaction product was extracted with ether and water. The organic layer was dried with MgSO₄ and concentrated. Then, the produced organic layer was purified by silica gel column and recrystallized to give a required compound.

Then, the compound was measured by HRMS [m/z 831.15 (M+)].

Compound (1-1-2-4) Synthesis Method.

Sub 1 synthesis was carried out in the same manner as described in the synthesis method of the compound (1-1-2-1).

Sub 2 Synthesis: A-4N (200 mmol) and bromodiphenylfluorene (DPF-Br) (79.4 g 200 mmol) were mixed with toluene (1000 mL), and added with Pd(dba)2 (6 g, 14 mmol), P(t-Bu)3 (1.4 g, 7 mol), and NaOtBu (29.6 g, 300 mmol), followed by reflux-stirring for 24 hours. After the reaction was completed, the reaction product was extracted with ether and water. The organic layer was dried with MgSO₄ and concentrated. Then, the produced organic layer was purified by silica gel column and recrystallized to give a required compound.

Sub 1+Sub 2 Synthesis:

Sub 1 (100 mmol) and dibromo diphenyl (156 g, 50 mmol) were mixed with toluene (1000 mL), and added with Pd(dba)2 (3 g, 7 mmol), P(t-Bu)3 (0.7 g, 3.5 mol), and NaOtBu (14.8 g, 150 mmol), followed by reflux-stirring for 24 hours.

After the reaction was completed, the reaction product was extracted with ether and water. The organic layer was dried with MgSO₄ and concentrated. Then, the produced organic layer was purified by silica gel column and recrystallized to give a required compound.

Then, the compound (50 mmol) was added with Sub 2 (50 mmol), Pd(dba)2 (3 g, 7 mmol), P(t-Bu)3 (0.7 g, 3.5 mol), and NaOtBu (14.8 g, 150 mmol), followed by reflux-stirring for 24 hours.

After the reaction was completed, the reaction product was extracted with ether and water. The organic layer was dried with MgSO₄ and concentrated. Then, the produced organic layer was purified by silica gel column and recrystallized to give a required compound.

Then, the compound was measured by HRMS [m/z 857.10 (M+)].

Compound (1-1-2-5) Synthesis Method.

Sub 1 synthesis was carried out in the same manner as described in Sub 1 synthesis used in the synthesis method of the compound (1-1-2-1).

Sub 2 Synthesis:

A-5N (200 mmol) and bromodiphenylfluorene (DPF-Br) (79.4 g 200 mmol) were mixed with toluene (1000 mL), and added with Pd(dba)2 (6 g, 14 mmol), P(t-Bu)3 (1.4 g, 7 mol), and NaOtBu (29.6 g, 300 mmol), followed by reflux-stirring for 24 hours. After the reaction was completed, the reaction product was extracted with ether and water. The organic layer was dried with MgSO₄ and concentrated. Then, the produced organic layer was purified by silica gel column and recrystallized to give a required compound.

Sub 1+Sub 2 Synthesis:

Sub 1 (100 mmol) and dibromo diphenyl (156 g, 50 mmol) were mixed with toluene (1000 mL), and added with Pd(dba)2 (3 g, 7 mmol), P(t-Bu)3 (0.7 g, 3.5 mol), and NaOtBu (14.8 g, 150 mmol), followed by reflux-stirring for 24 hours.

After the reaction was completed, the reaction product was extracted with ether and water. The organic layer was dried with MgSO₄ and concentrated. Then, the produced organic layer was purified by silica gel column and recrystallized to give a required compound.

Then, the compound (50 mmol) was added with Sub 2 (50 mmol), Pd(dba)2 (3 g, 7 mmol), P(t-Bu)3 (0.7 g, 3.5 mol), and NaOtBu (14.8 g, 150 mmol), followed by reflux-stirring for 24 hours.

After the reaction was completed, the reaction product was extracted with ether and water. The organic layer was dried with MgSO₄ and concentrated. Then, the produced organic layer was purified by silica gel column and recrystallized to give a required compound.

Then, the compound was measured by HRMS [m/z 907.12 (M+)].

Compound (1-1-2-6) Synthesis Method.

Sub 1 synthesis was carried out in the same manner as described in Sub 1 synthesis used in the synthesis method of the compound (1-1-2-1).

Sub 2 Synthesis:

A-6N (200 mmol) and bromodiphenylfluorene (DPF-Br) (79.4 g 200 mmol) were mixed with toluene (1000 mL), and added with Pd(dba)2 (6 g, 14 mmol), P(t-Bu)3 (1.4 g, 7 mol), and NaOtBu (29.6 g, 300 mmol), followed by reflux-stirring for 24 hours. After the reaction was completed, the reaction product was extracted with ether and water. The organic layer was dried with MgSO₄ and concentrated. Then, the produced organic layer was purified by silica gel column and recrystallized to give a required compound.

Sub 1+Sub 2 Synthesis:

Sub 1 (100 mmol) and dibromo diphenyl (156 g, 50 mmol) were mixed with toluene (1000 mL), and added with Pd(dba)2 (3 g, 7 mmol), P(t-Bu)3 (0.7 g, 3.5 mol), and NaOtBu (14.8 g, 150 mmol), followed by reflux-stirring for 24 hours.

After the reaction was completed, the reaction product was extracted with ether and water. The organic layer was dried with MgSO₄ and concentrated. Then, the produced organic layer was purified by silica gel column and recrystallized to give a required compound.

Then, the compound (50 mmol) was added with Sub 2 (50 mmol), Pd(dba)2 (3 g, 7 mmol), P(t-Bu)3 (0.7 g, 3.5 mol), and NaOtBu (14.8 g, 150 mmol), followed by reflux-stirring for 24 hours.

After the reaction was completed, the reaction product was extracted with ether and water. The organic layer was dried with MgSO₄ and concentrated. Then, the produced organic layer was purified by silica gel column and recrystallized to give a required compound.

Then, the compound was measured by HRMS [m/z 906.12 (M+)].

Compound (1-1-2-7) Synthesis Method.

Sub 1 synthesis was carried out in the same manner as described in Sub 1 synthesis used in the synthesis method of the compound (1-1-2-1).

Sub 2 Synthesis:

A-7N (200 mmol) and bromodiphenylfluorene (DPF-Br) (79.4 g 200 mmol) were mixed with toluene (1000 mL), and added with Pd(dba)2 (6 g, 14 mmol), P(t-Bu)3 (1.4 g, 7 mol), and NaOtBu (29.6 g, 300 mmol), followed by reflux-stirring for 24 hours. After the reaction was completed, the reaction product was extracted with ether and water. The organic layer was dried with MgSO₄ and concentrated. Then, the produced organic layer was purified by silica gel column and recrystallized to give a required compound.

Sub 1+Sub 2 Synthesis:

Sub 1 (100 mmol) and dibromo diphenyl (156 g, 50 mmol) were mixed with toluene (1000 mL), and added with Pd(dba)2 (3 g, 7 mmol), P(t-Bu)3 (0.7 g, 3.5 mol), and NaOtBu (14.8 g, 150 mmol), followed by reflux-stirring for 24 hours.

After the reaction was completed, the reaction product was extracted with ether and water. The organic layer was dried with MgSO₄ and concentrated. Then, the produced organic layer was purified by silica gel column and recrystallized to give a required compound.

Then, the compound (50 mmol) was added with Sub 2 (50 mmol), Pd(dba)2 (3 g, 7 mmol), P(t-Bu)3 (0.7 g, 3.5 mol), and NaOtBu (14.8 g, 150 mmol), followed by reflux-stirring for 24 hours.

After the reaction was completed, the reaction product was extracted with ether and water. The organic layer was dried with MgSO₄ and concentrated. Then, the produced organic layer was purified by silica gel column and recrystallized to give a required compound.

Then, the compound was measured by HRMS [m/z 906.72 (M+)].

Compound (1-1-2-8) Synthesis Method.

Sub 1 synthesis was carried out in the same manner as described in Sub 1 synthesis used in the synthesis method of the compound (1-1-2-1).

Sub 2 Synthesis:

A-8N (200 mmol) and bromodiphenylfluorene (DPF-Br) (79.4 g 200 mmol) were mixed with toluene (1000 mL), and added with Pd(dba)2 (6 g, 14 mmol), P(t-Bu)3 (1.4 g, 7 mol), and NaOtBu (29.6 g, 300 mmol), followed by reflux-stirring for 24 hours. After the reaction was completed, the reaction product was extracted with ether and water. The organic layer was dried with MgSO₄ and concentrated. Then, the produced organic layer was purified by silica gel column and recrystallized to give a required compound.

Sub 1+Sub 2 Synthesis:

Sub 1 (100 mmol) and dibromo diphenyl (156 g, 50 mmol) were mixed with toluene (1000 mL), and added with Pd(dba)2 (3 g, 7 mmol), P(t-Bu)3 (0.7 g, 3.5 mol), and NaOtBu (14.8 g, 150 mmol), followed by reflux-stirring for 24 hours.

After the reaction was completed, the reaction product was extracted with ether and water. The organic layer was dried with MgSO₄ and concentrated. Then, the produced organic layer was purified by silica gel column and recrystallized to give a required compound.

Then, the compound (50 mmol) was added with Sub 2 (50 mmol), Pd(dba)2 (3 g, 7 mmol), P(t-Bu)3 (0.7 g, 3.5 mol), and NaOtBu (14.8 g, 150 mmol), followed by reflux-stirring for 24 hours.

After the reaction was completed, the reaction product was extracted with ether and water. The organic layer was dried with MgSO₄ and concentrated. Then, the produced organic layer was purified by silica gel column and recrystallized to give a required compound.

Then, the compound was measured by HRMS [m/z 906.91 (M+)].

Compound (1-1-3-1) Synthesis Method.

Sub 1 Synthesis:

Aniline (A-1, amino compound) (18.6 g, 200 mmol) and bromo compound (A-3B, 200 mmol) were mixed with toluene (1000 mL), and added with Pd(dba)2 (6 g, 14 mmol), P(t-Bu)3 (1.4 g, 7 mol), and NaOtBu (29.6 g, 300 mmol), followed by reflux-stirring for 24 hours. After the reaction was completed, the reaction product was extracted with ether and water. The organic layer was dried with MgSO₄ and concentrated. Then, the produced organic layer was purified by silica gel column and recrystallized to give a required compound.

Sub 2 Synthesis:

A-1N (200 mmol) and bromodiphenylfluorene (DPF-Br) (79.4 g 200 mmol) were mixed with toluene (1000 mL), and added with Pd(dba)2 (6 g, 14 mmol), P(t-Bu)3 (1.4 g, 7 mol), and NaOtBu (29.6 g, 300 mmol), followed by reflux-stirring for 24 hours. After the reaction was completed, the reaction product was extracted with ether and water. The organic layer was dried with MgSO₄ and concentrated. Then, the produced organic layer was purified by silica gel column and recrystallized to give a required compound.

Sub 1+Sub 2 Synthesis:

Sub 1 (100 mmol) and dibromo diphenyl (156 g, 50 mmol) were mixed with toluene (1000 mL), and added with Pd(dba)2 (3 g, 7 mmol), P(t-Bu)3 (0.7 g, 3.5 mol), and NaOtBu (14.8 g, 150 mmol), followed by reflux-stirring for 24 hours.

After the reaction was completed, the reaction product was extracted with ether and water. The organic layer was dried with MgSO₄ and concentrated. Then, the produced organic layer was purified by silica gel column and recrystallized to give a required compound.

Then, the compound (50 mmol) was added with Sub 2 (50 mmol), Pd(dba)2 (3 g, 7 mmol), P(t-Bu)3 (0.7 g, 3.5 mol), and NaOtBu (14.8 g, 150 mmol), followed by reflux-stirring for 24 hours.

After the reaction was completed, the reaction product was extracted with ether and water. The organic layer was dried with MgSO₄ and concentrated. Then, the produced organic layer was purified by silica gel column and recrystallized to give a required compound.

Then, the compound was measured by HRMS [m/z 780.11 (M+)].

Compound (1-1-3-2) Synthesis Method.

Sub 1 synthesis was carried out in the same manner as described in Sub 1 synthesis used in the synthesis method of the compound (1-1-3-1).

Sub 2 Synthesis:

A-2N (200 mmol) and bromodiphenylfluorene (DPF-Br) (79.4 g 200 mmol) were mixed with toluene (1000 mL), and added with Pd(dba)2 (6 g, 14 mmol), P(t-Bu)3 (1.4 g, 7 mol), and NaOtBu (29.6 g, 300 mmol), followed by reflux-stirring for 24 hours. After the reaction was completed, the reaction product was extracted with ether and water. The organic layer was dried with MgSO₄ and concentrated. Then, the produced organic layer was purified by silica gel column and recrystallized to give a required compound.

Sub 1+Sub 2 Synthesis:

Sub 1 (100 mmol) and dibromo diphenyl (156 g, 50 mmol) were mixed with toluene (1000 mL), and added with Pd(dba)2 (3 g, 7 mmol), P(t-Bu)3 (0.7 g, 3.5 mol), and NaOtBu (14.8 g, 150 mmol), followed by reflux-stirring for 24 hours.

After the reaction was completed, the reaction product was extracted with ether and water. The organic layer was dried with MgSO₄ and concentrated. Then, the produced organic layer was purified by silica gel column and recrystallized to give a required compound.

Then, the compound (50 mmol) was added with Sub 2 (50 mmol), Pd(dba)2 (3 g, 7 mmol), P(t-Bu)3 (0.7 g, 3.5 mol), and NaOtBu (14.8 g, 150 mmol), followed by reflux-stirring for 24 hours.

After the reaction was completed, the reaction product was extracted with ether and water. The organic layer was dried with MgSO₄ and concentrated. Then, the produced organic layer was purified by silica gel column and recrystallized to give a required compound.

Then, the compound was measured by HRMS [m/z 830.11 (M+)].

Compound (1-1-3-3) Synthesis Method.

Sub 1 synthesis was carried out in the same manner as described in Sub 1 synthesis used in the synthesis method of the compound (1-1-3-1).

Sub 2 Synthesis:

A-3N (200 mmol) and bromodiphenylfluorene (DPF-Br) (79.4 g 200 mmol) were mixed with toluene (1000 mL), and added with Pd(dba)2 (6 g, 14 mmol), P(t-Bu)3 (1.4 g, 7 mol), and NaOtBu (29.6 g, 300 mmol), followed by reflux-stirring for 24 hours. After the reaction was completed, the reaction product was extracted with ether and water. The organic layer was dried with MgSO₄ and concentrated. Then, the produced organic layer was purified by silica gel column and recrystallized to give a required compound.

Sub 1+Sub 2 Synthesis:

Sub 1 (100 mmol) and dibromo diphenyl (156 g, 50 mmol) were mixed with toluene (1000 mL), and added with Pd(dba)2 (3 g, 7 mmol), P(t-Bu)3 (0.7 g, 3.5 mol), and NaOtBu (14.8 g, 150 mmol), followed by reflux-stirring for 24 hours.

After the reaction was completed, the reaction product was extracted with ether and water. The organic layer was dried with MgSO₄ and concentrated. Then, the produced organic layer was purified by silica gel column and recrystallized to give a required compound.

Then, the compound (50 mmol) was added with Sub 2 (50 mmol), Pd(dba)2 (3 g, 7 mmol), P(t-Bu)3 (0.7 g, 3.5 mol), and NaOtBu (14.8 g, 150 mmol), followed by reflux-stirring for 24 hours.

After the reaction was completed, the reaction product was extracted with ether and water. The organic layer was dried with MgSO₄ and concentrated. Then, the produced organic layer was purified by silica gel column and recrystallized to give a required compound.

Then, the compound was measured by HRMS [m/z 830.52 (M+)].

Compound (1-1-3-4) Synthesis Method.

Sub 1 synthesis was carried out in the same manner as described in Sub 1 synthesis used in the synthesis method of the compound (1-1-3-1).

Sub 2 Synthesis:

A-4N (200 mmol) and bromodiphenylfluorene (DPF-Br) (79.4 g 200 mmol) were mixed with toluene (1000 mL), and added with Pd(dba)2 (6 g, 14 mmol), P(t-Bu)3 (1.4 g, 7 mol), and NaOtBu (29.6 g, 300 mmol), followed by reflux-stirring for 24 hours. After the reaction was completed, the reaction product was extracted with ether and water. The organic layer was dried with MgSO₄ and concentrated. Then, the produced organic layer was purified by silica gel column and recrystallized to give a required compound.

Sub 1+Sub 2 Synthesis:

Sub 1 (100 mmol) and dibromo diphenyl (156 g, 50 mmol) were mixed with toluene (1000 mL), and added with Pd(dba)2 (3 g, 7 mmol), P(t-Bu)3 (0.7 g, 3.5 mol), and NaOtBu (14.8 g, 150 mmol), followed by reflux-stirring for 24 hours.

After the reaction was completed, the reaction product was extracted with ether and water. The organic layer was dried with MgSO₄ and concentrated. Then, the produced organic layer was purified by silica gel column and recrystallized to give a required compound.

Then, the compound (50 mmol) was added with Sub 2 (50 mmol), Pd(dba)2 (3 g, 7 mmol), P(t-Bu)3 (0.7 g, 3.5 mol), and NaOtBu (14.8 g, 150 mmol), followed by reflux-stirring for 24 hours.

After the reaction was completed, the reaction product was extracted with ether and water. The organic layer was dried with MgSO₄ and concentrated. Then, the produced organic layer was purified by silica gel column and recrystallized to give a required compound.

Then, the compound was measured by HRMS [m/z 856.92 (M+)].

Compound (1-1-3-5) Synthesis Method.

Sub 1 synthesis was carried out in the same manner as described in Sub 1 synthesis used in the synthesis method of the compound (1-1-3-1).

Sub 2 Synthesis:

A-5N (200 mmol) and bromodiphenylfluorene (DPF-Br) (79.4 g 200 mmol) were mixed with toluene (1000 mL), and added with Pd(dba)2 (6 g, 14 mmol), P(t-Bu)3 (1.4 g, 7 mol), and NaOtBu (29.6 g, 300 mmol), followed by reflux-stirring for 24 hours.

After the reaction was completed, the reaction product was extracted with ether and water. The organic layer was dried with MgSO₄ and concentrated. Then, the produced organic layer was purified by silica gel column and recrystallized to give a required compound.

Sub 1+Sub 2 Synthesis:

Sub 1 (100 mmol) and dibromo diphenyl (156 g, 50 mmol) were mixed with toluene (1000 mL), and added with Pd(dba)2 (3 g, 7 mmol), P(t-Bu)3 (0.7 g, 3.5 mol), and NaOtBu (14.8 g, 150 mmol), followed by reflux-stirring for 24 hours.

After the reaction was completed, the reaction product was extracted with ether and water. The organic layer was dried with MgSO₄ and concentrated. Then, the produced organic layer was purified by silica gel column and recrystallized to give a required compound.

Then, the compound (50 mmol) was added with Sub 2 (50 mmol), Pd(dba)2 (3 g, 7 mmol), P(t-Bu)3 (0.7 g, 3.5 mol), and NaOtBu (14.8 g, 150 mmol), followed by reflux-stirring for 24 hours.

After the reaction was completed, the reaction product was extracted with ether and water. The organic layer was dried with MgSO₄ and concentrated. Then, the produced organic layer was purified by silica gel column and recrystallized to give a required compound.

Then, the compound was measured by HRMS [m/z 907.02 (M+)].

Compound (1-1-3-6) Synthesis Method.

Sub 1 synthesis was carried out in the same manner as described in Sub 1 synthesis used in the synthesis method of the compound (1-1-3-1).

Sub 2 Synthesis:

A-6N (200 mmol) and bromodiphenylfluorene (DPF-Br) (79.4 g 200 mmol) were mixed with toluene (1000 mL), and added with Pd(dba)2 (6 g, 14 mmol), P(t-Bu)3 (1.4 g, 7 mol), and NaOtBu (29.6 g, 300 mmol), followed by reflux-stirring for 24 hours. After the reaction was completed, the reaction product was extracted with ether and water. The organic layer was dried with MgSO₄ and concentrated. Then, the produced organic layer was purified by silica gel column and recrystallized to give a required compound.

Sub 1+Sub 2 Synthesis:

Sub 1 (100 mmol) and dibromo diphenyl (156 g, 50 mmol) were mixed with toluene (1000 mL), and added with Pd(dba)2 (3 g, 7 mmol), P(t-Bu)3 (0.7 g, 3.5 mol), and NaOtBu (14.8 g, 150 mmol), followed by reflux-stirring for 24 hours.

After the reaction was completed, the reaction product was extracted with ether and water. The organic layer was dried with MgSO₄ and concentrated. Then, the produced organic layer was purified by silica gel column and recrystallized to give a required compound.

Then, the compound (50 mmol) was added with Sub 2 (50 mmol), Pd(dba)2 (3 g, 7 mmol), P(t-Bu)3 (0.7 g, 3.5 mol), and NaOtBu (14.8 g, 150 mmol), followed by reflux-stirring for 24 hours.

After the reaction was completed, the reaction product was extracted with ether and water. The organic layer was dried with MgSO₄ and concentrated. Then, the produced organic layer was purified by silica gel column and recrystallized to give a required compound.

Then, the compound was measured by HRMS [m/z 906.02 (M+)].

Compound (1-1-3-7) Synthesis Method.

Sub 1 synthesis was carried out in the same manner as described in Sub 1 synthesis used in the synthesis method of the compound (1-1-3-1).

Sub 2 Synthesis:

A-7N (200 mmol) and bromodiphenylfluorene (DPF-Br) (79.4 g 200 mmol) were mixed with toluene (1000 mL), and added with Pd(dba)2 (6 g, 14 mmol), P(t-Bu)3 (1.4 g, 7 mol), and NaOtBu (29.6 g, 300 mmol), followed by reflux-stirring for 24 hours. After the reaction was completed, the reaction product was extracted with ether and water. The organic layer was dried with MgSO₄ and concentrated. Then, the produced organic layer was purified by silica gel column and recrystallized to give a required compound.

Sub 1+Sub 2 Synthesis:

Sub 1 (100 mmol) and dibromo diphenyl (156 g, 50 mmol) were mixed with toluene (1000 mL), and added with Pd(dba)2 (3 g, 7 mmol), P(t-Bu)3 (0.7 g, 3.5 mol), and NaOtBu (14.8 g, 150 mmol), followed by reflux-stirring for 24 hours.

After the reaction was completed, the reaction product was extracted with ether and water. The organic layer was dried with MgSO₄ and concentrated. Then, the produced organic layer was purified by silica gel column and recrystallized to give a required compound.

Then, the compound (50 mmol) was added with Sub 2 (50 mmol), Pd(dba)2 (3 g, 7 mmol), P(t-Bu)3 (0.7 g, 3.5 mol), and NaOtBu (14.8 g, 150 mmol), followed by reflux-stirring for 24 hours.

After the reaction was completed, the reaction product was extracted with ether and water. The organic layer was dried with MgSO₄ and concentrated. Then, the produced organic layer was purified by silica gel column and recrystallized to give a required compound.

Then, the compound was measured by HRMS [m/z 906.61 (M+)].

Compound (1-1-3-8) Synthesis Method.

Sub 1 synthesis was carried out in the same manner as described in Sub 1 synthesis used in the synthesis method of the compound (1-1-3-1).

Sub 2 Synthesis:

A-8N (200 mmol) and bromodiphenylfluorene (DPF-Br) (79.4 g 200 mmol) were mixed with toluene (1000 mL), and added with Pd(dba)2 (6 g, 14 mmol), P(t-Bu)3 (1.4 g, 7 mol), and NaOtBu (29.6 g, 300 mmol), followed by reflux-stirring for 24 hours. After the reaction was completed, the reaction product was extracted with ether and water. The organic layer was dried with MgSO₄ and concentrated. Then, the produced organic layer was purified by silica gel column and recrystallized to give a required compound.

Sub 1+Sub 2 Synthesis:

Sub 1 (100 mmol) and dibromo diphenyl (156 g, 50 mmol) were mixed with toluene (1000 mL), and added with Pd(dba)2 (3 g, 7 mmol), P(t-Bu)3 (0.7 g, 3.5 mol), and NaOtBu (14.8 g, 150 mmol), followed by reflux-stirring for 24 hours.

After the reaction was completed, the reaction product was extracted with ether and water. The organic layer was dried with MgSO₄ and concentrated. Then, the produced organic layer was purified by silica gel column and recrystallized to give a required compound.

Then, the compound (50 mmol) was added with Sub 2 (50 mmol), Pd(dba)2 (3 g, 7 mmol), P(t-Bu)3 (0.7 g, 3.5 mol), and NaOtBu (14.8 g, 150 mmol), followed by reflux-stirring for 24 hours.

After the reaction was completed, the reaction product was extracted with ether and water. The organic layer was dried with MgSO₄ and concentrated. Then, the produced organic layer was purified by silica gel column and recrystallized to give a required compound.

Then, the compound was measured by HRMS [m/z 906.75 (M+)].

Compound (1-1-4-1) Synthesis Method.

Sub 1 Synthesis:

Aniline (A-1, amino compound) (18.6 g, 200 mmol) and bromo compound (A-4B, 200 mmol) were mixed with toluene (1000 mL), and added with Pd(dba)2 (6 g, 14 mmol), P(t-Bu)3 (1.4 g, 7 mol), and NaOtBu (29.6 g, 300 mmol), followed by reflux-stirring for 24 hours. After the reaction was completed, the reaction product was extracted with ether and water. The organic layer was dried with MgSO₄ and concentrated. Then, the produced organic layer was purified by silica gel column and recrystallized to give a required compound.

Sub 2 Synthesis:

A-1N (200 mmol) and bromodiphenylfluorene (DPF-Br) (79.4 g 200 mmol) were mixed with toluene (1000 mL), and added with Pd(dba)2 (6 g, 14 mmol), P(t-Bu)3 (1.4 g, 7 mol), and NaOtBu (29.6 g, 300 mmol), followed by reflux-stirring for 24 hours. After the reaction was completed, the reaction product was extracted with ether and water. The organic layer was dried with MgSO₄ and concentrated. Then, the produced organic layer was purified by silica gel column and recrystallized to give a required compound.

Sub 1+Sub 2 Synthesis:

Sub 1 (100 mmol) and dibromo diphenyl (156 g, 50 mmol) were mixed with toluene (1000 mL), and added with Pd(dba)2 (3 g, 7 mmol), P(t-Bu)3 (0.7 g, 3.5 mol), and NaOtBu (14.8 g, 150 mmol), followed by reflux-stirring for 24 hours.

After the reaction was completed, the reaction product was extracted with ether and water. The organic layer was dried with MgSO₄ and concentrated. Then, the produced organic layer was purified by silica gel column and recrystallized to give a required compound.

Then, the compound (50 mmol) was added with Sub 2 (50 mmol), Pd(dba)2 (3 g, 7 mmol), P(t-Bu)3 (0.7 g, 3.5 mol), and NaOtBu (14.8 g, 150 mmol), followed by reflux-stirring for 24 hours.

After the reaction was completed, the reaction product was extracted with ether and water. The organic layer was dried with MgSO₄ and concentrated. Then, the produced organic layer was purified by silica gel column and recrystallized to give a required compound.

Then, the compound was measured by HRMS [m/z 806.05 (M+)].

Compound (1-1-4-2) Synthesis Method.

Sub 1 synthesis was carried out in the same manner as described in Sub 1 synthesis used in the synthesis method of the compound (1-1-4-1).

Sub 2 Synthesis:

A-2N (200 mmol) and bromodiphenylfluorene (DPF-Br) (79.4 g 200 mmol) were mixed with toluene (1000 mL), and added with Pd(dba)2 (6 g, 14 mmol), P(t-Bu)3 (1.4 g, 7 mol), and NaOtBu (29.6 g, 300 mmol) followed by reflux-stirring for 24 hours. After the reaction was completed, the reaction product was extracted with ether and water. The organic layer was dried with MgSO₄ and concentrated. Then, the produced organic layer was purified by silica gel column and recrystallized to give a required compound.

Sub 1+Sub 2 Synthesis:

Sub 1 (100 mmol) and dibromo diphenyl (156 g, 50 mmol) were mixed with toluene (1000 mL), and added with Pd(dba)2 (3 g, 7 mmol), P(t-Bu)3 (0.7 g, 3.5 mol), and NaOtBu (14.8 g, 150 mmol), followed by reflux-stirring for 24 hours.

After the reaction was completed, the reaction product was extracted with ether and water. The organic layer was dried with MgSO₄ and concentrated. Then, the produced organic layer was purified by silica gel column and recrystallized to give a required compound.

Then, the compound (50 mmol) was added with Sub 2 (50 mmol), Pd(dba)2 (3 g, 7 mmol), P(t-Bu)3 (0.7 g, 3.5 mol), and NaOtBu (14.8 g, 150 mmol), followed by reflux-stirring for 24 hours.

After the reaction was completed, the reaction product was extracted with ether and water. The organic layer was dried with MgSO₄ and concentrated. Then, the produced organic layer was purified by silica gel column and recrystallized to give a required compound.

Then, the compound was measured by HRMS [m/z 856.71M+)].

Compound (1-1-4-3) Synthesis Method.

Sub 1 synthesis was carried out in the same manner as described in Sub 1 synthesis used in the synthesis method of the compound (1-1-4-1).

Sub 2 Synthesis:

A-3N (200 mmol) and bromodiphenylfluorene (DPF-Br) (79.4 g 200 mmol) were mixed with toluene (1000 mL), and added with Pd(dba)2 (6 g, 14 mmol), P(t-Bu)3 (1.4 g, 7 mol), and NaOtBu (29.6 g, 300 mmol), followed by reflux-stirring for 24 hours. After the reaction was completed, the reaction product was extracted with ether and water. The organic layer was dried with MgSO₄ and concentrated. Then, the produced organic layer was purified by silica gel column and recrystallized to give a required compound.

Sub 1+Sub 2 Synthesis:

Sub 1 (100 mmol) and dibromo diphenyl (156 g, 50 mmol) were mixed with toluene (1000 mL), and added with Pd(dba)2 (3 g, 7 mmol), P(t-Bu)3 (0.7 g, 3.5 mol), and NaOtBu (14.8 g, 150 mmol), followed by reflux-stirring for 24 hours.

After the reaction was completed, the reaction product was extracted with ether and water. The organic layer was dried with MgSO₄ and concentrated. Then, the produced organic layer was purified by silica gel column and recrystallized to give a required compound.

Then, the compound (50 mmol) was added with Sub 2 (50 mmol), Pd(dba)2 (3 g, 7 mmol), P(t-Bu)3 (0.7 g, 3.5 mol), and NaOtBu (14.8 g, 150 mmol), followed by reflux-stirring for 24 hours.

After the reaction was completed, the reaction product was extracted with ether and water. The organic layer was dried with MgSO₄ and concentrated. Then, the produced organic layer was purified by silica gel column and recrystallized to give a required compound.

Then, the compound was measured by HRMS [m/z 856.82M+)].

Compound (1-1-4-4) Synthesis Method.

Sub 1 synthesis was carried out in the same manner as described in Sub 1 synthesis used in the synthesis method of the compound (1-1-4-1).

Sub 2 Synthesis:

A-4N (200 mmol) and bromodiphenylfluorene (DPF-Br) (79.4 g 200 mmol) were mixed with toluene (1000 mL), and added with Pd(dba)2 (6 g, 14 mmol), P(t-Bu)3 (1.4 g, 7 mol), and NaOtBu (29.6 g, 300 mmol), followed by reflux-stirring for 24 hours. After the reaction was completed, the reaction product was extracted with ether and water. The organic layer was dried with MgSO₄ and concentrated. Then, the produced organic layer was purified by silica gel column and recrystallized to give a required compound.

Sub 1+Sub 2 Synthesis:

Sub 1 (100 mmol) and dibromo diphenyl (156 g, 50 mmol) were mixed with toluene (1000 mL), and added with Pd(dba)2 (3 g, 7 mmol), P(t-Bu)3 (0.7 g, 3.5 mol), and NaOtBu (14.8 g, 150 mmol), followed by reflux-stirring for 24 hours.

After the reaction was completed, the reaction product was extracted with ether and water. The organic layer was dried with MgSO₄ and concentrated. Then, the produced organic layer was purified by silica gel column and recrystallized to give a required compound.

Then, the compound (50 mmol) was added with Sub 2 (50 mmol), Pd(dba)2 (3 g, 7 mmol), P(t-Bu)3 (0.7 g, 3.5 mol), and NaOtBu (14.8 g, 150 mmol), followed by reflux-stirring for 24 hours.

After the reaction was completed, the reaction product was extracted with ether and water. The organic layer was dried with MgSO₄ and concentrated. Then, the produced organic layer was purified by silica gel column and recrystallized to give a required compound.

Then, the compound was measured by HRMS [m/z 882.15M+)].

Compound (1-1-4-5) Synthesis Method.

Sub 1 synthesis was carried out in the same manner as described in Sub 1 synthesis used in the synthesis method of the compound (1-1-4-1).

Sub 2 Synthesis:

A-5N (200 mmol) and bromodiphenylfluorene (DPF-Br) (79.4 g 200 mmol) were mixed with toluene (1000 mL), and added with Pd(dba)2 (6 g, 14 mmol), P(t-Bu)3 (1.4 g, 7 mol), and NaOtBu (29.6 g, 300 mmol), followed by reflux-stirring for 24 hours. After the reaction was completed, the reaction product was extracted with ether and water. The organic layer was dried with MgSO₄ and concentrated. Then, the produced organic layer was purified by silica gel column and recrystallized to give a required compound.

Sub 1+Sub 2 Synthesis:

Sub 1 (100 mmol) and dibromo diphenyl (156 g, 50 mmol) were mixed with toluene (1000 mL), and added with Pd(dba)2 (3 g, 7 mmol), P(t-Bu)3 (0.7 g, 3.5 mol), and NaOtBu (14.8 g, 150 mmol), followed by reflux-stirring for 24 hours.

After the reaction was completed, the reaction product was extracted with ether and water. The organic layer was dried with MgSO₄ and concentrated. Then, the produced organic layer was purified by silica gel column and recrystallized to give a required compound.

Then, the compound (50 mmol) was added with Sub 2 (50 mmol), Pd(dba)2 (3 g, 7 mmol), P(t-Bu)3 (0.7 g, 3.5 mol), and NaOtBu (14.8 g, 150 mmol), followed by reflux-stirring for 24 hours.

After the reaction was completed, the reaction product was extracted with ether and water. The organic layer was dried with MgSO₄ and concentrated. Then, the produced organic layer was purified by silica gel column and recrystallized to give a required compound.

Then, the compound was measured by HRMS [m/z 932.21M+)].

Compound (1-1-4-6) Synthesis Method.

Sub 1 synthesis was carried out in the same manner as described in Sub 1 synthesis used in the synthesis method of the compound (1-1-4-1).

Sub 2 Synthesis:

A-6N (200 mmol) and bromodiphenylfluorene (DPF-Br) (79.4 g 200 mmol) were mixed with toluene (1000 mL), and added with Pd(dba)2 (6 g, 14 mmol), P(t-Bu)3 (1.4 g, 7 mol), and NaOtBu (29.6 g, 300 mmol), followed by reflux-stirring for 24 hours. After the reaction was completed, the reaction product was extracted with ether and water. The organic layer was dried with MgSO₄ and concentrated. Then, the produced organic layer was purified by silica gel column and recrystallized to give a required compound.

Sub 1+Sub 2 Synthesis:

Sub 1 (100 mmol) and dibromo diphenyl (156 g, 50 mmol) were mixed with toluene (1000 mL), and added with Pd(dba)2 (3 g, 7 mmol), P(t-Bu)3 (0.7 g, 3.5 mol), and NaOtBu (14.8 g, 150 mmol), followed by reflux-stirring for 24 hours.

After the reaction was completed, the reaction product was extracted with ether and water. The organic layer was dried with MgSO₄ and concentrated. Then, the produced organic layer was purified by silica gel column and recrystallized to give a required compound.

Then, the compound (50 mmol) was added with Sub 2 (50 mmol), Pd(dba)2 (3 g, 7 mmol), P(t-Bu)3 (0.7 g, 3.5 mol), and NaOtBu (14.8 g, 150 mmol), followed by reflux-stirring for 24 hours.

After the reaction was completed, the reaction product was extracted with ether and water. The organic layer was dried with MgSO₄ and concentrated. Then, the produced organic layer was purified by silica gel column and recrystallized to give a required compound.

Then, the compound was measured by HRMS [m/z 932.85M+)].

Compound (1-1-4-7) Synthesis Method.

Sub 1 synthesis was carried out in the same manner as described in Sub 1 synthesis used in the synthesis method of the compound (1-1-4-1).

Sub 2 Synthesis:

A-7N (200 mmol) and bromodiphenylfluorene (DPF-Br) (79.4 g 200 mmol) were mixed with toluene (1000 mL), and added with Pd(dba)2 (6 g, 14 mmol), P(t-Bu)3 (1.4 g, 7 mol), and NaOtBu (29.6 g, 300 mmol), followed by reflux-stirring for 24 hours. After the reaction was completed, the reaction product was extracted with ether and water. The organic layer was dried with MgSO₄ and concentrated. Then, the produced organic layer was purified by silica gel column and recrystallized to give a required compound.

Sub 1+Sub 2 Synthesis:

Sub 1 (100 mmol) and dibromo diphenyl (156 g, 50 mmol) were mixed with toluene (1000 mL), and added with Pd(dba)2 (3 g, 7 mmol), P(t-Bu)3 (0.7 g, 3.5 mol), and NaOtBu (14.8 g, 150 mmol), followed by reflux-stirring for 24 hours.

After the reaction was completed, the reaction product was extracted with ether and water. The organic layer was dried with MgSO₄ and concentrated. Then, the produced organic layer was purified by silica gel column and recrystallized to give a required compound.

Then, the compound (50 mmol) was added with Sub 2 (50 mmol), Pd(dba)2 (3 g, 7 mmol), P(t-Bu)3 (0.7 g, 3.5 mol), and NaOtBu (14.8 g, 150 mmol), followed by reflux-stirring for 24 hours.

After the reaction was completed, the reaction product was extracted with ether and water. The organic layer was dried with MgSO₄ and concentrated. Then, the produced organic layer was purified by silica gel column and recrystallized to give a required compound.

Then, the compound was measured by HRMS [m/z 932.16M+)].

Compound (1-1-4-8) Synthesis Method.

Sub 1 synthesis was carried out in the same manner as described in Sub 1 synthesis used in the synthesis method of the compound (1-1-4-1).

Sub 2 Synthesis:

A-7N (200 mmol) and bromodiphenylfluorene (DPF-Br) (79.4 g 200 mmol) were mixed with toluene (1000 mL), and added with Pd(dba)2 (6 g, 14 mmol), P(t-Bu)3 (1.4 g, 7 mol), and NaOtBu (29.6 g, 300 mmol), followed by reflux-stirring for 24 hours. After the reaction was completed, the reaction product was extracted with ether and water. The organic layer was dried with MgSO₄ and concentrated. Then, the produced organic layer was purified by silica gel column and recrystallized to give a required compound.

Sub 1+Sub 2 Synthesis:

Sub 1 (100 mmol) and dibromo diphenyl (156 g, 50 mmol) were mixed with toluene (1000 mL), and added with Pd(dba)2 (3 g, 7 mmol), P(t-Bu)3 (0.7 g, 3.5 mol), and NaOtBu (14.8 g, 150 mmol), followed by reflux-stirring for 24 hours.

After the reaction was completed, the reaction product was extracted with ether and water. The organic layer was dried with MgSO₄ and concentrated. Then, the produced organic layer was purified by silica gel column and recrystallized to give a required compound.

Then, the compound (50 mmol) was added with Sub 2 (50 mmol), Pd(dba)2 (3 g, 7 mmol), P(t-Bu)3 (0.7 g, 3.5 mol), and NaOtBu (14.8 g, 150 mmol), followed by reflux-stirring for 24 hours.

After the reaction was completed, the reaction product was extracted with ether and water. The organic layer was dried with MgSO₄ and concentrated. Then, the produced organic layer was purified by silica gel column and recrystallized to give a required compound.

Then, the compound was measured by HRMS [m/z 932.91M+)].

Compound (1-2-2-1) Synthesis Method.

Sub 1 Synthesis:

aniline (A-2, amino compound) (200 mmol) and bromo compound (A-2B, 200 mmol) were mixed with toluene (1000 mL), and added with Pd(dba)2 (6 g, 14 mmol), P(t-Bu)3 (1.4 g, 7 mol), and NaOtBu (29.6 g, 300 mmol), followed by reflux-stirring for 24 hours. After the reaction was completed, the reaction product was extracted with ether and water. The organic layer was dried with MgSO₄ and concentrated. Then, the produced organic layer was purified by silica gel column and recrystallized to give a required compound.

Sub 2 Synthesis:

A-1N (200 mmol) and bromodiphenylfluorene (DPF-Br) (79.4 g 200 mmol) were mixed with toluene (1000 mL), and added with Pd(dba)2 (6 g, 14 mmol), P(t-Bu)3 (1.4 g, 7 mol), and NaOtBu (29.6 g, 300 mmol), followed by reflux-stirring for 24 hours. After the reaction was completed, the reaction product was extracted with ether and water. The organic layer was dried with MgSO₄ and concentrated. Then, the produced organic layer was purified by silica gel column and recrystallized to give a required compound.

Sub 1+Sub 2 Synthesis:

Sub 1 (100 mmol) and dibromo diphenyl (156 g, 50 mmol) were mixed with toluene (1000 mL), and added with Pd(dba)2 (3 g, 7 mmol), P(t-Bu)3 (0.7 g, 3.5 mol), and NaOtBu (14.8 g, 150 mmol), followed by reflux-stirring for 24 hours.

After the reaction was completed, the reaction product was extracted with ether and water. The organic layer was dried with MgSO₄ and concentrated. Then, the produced organic layer was purified by silica gel column and recrystallized to give a required compound.

Then, the compound (50 mmol) was added with Sub 2 (50 mmol), Pd(dba)2 (3 g, 7 mmol), P(t-Bu)3 (0.7 g, 3.5 mol), and NaOtBu (14.8 g, 150 mmol), followed by reflux-stirring for 24 hours.

After the reaction was completed, the reaction product was extracted with ether and water. The organic layer was dried with MgSO₄ and concentrated. Then, the produced organic layer was purified by silica gel column and recrystallized to give a required compound.

Then, the compound was measured by HRMS [m/z 830.07 (M+)].

Compound (1-2-2-2) Synthesis Method.

Sub 1 synthesis was carried out in the same manner as described in Sub 1 synthesis used in the synthesis method of the compound (1-2-2-1).

Sub 2 Synthesis:

A-2N (200 mmol) and bromodiphenylfluorene (DPF-Br) (79.4 g 200 mmol) were mixed with toluene (1000 mL), and added with Pd(dba)2 (6 g, 14 mmol), P(t-Bu)3 (1.4 g, 7 mol), and NaOtBu (29.6 g, 300 mmol), followed by reflux-stirring for 24 hours. After the reaction was completed, the reaction product was extracted with ether and water. The organic layer was dried with MgSO₄ and concentrated. Then, the produced organic layer was purified by silica gel column and recrystallized to give a required compound.

Sub 1+Sub 2 Synthesis:

Sub 1 (100 mmol) and dibromo diphenyl (156 g, 50 mmol) were mixed with toluene (1000 mL), and added with Pd(dba)2 (3 g, 7 mmol), P(t-Bu)3 (0.7 g, 3.5 mol), and NaOtBu (14.8 g, 150 mmol), followed by reflux-stirring for 24 hours.

After the reaction was completed, the reaction product was extracted with ether and water. The organic layer was dried with MgSO₄ and concentrated. Then, the produced organic layer was purified by silica gel column and recrystallized to give a required compound.

Then, the compound (50 mmol) was added with Sub 2 (50 mmol), Pd(dba)2 (3 g, 7 mmol), P(t-Bu)3 (0.7 g, 3.5 mol), and NaOtBu (14.8 g, 150 mmol), followed by reflux-stirring for 24 hours.

After the reaction was completed, the reaction product was extracted with ether and water. The organic layer was dried with MgSO₄ and concentrated. Then, the produced organic layer was purified by silica gel column and recrystallized to give a required compound.

Then, the compound was measured by HRMS [m/z 880.07 (M+)].

Compound (1-2-2-3) Synthesis Method.

Sub 1 synthesis was carried out in the same manner as described in Sub 1 synthesis used in the synthesis method of the compound (1-2-2-1).

Sub 2 Synthesis:

A-3N (200 mmol) and bromodiphenylfluorene (DPF-Br) (79.4 g 200 mmol) were mixed with toluene (1000 mL), and added with Pd(dba)2 (6 g, 14 mmol), P(t-Bu)3 (1.4 g, 7 mol), and NaOtBu (29.6 g, 300 mmol), followed by reflux-stirring for 24 hours. After the reaction was completed, the reaction product was extracted with ether and water. The organic layer was dried with MgSO₄ and concentrated. Then, the produced organic layer was purified by silica gel column and recrystallized to give a required compound.

Sub 1+Sub 2 Synthesis:

Sub 1 (100 mmol) and dibromo diphenyl (156 g, 50 mmol) were mixed with toluene (1000 mL), and added with Pd(dba)2 (3 g, 7 mmol), P(t-Bu)3 (0.7 g, 3.5 mol), and NaOtBu (14.8 g, 150 mmol), followed by reflux-stirring for 24 hours.

After the reaction was completed, the reaction product was extracted with ether and water. The organic layer was dried with MgSO₄ and concentrated. Then, the produced organic layer was purified by silica gel column and recrystallized to give a required compound.

Then, the compound (50 mmol) was added with Sub 2 (50 mmol), Pd(dba)2 (3 g, 7 mmol), P(t-Bu)3 (0.7 g, 3.5 mol), and NaOtBu (14.8 g, 150 mmol), followed by reflux-stirring for 24 hours.

After the reaction was completed, the reaction product was extracted with ether and water. The organic layer was dried with MgSO₄ and concentrated. Then, the produced organic layer was purified by silica gel column and recrystallized to give a required compound.

Then, the compound was measured by HRMS [m/z 880.77 (M+)].

Compound (1-2-2-4) Synthesis Method.

Sub 1 synthesis was carried out in the same manner as described in Sub 1 synthesis used in the synthesis method of the compound (1-2-2-1).

Sub 2 Synthesis:

A-4N (200 mmol) and bromodiphenylfluorene (DPF-Br) (79.4 g 200 mmol) were mixed with toluene (1000 mL), and added with Pd(dba)2 (6 g, 14 mmol), P(t-Bu)3 (1.4 g, 7 mol), and NaOtBu (29.6 g, 300 mmol), followed by reflux-stirring for 24 hours. After the reaction was completed, the reaction product was extracted with ether and water. The organic layer was dried with MgSO₄ and concentrated. Then, the produced organic layer was purified by silica gel column and recrystallized to give a required compound.

Sub 1+Sub 2 Synthesis:

Sub 1 (100 mmol) and dibromo diphenyl (156 g, 50 mmol) were mixed with toluene (1000 mL), and added with Pd(dba)2 (3 g, 7 mmol), P(t-Bu)3 (0.7 g, 3.5 mol), and NaOtBu (14.8 g, 150 mmol), followed by reflux-stirring for 24 hours.

After the reaction was completed, the reaction product was extracted with ether and water. The organic layer was dried with MgSO₄ and concentrated. Then, the produced organic layer was purified by silica gel column and recrystallized to give a required compound.

Then, the compound (50 mmol) was added with Sub 2 (50 mmol), Pd(dba)2 (3 g, 7 mmol), P(t-Bu)3 (0.7 g, 3.5 mol), and NaOtBu (14.8 g, 150 mmol), followed by reflux-stirring for 24 hours.

After the reaction was completed, the reaction product was extracted with ether and water. The organic layer was dried with MgSO₄ and concentrated. Then, the produced organic layer was purified by silica gel column and recrystallized to give a required compound.

Then, the compound was measured by HRMS [m/z 906.77 (M+)].

Compound (1-2-2-5) Synthesis Method.

Sub 1 synthesis was carried out in the same manner as described in Sub 1 synthesis used in the synthesis method of the compound (1-2-2-1).

Sub 2 Synthesis:

A-5N (200 mmol) and bromodiphenylfluorene (DPF-Br) (79.4 g 200 mmol) were mixed with toluene (1000 mL), and added with Pd(dba)2 (6 g, 14 mmol), P(t-Bu)3 (1.4 g, 7 mol), and NaOtBu (29.6 g, 300 mmol), followed by reflux-stirring for 24 hours. After the reaction was completed, the reaction product was extracted with ether and water. The organic layer was dried with MgSO₄ and concentrated. Then, the produced organic layer was purified by silica gel column and recrystallized to give a required compound.

Sub 1+Sub 2 synthesis:

Sub 1 (100 mmol) and dibromo diphenyl (156 g, 50 mmol) were mixed with toluene (1000 mL), and added with Pd(dba)2 (3 g, 7 mmol), P(t-Bu)3 (0.7 g, 3.5 mol), and NaOtBu (14.8 g, 150 mmol), followed by reflux-stirring for 24 hours.

After the reaction was completed, the reaction product was extracted with ether and water. The organic layer was dried with MgSO₄ and concentrated. Then, the produced organic layer was purified by silica gel column and recrystallized to give a required compound.

Then, the compound (50 mmol) was added with Sub 2 (50 mmol), Pd(dba)2 (3 g, 7 mmol), P(t-Bu)3 (0.7 g, 3.5 mol), and NaOtBu (14.8 g, 150 mmol), followed by reflux-stirring for 24 hours.

After the reaction was completed, the reaction product was extracted with ether and water. The organic layer was dried with MgSO₄ and concentrated. Then, the produced organic layer was purified by silica gel column and recrystallized to give a required compound.

Then, the compound was measured by HRMS [m/z 956.22 (M+)].

Compound (1-2-2-6) Synthesis Method.

Sub 1 synthesis was carried out in the same manner as described in Sub 1 synthesis used in the synthesis method of the compound (1-2-2-1).

Sub 2 Synthesis:

A-6N (200 mmol) and bromodiphenylfluorene (DPF-Br) (79.4 g 200 mmol) were mixed with toluene (1000 mL), and added with Pd(dba)2 (6 g, 14 mmol), P(t-Bu)3 (1.4 g, 7 mol), and NaOtBu (29.6 g, 300 mmol), followed by reflux-stirring for 24 hours. After the reaction was completed, the reaction product was extracted with ether and water. The organic layer was dried with MgSO₄ and concentrated. Then, the produced organic layer was purified by silica gel column and recrystallized to give a required compound.

Sub 1+Sub 2 Synthesis:

Sub 1 (100 mmol) and dibromo diphenyl (156 g, 50 mmol) were mixed with toluene (1000 mL), and added with Pd(dba)2 (3 g, 7 mmol), P(t-Bu)3 (0.7 g, 3.5 mol), and NaOtBu (14.8 g, 150 mmol), followed by reflux-stirring for 24 hours.

After the reaction was completed, the reaction product was extracted with ether and water. The organic layer was dried with MgSO₄ and concentrated. Then, the produced organic layer was purified by silica gel column and recrystallized to give a required compound.

Then, the compound (50 mmol) was added with Sub 2 (50 mmol), Pd(dba)2 (3 g, 7 mmol), P(t-Bu)3 (0.7 g, 3.5 mol), and NaOtBu (14.8 g, 150 mmol), followed by reflux-stirring for 24 hours.

After the reaction was completed, the reaction product was extracted with ether and water. The organic layer was dried with MgSO₄ and concentrated. Then, the produced organic layer was purified by silica gel column and recrystallized to give a required compound.

Then, the compound was measured by HRMS [m/z 956.71 (M+)].

Compound (1-2-2-7) Synthesis Method.

Sub 1 synthesis was carried out in the same manner as described in Sub 1 synthesis used in the synthesis method of the compound (1-2-2-1).

Sub 2 Synthesis:

A-7N (200 mmol) and bromodiphenylfluorene (DPF-Br) (79.4 g 200 mmol) were mixed with toluene (1000 mL), and added with Pd(dba)2 (6 g, 14 mmol), P(t-Bu)3 (1.4 g, 7 mol), and NaOtBu (29.6 g, 300 mmol), followed by reflux-stirring for 24 hours. After the reaction was completed, the reaction product was extracted with ether and water. The organic layer was dried with MgSO₄ and concentrated. Then, the produced organic layer was purified by silica gel column and recrystallized to give a required compound.

Sub 1+Sub 2 Synthesis:

Sub 1 (100 mmol) and dibromo diphenyl (156 g, 50 mmol) were mixed with toluene (1000 mL), and added with Pd(dba)2 (3 g, 7 mmol), P(t-Bu)3 (0.7 g, 3.5 mol), and NaOtBu (14.8 g, 150 mmol), followed by reflux-stirring for 24 hours.

After the reaction was completed, the reaction product was extracted with ether and water. The organic layer was dried with MgSO₄ and concentrated. Then, the produced organic layer was purified by silica gel column and recrystallized to give a required compound.

Then, the compound (50 mmol) was added with Sub 2 (50 mmol), Pd(dba)2 (3 g, 7 mmol), P(t-Bu)3 (0.7 g, 3.5 mol), and NaOtBu (14.8 g, 150 mmol), followed by reflux-stirring for 24 hours.

After the reaction was completed, the reaction product was extracted with ether and water. The organic layer was dried with MgSO₄ and concentrated. Then, the produced organic layer was purified by silica gel column and recrystallized to give a required compound.

Then, the compound was measured by HRMS [m/z 956.44 (M+)].

Compound (1-2-2-8) Synthesis Method.

Sub 1 synthesis was carried out in the same manner as described in Sub 1 synthesis used in the synthesis method of the compound (1-2-2-1).

Sub 2 Synthesis:

A-7N (200 mmol) and bromodiphenylfluorene (DPF-Br) (79.4 g 200 mmol) were mixed with toluene (1000 mL), and added with Pd(dba)2 (6 g, 14 mmol), P(t-Bu)3 (1.4 g, 7 mol), and NaOtBu (29.6 g, 300 mmol), followed by reflux-stirring for 24 hours. After the reaction was completed, the reaction product was extracted with ether and water. The organic layer was dried with MgSO₄ and concentrated. Then, the produced organic layer was purified by silica gel column and recrystallized to give a required compound.

Sub 1+Sub 2 Synthesis:

Sub 1 (100 mmol) and dibromo diphenyl (156 g, 50 mmol) were mixed with toluene (1000 mL), and added with Pd(dba)2 (3 g, 7 mmol), P(t-Bu)3 (0.7 g, 3.5 mol), and NaOtBu (14.8 g, 150 mmol), followed by reflux-stirring for 24 hours.

After the reaction was completed, the reaction product was extracted with ether and water. The organic layer was dried with MgSO₄ and concentrated. Then, the produced organic layer was purified by silica gel column and recrystallized to give a required compound.

Then, the compound (50 mmol) was added with Sub 2 (50 mmol), Pd(dba)2 (3 g, 7 mmol), P(t-Bu)3 (0.7 g, 3.5 mol), and NaOtBu (14.8 g, 150 mmol), followed by reflux-stirring for 24 hours.

After the reaction was completed, the reaction product was extracted with ether and water. The organic layer was dried with MgSO₄ and concentrated. Then, the produced organic layer was purified by silica gel column and recrystallized to give a required compound.

Then, the compound was measured by HRMS [m/z 956.65 (M+)].

Compound (1-2-3-1) Synthesis Method.

Sub 1 synthesis:

amino compound (A-2N, amino compound) (200 mmol) and bromo compound (A-3B, 200 mmol) were mixed with toluene (1000 mL), and added with Pd(dba)2 (6 g, 14 mmol), P(t-Bu)3 (1.4 g, 7 mol), and NaOtBu (29.6 g, 300 mmol), followed by reflux-stirring for 24 hours. After the reaction was completed, the reaction product was extracted with ether and water. The organic layer was dried with MgSO₄ and concentrated. Then, the produced organic layer was purified by silica gel column and recrystallized to give a required compound.

Sub 2 Synthesis:

A-1N (200 mmol) and bromodiphenylfluorene (DPF-Br) (79.4 g 200 mmol) were mixed with toluene (1000 mL), and added with Pd(dba)2 (6 g, 14 mmol), P(t-Bu)3 (1.4 g, 7 mol), and NaOtBu (29.6 g, 300 mmol), followed by reflux-stirring for 24 hours. After the reaction was completed, the reaction product was extracted with ether and water. The organic layer was dried with MgSO₄ and concentrated. Then, the produced organic layer was purified by silica gel column and recrystallized to give a required compound.

Sub 1+Sub 2 Synthesis:

Sub 1 (100 mmol) and dibromo diphenyl (156 g, 50 mmol) were mixed with toluene (1000 mL), and added with Pd(dba)2 (3 g, 7 mmol), P(t-Bu)3 (0.7 g, 3.5 mol), and NaOtBu (14.8 g, 150 mmol), followed by reflux-stirring for 24 hours.

After the reaction was completed, the reaction product was extracted with ether and water. The organic layer was dried with MgSO₄ and concentrated. Then, the produced organic layer was purified by silica gel column and recrystallized to give a required compound.

Then, the compound (50 mmol) was added with Sub 2 (50 mmol), Pd(dba)2 (3 g, 7 mmol), P(t-Bu)3 (0.7 g, 3.5 mol), and NaOtBu (14.8 g, 150 mmol), followed by reflux-stirring for 24 hours.

After the reaction was completed, the reaction product was extracted with ether and water. The organic layer was dried with MgSO₄ and concentrated. Then, the produced organic layer was purified by silica gel column and recrystallized to give a required compound.

Then, the compound was measured by HRMS [m/z 830.17 (M+)].

Compound (1-2-3-2) Synthesis Method.

Sub 1 synthesis was carried out in the same manner as described in Sub 1 synthesis used in the synthesis method of the compound (1-2-3-1).

Sub 2 Synthesis:

A-2N (200 mmol) and bromodiphenylfluorene (DPF-Br) (79.4 g 200 mmol) were mixed with toluene (1000 mL), and added with Pd(dba)2 (6 g, 14 mmol), P(t-Bu)3 (1.4 g, 7 mol), and NaOtBu (29.6 g, 300 mmol), followed by reflux-stirring for 24 hours. After the reaction was completed, the reaction product was extracted with ether and water. The organic layer was dried with MgSO₄ and concentrated. Then, the produced organic layer was purified by silica gel column and recrystallized to give a required compound.

Sub 1+Sub 2 Synthesis:

Sub 1 (100 mmol) and dibromo diphenyl (156 g, 50 mmol) were mixed with toluene (1000 mL), and added with Pd(dba)2 (3 g, 7 mmol), P(t-Bu)3 (0.7 g, 3.5 mol), and NaOtBu (14.8 g, 150 mmol), followed by reflux-stirring for 24 hours.

After the reaction was completed, the reaction product was extracted with ether and water. The organic layer was dried with MgSO₄ and concentrated. Then, the produced organic layer was purified by silica gel column and recrystallized to give a required compound.

Then, the compound (50 mmol) was added with Sub 2 (50 mmol), Pd(dba)2 (3 g, 7 mmol), P(t-Bu)3 (0.7 g, 3.5 mol), and NaOtBu (14.8 g, 150 mmol), followed by reflux-stirring for 24 hours.

After the reaction was completed, the reaction product was extracted with ether and water. The organic layer was dried with MgSO₄ and concentrated. Then, the produced organic layer was purified by silica gel column and recrystallized to give a required compound.

Then, the compound was measured by HRMS [m/z 880.17 (M+)].

Compound (1-2-3-3) Synthesis Method.

Sub 1 synthesis was carried out in the same manner as described in Sub 1 synthesis used in the synthesis method of the compound (1-2-3-1).

Sub 2 Synthesis:

A-3N (200 mmol) and bromodiphenylfluorene (DPF-Br) (79.4 g 200 mmol) were mixed with toluene (1000 mL), and added with Pd(dba)2 (6 g, 14 mmol), P(t-Bu)3 (1.4 g, 7 mol), and NaOtBu (29.6 g, 300 mmol), followed by reflux-stirring for 24 hours. After the reaction was completed, the reaction product was extracted with ether and water. The organic layer was dried with MgSO₄ and concentrated. Then, the produced organic layer was purified by silica gel column and recrystallized to give a required compound.

Sub 1+Sub 2 Synthesis:

Sub 1 (100 mmol) and dibromo diphenyl (156 g, 50 mmol) were mixed with toluene (1000 mL), and added with Pd(dba)2 (3 g, 7 mmol), P(t-Bu)3 (0.7 g, 3.5 mol), and NaOtBu (14.8 g, 150 mmol), followed by reflux-stirring for 24 hours.

After the reaction was completed, the reaction product was extracted with ether and water. The organic layer was dried with MgSO₄ and concentrated. Then, the produced organic layer was purified by silica gel column and recrystallized to give a required compound.

Then, the compound (50 mmol) was added with Sub 2 (50 mmol), Pd(dba)2 (3 g, 7 mmol), P(t-Bu)3 (0.7 g, 3.5 mol), and NaOtBu (14.8 g, 150 mmol), followed by reflux-stirring for 24 hours.

After the reaction was completed, the reaction product was extracted with ether and water. The organic layer was dried with MgSO₄ and concentrated. Then, the produced organic layer was purified by silica gel column and recrystallized to give a required compound.

Then, the compound was measured by HRMS [m/z 880.52 (M+)].

Compound (1-2-3-4) Synthesis Method.

Sub 1 synthesis was carried out in the same manner as described in Sub 1 synthesis used in the synthesis method of the compound (1-2-3-1).

Sub 2 Synthesis:

A-4N (200 mmol) and bromodiphenylfluorene (DPF-Br) (79.4 g 200 mmol) were mixed with toluene (1000 mL), and added with Pd(dba)2 (6 g, 14 mmol), P(t-Bu)3 (1.4 g, 7 mol), and NaOtBu (29.6 g, 300 mmol), followed by reflux-stirring for 24 hours. After the reaction was completed, the reaction product was extracted with ether and water. The organic layer was dried with MgSO₄ and concentrated. Then, the produced organic layer was purified by silica gel column and recrystallized to give a required compound.

Sub 1+Sub 2 Synthesis:

Sub 1 (100 mmol) and dibromo diphenyl (156 g, 50 mmol) were mixed with toluene (1000 mL), and added with Pd(dba)2 (3 g, 7 mmol), P(t-Bu)3 (0.7 g, 3.5 mol), and NaOtBu (14.8 g, 150 mmol), followed by reflux-stirring for 24 hours.

After the reaction was completed, the reaction product was extracted with ether and water. The organic layer was dried with MgSO₄ and concentrated. Then, the produced organic layer was purified by silica gel column and recrystallized to give a required compound.

Then, the compound (50 mmol) was added with Sub 2 (50 mmol), Pd(dba)2 (3 g, 7 mmol), P(t-Bu)3 (0.7 g, 3.5 mol), and NaOtBu (14.8 g, 150 mmol), followed by reflux-stirring for 24 hours.

After the reaction was completed, the reaction product was extracted with ether and water. The organic layer was dried with MgSO₄ and concentrated. Then, the produced organic layer was purified by silica gel column and recrystallized to give a required compound.

Then, the compound was measured by HRMS [m/z 907.05 (M+)].

Compound (1-2-3-5) Synthesis Method.

Sub 1 synthesis was carried out in the same manner as described in Sub 1 synthesis used in the synthesis method of the compound (1-2-3-1).

Sub 2 Synthesis:

A-5N (200 mmol) and bromodiphenylfluorene (DPF-Br) (79.4 g 200 mmol) were mixed with toluene (1000 mL), and added with Pd(dba)2 (6 g, 14 mmol), P(t-Bu)3 (1.4 g, 7 mol), and NaOtBu (29.6 g, 300 mmol), followed by reflux-stirring for 24 hours. After the reaction was completed, the reaction product was extracted with ether and water. The organic layer was dried with MgSO₄ and concentrated. Then, the produced organic layer was purified by silica gel column and recrystallized to give a required compound.

Sub 1+Sub 2 Synthesis:

Sub 1 (100 mmol) and dibromo diphenyl (156 g, 50 mmol) were mixed with toluene (1000 mL), and added with Pd(dba)2 (3 g, 7 mmol), P(t-Bu)3 (0.7 g, 3.5 mol), and NaOtBu (14.8 g, 150 mmol), followed by reflux-stirring for 24 hours.

After the reaction was completed, the reaction product was extracted with ether and water. The organic layer was dried with MgSO₄ and concentrated. Then, the produced organic layer was purified by silica gel column and recrystallized to give a required compound.

Then, the compound (50 mmol) was added with Sub 2 (50 mmol), Pd(dba)2 (3 g, 7 mmol), P(t-Bu)3 (0.7 g, 3.5 mol), and NaOtBu (14.8 g, 150 mmol), followed by reflux-stirring for 24 hours.

After the reaction was completed, the reaction product was extracted with ether and water. The organic layer was dried with MgSO₄ and concentrated. Then, the produced organic layer was purified by silica gel column and recrystallized to give a required compound.

Then, the compound was measured by HRMS [m/z 956.22 (M+)].

Compound (1-2-3-6) Synthesis Method.

Sub 1 synthesis was carried out in the same manner as described in Sub 1 synthesis used in the synthesis method of the compound (1-2-3-1).

Sub 2 Synthesis:

A-6N (200 mmol) and bromodiphenylfluorene (DPF-Br) (79.4 g 200 mmol) were mixed with toluene (1000 mL), and added with Pd(dba)2 (6 g, 14 mmol), P(t-Bu)3 (1.4 g, 7 mol), and NaOtBu (29.6 g, 300 mmol), followed by reflux-stirring for 24 hours. After the reaction was completed, the reaction product was extracted with ether and water. The organic layer was dried with MgSO₄ and concentrated. Then, the produced organic layer was purified by silica gel column and recrystallized to give a required compound.

Sub 1+Sub 2 Synthesis:

Sub 1 (100 mmol) and dibromo diphenyl (156 g, 50 mmol) were mixed with toluene (1000 mL), and added with Pd(dba)2 (3 g, 7 mmol), P(t-Bu)3 (0.7 g, 3.5 mol), and NaOtBu (14.8 g, 150 mmol), followed by reflux-stirring for 24 hours.

After the reaction was completed, the reaction product was extracted with ether and water. The organic layer was dried with MgSO₄ and concentrated. Then, the produced organic layer was purified by silica gel column and recrystallized to give a required compound.

Then, the compound (50 mmol) was added with Sub 2 (50 mmol), Pd(dba)2 (3 g, 7 mmol), P(t-Bu)3 (0.7 g, 3.5 mol), and NaOtBu (14.8 g, 150 mmol), followed by reflux-stirring for 24 hours.

After the reaction was completed, the reaction product was extracted with ether and water. The organic layer was dried with MgSO₄ and concentrated. Then, the produced organic layer was purified by silica gel column and recrystallized to give a required compound.

Then, the compound was measured by HRMS [m/z 956.76 (M+)].

Compound (1-2-3-7) Synthesis Method.

Sub 1 synthesis was carried out in the same manner as described in Sub 1 synthesis used in the synthesis method of the compound (1-2-3-1).

Sub 2 Synthesis:

A-7N (200 mmol) and bromodiphenylfluorene (DPF-Br) (79.4 g 200 mmol) were mixed with toluene (1000 mL), and added with Pd(dba)2 (6 g, 14 mmol), P(t-Bu)3 (1.4 g, 7 mol), and NaOtBu (29.6 g, 300 mmol), followed by reflux-stirring for 24 hours. After the reaction was completed, the reaction product was extracted with ether and water. The organic layer was dried with MgSO₄ and concentrated. Then, the produced organic layer was purified by silica gel column and recrystallized to give a required compound.

Sub 1+Sub 2 Synthesis:

Sub 1 (100 mmol) and dibromo diphenyl (156 g, 50 mmol) were mixed with toluene (1000 mL), and added with Pd(dba)2 (3 g, 7 mmol), P(t-Bu)3 (0.7 g, 3.5 mol), and NaOtBu (14.8 g, 150 mmol), followed by reflux-stirring for 24 hours.

After the reaction was completed, the reaction product was extracted with ether and water. The organic layer was dried with MgSO₄ and concentrated. Then, the produced organic layer was purified by silica gel column and recrystallized to give a required compound.

Then, the compound (50 mmol) was added with Sub 2 (50 mmol), Pd(dba)2 (3 g, 7 mmol), P(t-Bu)3 (0.7 g, 3.5 mol), and NaOtBu (14.8 g, 150 mmol), followed by reflux-stirring for 24 hours.

After the reaction was completed, the reaction product was extracted with ether and water. The organic layer was dried with MgSO₄ and concentrated. Then, the produced organic layer was purified by silica gel column and recrystallized to give a required compound.

Then, the compound was measured by HRMS [m/z 956.10 (M+)].

Compound (1-2-3-8) Synthesis Method.

Sub 1 synthesis was carried out in the same manner as described in Sub 1 synthesis used in the synthesis method of the compound (1-2-3-1).

Sub 2 Synthesis:

A-8N (200 mmol) and bromodiphenylfluorene (DPF-Br) (79.4 g 200 mmol) were mixed with toluene (1000 mL), and added with Pd(dba)2 (6 g, 14 mmol), P(t-Bu)3 (1.4 g, 7 mol), and NaOtBu (29.6 g, 300 mmol), followed by reflux-stirring for 24 hours. After the reaction was completed, the reaction product was extracted with ether and water. The organic layer was dried with MgSO₄ and concentrated. Then, the produced organic layer was purified by silica gel column and recrystallized to give a required compound.

Sub 1+Sub 2 Synthesis:

Sub 1 (100 mmol) and dibromo diphenyl (156 g, 50 mmol) were mixed with toluene (1000 mL), and added with Pd(dba)2 (3 g, 7 mmol), P(t-Bu)3 (0.7 g, 3.5 mol), and NaOtBu (14.8 g, 150 mmol), followed by reflux-stirring for 24 hours.

After the reaction was completed, the reaction product was extracted with ether and water. The organic layer was dried with MgSO₄ and concentrated. Then, the produced organic layer was purified by silica gel column and recrystallized to give a required compound.

Then, the compound (50 mmol) was added with Sub 2 (50 mmol), Pd(dba)2 (3 g, 7 mmol), P(t-Bu)3 (0.7 g, 3.5 mol), and NaOtBu (14.8 g, 150 mmol), followed by reflux-stirring for 24 hours.

After the reaction was completed, the reaction product was extracted with ether and water. The organic layer was dried with MgSO₄ and concentrated. Then, the produced organic layer was purified by silica gel column and recrystallized to give a required compound.

Then, the compound was measured by HRMS [m/z 956.55 (M+)].

Compound (1-2-4-1) Synthesis Method.

Sub 1 synthesis:

amino compound (A-2N, amino compound) (200 mmol) and bromo compound (A-4B, 200 mmol) were mixed with toluene (1000 mL), and added with Pd(dba)2 (6 g, 14 mmol), P(t-Bu)3 (1.4 g, 7 mol), and NaOtBu (29.6 g, 300 mmol), followed by reflux-stirring for 24 hours. After the reaction was completed, the reaction product was extracted with ether and water. The organic layer was dried with MgSO₄ and concentrated. Then, the produced organic layer was purified by silica gel column and recrystallized to give a required compound.

Sub 2 Synthesis:

A-1N (200 mmol) and bromodiphenylfluorene (DPF-Br) (79.4 g 200 mmol) were mixed with toluene (1000 mL), and added with Pd(dba)2 (6 g, 14 mmol), P(t-Bu)3 (1.4 g, 7 mol), and NaOtBu (29.6 g, 300 mmol), followed by reflux-stirring for 24 hours. After the reaction was completed, the reaction product was extracted with ether and water. The organic layer was dried with MgSO₄ and concentrated. Then, the produced organic layer was purified by silica gel column and recrystallized to give a required compound.

Sub 1+Sub 2 Synthesis:

Sub 1 (100 mmol) and dibromo diphenyl (156 g, 50 mmol) were mixed with toluene (1000 mL), and added with Pd(dba)2 (3 g, 7 mmol), P(t-Bu)3 (0.7 g, 3.5 mol), and NaOtBu (14.8 g, 150 mmol), followed by reflux-stirring for 24 hours.

After the reaction was completed, the reaction product was extracted with ether and water. The organic layer was dried with MgSO₄ and concentrated. Then, the produced organic layer was purified by silica gel column and recrystallized to give a required compound.

Then, the compound (50 mmol) was added with Sub 2 (50 mmol), Pd(dba)2 (3 g, 7 mmol), P(t-Bu)3 (0.7 g, 3.5 mol), and NaOtBu (14.8 g, 150 mmol), followed by reflux-stirring for 24 hours.

After the reaction was completed, the reaction product was extracted with ether and water. The organic layer was dried with MgSO₄ and concentrated. Then, the produced organic layer was purified by silica gel column and recrystallized to give a required compound.

Then, the compound was measured by HRMS [m/z 856.01 (M+)].

Compound (1-2-4-2) Synthesis Method.

Sub 1 synthesis was carried out in the same manner as described in Sub 1 synthesis used in the synthesis method of the compound (1-2-4-1).

Sub 2 Synthesis:

A-2N (200 mmol) and bromodiphenylfluorene (DPF-Br) (79.4 g 200 mmol) were mixed with toluene (1000 mL), and added with Pd(dba)2 (6 g, 14 mmol), P(t-Bu)3 (1.4 g, 7 mol), and NaOtBu (29.6 g, 300 mmol), followed by reflux-stirring for 24 hours. After the reaction was completed, the reaction product was extracted with ether and water. The organic layer was dried with MgSO₄ and concentrated. Then, the produced organic layer was purified by silica gel column and recrystallized to give a required compound.

Sub 1+Sub 2 Synthesis:

Sub 1 (100 mmol) and dibromo diphenyl (156 g, 50 mmol) were mixed with toluene (1000 mL), and added with Pd(dba)2 (3 g, 7 mmol), P(t-Bu)3 (0.7 g, 3.5 mol), and NaOtBu (14.8 g, 150 mmol), followed by reflux-stirring for 24 hours.

After the reaction was completed, the reaction product was extracted with ether and water. The organic layer was dried with MgSO₄ and concentrated. Then, the produced organic layer was purified by silica gel column and recrystallized to give a required compound.

Then, the compound (50 mmol) was added with Sub 2 (50 mmol), Pd(dba)2 (3 g, 7 mmol), P(t-Bu)3 (0.7 g, 3.5 mol), and NaOtBu (14.8 g, 150 mmol), followed by reflux-stirring for 24 hours.

After the reaction was completed, the reaction product was extracted with ether and water. The organic layer was dried with MgSO₄ and concentrated. Then, the produced organic layer was purified by silica gel column and recrystallized to give a required compound.

Then, the compound was measured by HRMS [m/z 906.55 (M+)].

Compound (1-2-4-3) Synthesis Method.

Sub 1 synthesis was carried out in the same manner as described in Sub 1 synthesis used in the synthesis method of the compound (1-2-4-1).

Sub 2 Synthesis:

A-3N (200 mmol) and bromodiphenylfluorene (DPF-Br) (79.4 g 200 mmol) were mixed with toluene (1000 mL), and added with Pd(dba)2 (6 g, 14 mmol), P(t-Bu)3 (1.4 g, 7 mol), and NaOtBu (29.6 g, 300 mmol), followed by reflux-stirring for 24 hours. After the reaction was completed, the reaction product was extracted with ether and water. The organic layer was dried with MgSO₄ and concentrated. Then, the produced organic layer was purified by silica gel column and recrystallized to give a required compound.

Sub 1+Sub 2 Synthesis:

Sub 1 (100 mmol) and dibromo diphenyl (156 g, 50 mmol) were mixed with toluene (1000 mL), and added with Pd(dba)2 (3 g, 7 mmol), P(t-Bu)3 (0.7 g, 3.5 mol), and NaOtBu (14.8 g, 150 mmol), followed by reflux-stirring for 24 hours.

After the reaction was completed, the reaction product was extracted with ether and water. The organic layer was dried with MgSO₄ and concentrated. Then, the produced organic layer was purified by silica gel column and recrystallized to give a required compound.

Then, the compound (50 mmol) was added with Sub 2 (50 mmol), Pd(dba)2 (3 g, 7 mmol), P(t-Bu)3 (0.7 g, 3.5 mol), and NaOtBu (14.8 g, 150 mmol), followed by reflux-stirring for 24 hours.

After the reaction was completed, the reaction product was extracted with ether and water. The organic layer was dried with MgSO₄ and concentrated. Then, the produced organic layer was purified by silica gel column and recrystallized to give a required compound.

Then, the compound was measured by HRMS [m/z 906.71 (M+)].

Compound (1-2-4-4) Synthesis Method.

Sub 1 synthesis was carried out in the same manner as described in Sub 1 synthesis used in the synthesis method of the compound (1-2-4-1).

Sub 2 Synthesis:

A-4N (200 mmol) and bromodiphenylfluorene (DPF-Br) (79.4 g 200 mmol) were mixed with toluene (1000 mL), and added with Pd(dba)2 (6 g, 14 mmol), P(t-Bu)3 (1.4 g, 7 mol), and NaOtBu (29.6 g, 300 mmol), followed by reflux-stirring for 24 hours. After the reaction was completed, the reaction product was extracted with ether and water. The organic layer was dried with MgSO₄ and concentrated. Then, the produced organic layer was purified by silica gel column and recrystallized to give a required compound.

Sub 1+Sub 2 Synthesis:

Sub 1 (100 mmol) and dibromo diphenyl (156 g, 50 mmol) were mixed with toluene (1000 mL), and added with Pd(dba)2 (3 g, 7 mmol), P(t-Bu)3 (0.7 g, 3.5 mol), and NaOtBu (14.8 g, 150 mmol), followed by reflux-stirring for 24 hours.

After the reaction was completed, the reaction product was extracted with ether and water. The organic layer was dried with MgSO₄ and concentrated. Then, the produced organic layer was purified by silica gel column and recrystallized to give a required compound.

Then, the compound (50 mmol) was added with Sub 2 (50 mmol), Pd(dba)2 (3 g, 7 mmol), P(t-Bu)3 (0.7 g, 3.5 mol), and NaOtBu (14.8 g, 150 mmol), followed by reflux-stirring for 24 hours.

After the reaction was completed, the reaction product was extracted with ether and water. The organic layer was dried with MgSO₄ and concentrated. Then, the produced organic layer was purified by silica gel column and recrystallized to give a required compound.

Then, the compound was measured by HRMS [m/z 933.01 (M+)].

Compound (1-2-4-5) Synthesis Method.

Sub 1 synthesis was carried out in the same manner as described in Sub 1 synthesis used in the synthesis method of the compound (1-2-4-1).

Sub 2 Synthesis:

A-5N (200 mmol) and bromodiphenylfluorene (DPF-Br) (79.4 g 200 mmol) were mixed with toluene (1000 mL), and added with Pd(dba)2 (6 g, 14 mmol), P(t-Bu)3 (1.4 g, 7 mol), and NaOtBu (29.6 g, 300 mmol), followed by reflux-stirring for 24 hours. After the reaction was completed, the reaction product was extracted with ether and water. The organic layer was dried with MgSO₄ and concentrated. Then, the produced organic layer was purified by silica gel column and recrystallized to give a required compound.

Sub 1+Sub 2 Synthesis:

Sub 1 (100 mmol) and dibromo diphenyl (156 g, 50 mmol) were mixed with toluene (1000 mL), and added with Pd(dba)2 (3 g, 7 mmol), P(t-Bu)3 (0.7 g, 3.5 mol), and NaOtBu (14.8 g, 150 mmol), followed by reflux-stirring for 24 hours.

After the reaction was completed, the reaction product was extracted with ether and water. The organic layer was dried with MgSO₄ and concentrated. Then, the produced organic layer was purified by silica gel column and recrystallized to give a required compound.

Then, the compound (50 mmol) was added with Sub 2 (50 mmol), Pd(dba)2 (3 g, 7 mmol), P(t-Bu)3 (0.7 g, 3.5 mol), and NaOtBu (14.8 g, 150 mmol), followed by reflux-stirring for 24 hours.

After the reaction was completed, the reaction product was extracted with ether and water. The organic layer was dried with MgSO₄ and concentrated. Then, the produced organic layer was purified by silica gel column and recrystallized to give a required compound.

Then, the compound was measured by HRMS [m/z 983.01 (M+)].

Compound (1-2-4-6) Synthesis Method.

Sub 1 synthesis was carried out in the same manner as described in Sub 1 synthesis used in the synthesis method of the compound (1-2-4-1).

Sub 2 Synthesis:

A-6N (200 mmol) and bromodiphenylfluorene (DPF-Br) (79.4 g 200 mmol) were mixed with toluene (1000 mL), and added with Pd(dba)2 (6 g, 14 mmol), P(t-Bu)3 (1.4 g, 7 mol), and NaOtBu (29.6 g, 300 mmol), followed by reflux-stirring for 24 hours. After the reaction was completed, the reaction product was extracted with ether and water. The organic layer was dried with MgSO₄ and concentrated. Then, the produced organic layer was purified by silica gel column and recrystallized to give a required compound.

Sub 1+Sub 2 Synthesis:

Sub 1 (100 mmol) and dibromo diphenyl (156 g, 50 mmol) were mixed with toluene (1000 mL), and added with Pd(dba)2 (3 g, 7 mmol), P(t-Bu)3 (0.7 g, 3.5 mol), and NaOtBu (14.8 g, 150 mmol), followed by reflux-stirring for 24 hours.

After the reaction was completed, the reaction product was extracted with ether and water. The organic layer was dried with MgSO₄ and concentrated. Then, the produced organic layer was purified by silica gel column and recrystallized to give a required compound.

Then, the compound (50 mmol) was added with Sub 2 (50 mmol), Pd(dba)2 (3 g, 7 mmol), P(t-Bu)3 (0.7 g, 3.5 mol), and NaOtBu (14.8 g, 150 mmol), followed by reflux-stirring for 24 hours.

After the reaction was completed, the reaction product was extracted with ether and water. The organic layer was dried with MgSO₄ and concentrated. Then, the produced organic layer was purified by silica gel column and recrystallized to give a required compound.

Then, the compound was measured by HRMS [m/z 982.01 (M+)].

Compound (1-2-4-7) Synthesis Method.

Sub 1 synthesis was carried out in the same manner as described in Sub 1 synthesis used in the synthesis method of the compound (1-2-4-1).

Sub 2 Synthesis:

A-7N (200 mmol) and bromodiphenylfluorene (DPF-Br) (79.4 g 200 mmol) were mixed with toluene (1000 mL), and added with Pd(dba)2 (6 g, 14 mmol), P(t-Bu)3 (1.4 g, 7 mol), and NaOtBu (29.6 g, 300 mmol), followed by reflux-stirring for 24 hours. After the reaction was completed, the reaction product was extracted with ether and water. The organic layer was dried with MgSO₄ and concentrated. Then, the produced organic layer was purified by silica gel column and recrystallized to give a required compound.

Sub 1+Sub 2 Synthesis:

Sub 1 (100 mmol) and dibromo diphenyl (156 g, 50 mmol) were mixed with toluene (1000 mL), and added with Pd(dba)2 (3 g, 7 mmol), P(t-Bu)3 (0.7 g, 3.5 mol), and NaOtBu (14.8 g, 150 mmol), followed by reflux-stirring for 24 hours.

After the reaction was completed, the reaction product was extracted with ether and water. The organic layer was dried with MgSO₄ and concentrated. Then, the produced organic layer was purified by silica gel column and recrystallized to give a required compound.

Then, the compound (50 mmol) was added with Sub 2 (50 mmol), Pd(dba)2 (3 g, 7 mmol), P(t-Bu)3 (0.7 g, 3.5 mol), and NaOtBu (14.8 g, 150 mmol), followed by reflux-stirring for 24 hours.

After the reaction was completed, the reaction product was extracted with ether and water. The organic layer was dried with MgSO₄ and concentrated. Then, the produced organic layer was purified by silica gel column and recrystallized to give a required compound.

Then, the compound was measured by HRMS [m/z 982.91 (M+)].

Compound (1-2-4-8) Synthesis Method.

Sub 1 synthesis was carried out in the same manner as described in Sub 1 synthesis used in the synthesis method of the compound (1-2-4-1).

Sub 2 Synthesis:

A-8N (200 mmol) and bromodiphenylfluorene (DPF-Br) (79.4 g 200 mmol) were mixed with toluene (1000 mL), and added with Pd(dba)2 (6 g, 14 mmol), P(t-Bu)3 (1.4 g, 7 mol), and NaOtBu (29.6 g, 300 mmol), followed by reflux-stirring for 24 hours. After the reaction was completed, the reaction product was extracted with ether and water. The organic layer was dried with MgSO₄ and concentrated. Then, the produced organic layer was purified by silica gel column and recrystallized to give a required compound.

Sub 1+Sub 2 Synthesis:

Sub 1 (100 mmol) and dibromo diphenyl (156 g, 50 mmol) were mixed with toluene (1000 mL), and added with Pd(dba)2 (3 g, 7 mmol), P(t-Bu)3 (0.7 g, 3.5 mol), and NaOtBu (14.8 g, 150 mmol), followed by reflux-stirring for 24 hours.

After the reaction was completed, the reaction product was extracted with ether and water. The organic layer was dried with MgSO₄ and concentrated. Then, the produced organic layer was purified by silica gel column and recrystallized to give a required compound.

Then, the compound (50 mmol) was added with Sub 2 (50 mmol), Pd(dba)2 (3 g, 7 mmol), P(t-Bu)3 (0.7 g, 3.5 mol), and NaOtBu (14.8 g, 150 mmol), followed by reflux-stirring for 24 hours.

After the reaction was completed, the reaction product was extracted with ether and water. The organic layer was dried with MgSO₄ and concentrated. Then, the produced organic layer was purified by silica gel column and recrystallized to give a required compound.

Then, the compound was measured by HRMS [m/z 982.91 (M+)].

Compound (1-3-3-1) Synthesis Method.

Sub 1 Synthesis:

Amino compound (A-3N, amino compound) (200 mmol) and bromo compound (A-3B, 200 mmol) were mixed with toluene (1000 mL), and added with Pd(dba)2 (6 g, 14 mmol), P(t-Bu)3 (1.4 g, 7 mol), and NaOtBu (29.6 g, 300 mmol), followed by reflux-stirring for 24 hours. After the reaction was completed, the reaction product was extracted with ether and water. The organic layer was dried with MgSO₄ and concentrated. Then, the produced organic layer was purified by silica gel column and recrystallized to give a required compound.

Sub 2 Synthesis:

A-1N (200 mmol) and bromodiphenylfluorene (DPF-Br) (79.4 g 200 mmol) were mixed with toluene (1000 mL), and added with Pd(dba)2 (6 g, 14 mmol), P(t-Bu)3 (1.4 g, 7 mol), and NaOtBu (29.6 g, 300 mmol), followed by reflux-stirring for 24 hours. After the reaction was completed, the reaction product was extracted with ether and water. The organic layer was dried with MgSO₄ and concentrated. Then, the produced organic layer was purified by silica gel column and recrystallized to give a required compound.

Sub 1+Sub 2 Synthesis:

Sub 1 (100 mmol) and dibromo diphenyl (156 g, 50 mmol) were mixed with toluene (1000 mL), and added with Pd(dba)2 (3 g, 7 mmol), P(t-Bu)3 (0.7 g, 3.5 mol), and NaOtBu (14.8 g, 150 mmol), followed by reflux-stirring for 24 hours.

After the reaction was completed, the reaction product was extracted with ether and water. The organic layer was dried with MgSO₄ and concentrated. Then, the produced organic layer was purified by silica gel column and recrystallized to give a required compound.

Then, the compound (50 mmol) was added with Sub 2 (50 mmol), Pd(dba)2 (3 g, 7 mmol), P(t-Bu)3 (0.7 g, 3.5 mol), and NaOtBu (14.8 g, 150 mmol), followed by reflux-stirring for 24 hours.

After the reaction was completed, the reaction product was extracted with ether and water. The organic layer was dried with MgSO₄ and concentrated. Then, the produced organic layer was purified by silica gel column and recrystallized to give a required compound.

Then, the compound was measured by HRMS [m/z 830.21 (M+)].

Compound (1-3-3-2) Synthesis Method.

Sub 1 synthesis was carried out in the same manner as described in Sub 1 synthesis used in the synthesis method of the compound (1-3-3-1).

Sub 2 Synthesis:

A-2N (200 mmol) and bromodiphenylfluorene (DPF-Br) (79.4 g 200 mmol) were mixed with toluene (1000 mL), and added with Pd(dba)2 (6 g, 14 mmol), P(t-Bu)3 (1.4 g, 7 mol), and NaOtBu (29.6 g, 300 mmol), followed by reflux-stirring for 24 hours. After the reaction was completed, the reaction product was extracted with ether and water. The organic layer was dried with MgSO₄ and concentrated. Then, the produced organic layer was purified by silica gel column and recrystallized to give a required compound.

Sub 1+Sub 2 Synthesis:

Sub 1 (100 mmol) and dibromo diphenyl (156 g, 50 mmol) were mixed with toluene (1000 mL), and added with Pd(dba)2 (3 g, 7 mmol), P(t-Bu)3 (0.7 g, 3.5 mol), and NaOtBu (14.8 g, 150 mmol), followed by reflux-stirring for 24 hours.

After the reaction was completed, the reaction product was extracted with ether and water. The organic layer was dried with MgSO₄ and concentrated. Then, the produced organic layer was purified by silica gel column and recrystallized to give a required compound.

Then, the compound (50 mmol) was added with Sub 2 (50 mmol), Pd(dba)2 (3 g, 7 mmol), P(t-Bu)3 (0.7 g, 3.5 mol), and NaOtBu (14.8 g, 150 mmol), followed by reflux-stirring for 24 hours.

After the reaction was completed, the reaction product was extracted with ether and water. The organic layer was dried with MgSO₄ and concentrated. Then, the produced organic layer was purified by silica gel column and recrystallized to give a required compound.

Then, the compound was measured by HRMS [m/z 880.19 (M+)].

Compound (1-3-3-3) Synthesis Method.

Sub 1 synthesis was carried out in the same manner as described in Sub 1 synthesis used in the synthesis method of the compound (1-3-3-1).

Sub 2 Synthesis:

A-3N (200 mmol) and bromodiphenylfluorene (DPF-Br) (79.4 g 200 mmol) were mixed with toluene (1000 mL), and added with Pd(dba)2 (6 g, 14 mmol), P(t-Bu)3 (1.4 g, 7 mol), and NaOtBu (29.6 g, 300 mmol), followed by reflux-stirring for 24 hours. After the reaction was completed, the reaction product was extracted with ether and water. The organic layer was dried with MgSO₄ and concentrated. Then, the produced organic layer was purified by silica gel column and recrystallized to give a required compound.

Sub 1+Sub 2 Synthesis:

Sub 1 (100 mmol) and dibromo diphenyl (156 g, 50 mmol) were mixed with toluene (1000 mL), and added with Pd(dba)2 (3 g, 7 mmol), P(t-Bu)3 (0.7 g, 3.5 mol), and NaOtBu (14.8 g, 150 mmol), followed by reflux-stirring for 24 hours.

After the reaction was completed, the reaction product was extracted with ether and water. The organic layer was dried with MgSO₄ and concentrated. Then, the produced organic layer was purified by silica gel column and recrystallized to give a required compound.

Then, the compound (50 mmol) was added with Sub 2 (50 mmol), Pd(dba)2 (3 g, 7 mmol), P(t-Bu)3 (0.7 g, 3.5 mol), and NaOtBu (14.8 g, 150 mmol), followed by reflux-stirring for 24 hours.

After the reaction was completed, the reaction product was extracted with ether and water. The organic layer was dried with MgSO₄ and concentrated. Then, the produced organic layer was purified by silica gel column and recrystallized to give a required compound.

Then, the compound was measured by HRMS [m/z 880.79 (M+)].

Compound (1-3-3-4) Synthesis Method.

Sub 1 synthesis was carried out in the same manner as described in Sub 1 synthesis used in the synthesis method of the compound (1-3-3-1).

Sub 2 Synthesis:

A-4N (200 mmol) and bromodiphenylfluorene (DPF-Br) (79.4 g 200 mmol) were mixed with toluene (1000 mL), and added with Pd(dba)2 (6 g, 14 mmol), P(t-Bu)3 (1.4 g, 7 mol), and NaOtBu (29.6 g, 300 mmol), followed by reflux-stirring for 24 hours. After the reaction was completed, the reaction product was extracted with ether and water. The organic layer was dried with MgSO₄ and concentrated. Then, the produced organic layer was purified by silica gel column and recrystallized to give a required compound.

Sub 1+Sub 2 Synthesis:

Sub 1 (100 mmol) and dibromo diphenyl (156 g, 50 mmol) were mixed with toluene (1000 mL), and added with Pd(dba)2 (3 g, 7 mmol), P(t-Bu)3 (0.7 g, 3.5 mol), and NaOtBu (14.8 g, 150 mmol), followed by reflux-stirring for 24 hours.

After the reaction was completed, the reaction product was extracted with ether and water. The organic layer was dried with MgSO₄ and concentrated. Then, the produced organic layer was purified by silica gel column and recrystallized to give a required compound.

Then, the compound (50 mmol) was added with Sub 2 (50 mmol), Pd(dba)2 (3 g, 7 mmol), P(t-Bu)3 (0.7 g, 3.5 mol), and NaOtBu (14.8 g, 150 mmol), followed by reflux-stirring for 24 hours.

After the reaction was completed, the reaction product was extracted with ether and water. The organic layer was dried with MgSO₄ and concentrated. Then, the produced organic layer was purified by silica gel column and recrystallized to give a required compound.

Then, the compound was measured by HRMS [m/z 907.10 (M+)].

Compound (1-3-3-5) Synthesis Method.

Sub 1 synthesis was carried out in the same manner as described in Sub 1 synthesis used in the synthesis method of the compound (1-3-3-1).

Sub 2 Synthesis:

A-5N (200 mmol) and bromodiphenylfluorene (DPF-Br) (79.4 g 200 mmol) were mixed with toluene (1000 mL), and added with Pd(dba)2 (6 g, 14 mmol), P(t-Bu)3 (1.4 g, 7 mol), and NaOtBu (29.6 g, 300 mmol), followed by reflux-stirring for 24 hours. After the reaction was completed, the reaction product was extracted with ether and water. The organic layer was dried with MgSO₄ and concentrated. Then, the produced organic layer was purified by silica gel column and recrystallized to give a required compound.

Sub 1+Sub 2 Synthesis:

Sub 1 (100 mmol) and dibromo diphenyl (156 g, 50 mmol) were mixed with toluene (1000 mL), and added with Pd(dba)2 (3 g, 7 mmol), P(t-Bu)3 (0.7 g, 3.5 mol), and NaOtBu (14.8 g, 150 mmol), followed by reflux-stirring for 24 hours.

After the reaction was completed, the reaction product was extracted with ether and water. The organic layer was dried with MgSO₄ and concentrated. Then, the produced organic layer was purified by silica gel column and recrystallized to give a required compound.

Then, the compound (50 mmol) was added with Sub 2 (50 mmol), Pd(dba)2 (3 g, 7 mmol), P(t-Bu)3 (0.7 g, 3.5 mol), and NaOtBu (14.8 g, 150 mmol), followed by reflux-stirring for 24 hours.

After the reaction was completed, the reaction product was extracted with ether and water. The organic layer was dried with MgSO₄ and concentrated. Then, the produced organic layer was purified by silica gel column and recrystallized to give a required compound.

Then, the compound was measured by HRMS [m/z 957.13 (M+)].

Compound (1-3-3-6) Synthesis Method.

Sub 1 synthesis was carried out in the same manner as described in Sub 1 synthesis used in the synthesis method of the compound (1-3-3-1).

Sub 2 Synthesis:

A-6N (200 mmol) and bromodiphenylfluorene (DPF-Br) (79.4 g 200 mmol) were mixed with toluene (1000 mL), and added with Pd(dba)2 (6 g, 14 mmol), P(t-Bu)3 (1.4 g, 7 mol), and NaOtBu (29.6 g, 300 mmol), followed by reflux-stirring for 24 hours. After the reaction was completed, the reaction product was extracted with ether and water. The organic layer was dried with MgSO₄ and concentrated. Then, the produced organic layer was purified by silica gel column and recrystallized to give a required compound.

Sub 1+Sub 2 Synthesis:

Sub 1 (100 mmol) and dibromo diphenyl (156 g, 50 mmol) were mixed with toluene (1000 mL), and added with Pd(dba)2 (3 g, 7 mmol), P(t-Bu)3 (0.7 g, 3.5 mol), and NaOtBu (14.8 g, 150 mmol), followed by reflux-stirring for 24 hours.

After the reaction was completed, the reaction product was extracted with ether and water. The organic layer was dried with MgSO₄ and concentrated. Then, the produced organic layer was purified by silica gel column and recrystallized to give a required compound.

Then, the compound (50 mmol) was added with Sub 2 (50 mmol), Pd(dba)2 (3 g, 7 mmol), P(t-Bu)3 (0.7 g, 3.5 mol), and NaOtBu (14.8 g, 150 mmol), followed by reflux-stirring for 24 hours.

After the reaction was completed, the reaction product was extracted with ether and water. The organic layer was dried with MgSO₄ and concentrated. Then, the produced organic layer was purified by silica gel column and recrystallized to give a required compound.

Then, the compound was measured by HRMS [m/z 956.73 (M+)].

Compound (1-3-3-7) Synthesis Method.

Sub 1 synthesis was carried out in the same manner as described in Sub 1 synthesis used in the synthesis method of the compound (1-3-3-1).

Sub 2 Synthesis:

A-7N (200 mmol) and bromodiphenylfluorene (DPF-Br) (79.4 g 200 mmol) were mixed with toluene (1000 mL), and added with Pd(dba)2 (6 g, 14 mmol), P(t-Bu)3 (1.4 g, 7 mol), and NaOtBu (29.6 g, 300 mmol), followed by reflux-stirring for 24 hours. After the reaction was completed, the reaction product was extracted with ether and water. The organic layer was dried with MgSO₄ and concentrated. Then, the produced organic layer was purified by silica gel column and recrystallized to give a required compound.

Sub 1+Sub 2 Synthesis:

Sub 1 (100 mmol) and dibromo diphenyl (156 g, 50 mmol) were mixed with toluene (1000 mL), and added with Pd(dba)2 (3 g, 7 mmol), P(t-Bu)3 (0.7 g, 3.5 mol), and NaOtBu (14.8 g, 150 mmol), followed by reflux-stirring for 24 hours.

After the reaction was completed, the reaction product was extracted with ether and water. The organic layer was dried with MgSO₄ and concentrated. Then, the produced organic layer was purified by silica gel column and recrystallized to give a required compound.

Then, the compound (50 mmol) was added with Sub 2 (50 mmol), Pd(dba)2 (3 g, 7 mmol), P(t-Bu)3 (0.7 g, 3.5 mol), and NaOtBu (14.8 g, 150 mmol), followed by reflux-stirring for 24 hours.

After the reaction was completed, the reaction product was extracted with ether and water. The organic layer was dried with MgSO₄ and concentrated. Then, the produced organic layer was purified by silica gel column and recrystallized to give a required compound.

Then, the compound was measured by HRMS [m/z 956.63 (M+)].

Compound (1-3-3-8) Synthesis Method.

Sub 1 synthesis was carried out in the same manner as described in Sub 1 synthesis used in the synthesis method of the compound (1-3-3-1).

Sub 2 Synthesis:

A-8N (200 mmol) and bromodiphenylfluorene (DPF-Br) (79.4 g 200 mmol) were mixed with toluene (1000 mL), and added with Pd(dba)2 (6 g, 14 mmol), P(t-Bu)3 (1.4 g, 7 mol), and NaOtBu (29.6 g, 300 mmol), followed by reflux-stirring for 24 hours. After the reaction was completed, the reaction product was extracted with ether and water. The organic layer was dried with MgSO₄ and concentrated. Then, the produced organic layer was purified by silica gel column and recrystallized to give a required compound.

Sub 1+Sub 2 Synthesis:

Sub 1 (100 mmol) and dibromo diphenyl (156 g, 50 mmol) were mixed with toluene (1000 mL), and added with Pd(dba)2 (3 g, 7 mmol), P(t-Bu)3 (0.7 g, 3.5 mol), and NaOtBu (14.8 g, 150 mmol), followed by reflux-stirring for 24 hours.

After the reaction was completed, the reaction product was extracted with ether and water. The organic layer was dried with MgSO₄ and concentrated. Then, the produced organic layer was purified by silica gel column and recrystallized to give a required compound.

Then, the compound (50 mmol) was added with Sub 2 (50 mmol), Pd(dba)2 (3 g, 7 mmol), P(t-Bu)3 (0.7 g, 3.5 mol), and NaOtBu (14.8 g, 150 mmol), followed by reflux-stirring for 24 hours.

After the reaction was completed, the reaction product was extracted with ether and water. The organic layer was dried with MgSO₄ and concentrated. Then, the produced organic layer was purified by silica gel column and recrystallized to give a required compound.

Then, the compound was measured by HRMS [m/z 956.42 (M+)].

Compound (1-3-4-1) Synthesis Method.

Sub 1 Synthesis:

amino compound (A-3N, amino compound) (200 mmol) and bromo compound (A-4B, 200 mmol) were mixed with toluene (1000 mL), and added with Pd(dba)2 (6 g, 14 mmol), P(t-Bu)3 (1.4 g, 7 mol), and NaOtBu (29.6 g, 300 mmol), followed by reflux-stirring for 24 hours. After the reaction was completed, the reaction product was extracted with ether and water. The organic layer was dried with MgSO₄ and concentrated. Then, the produced organic layer was purified by silica gel column and recrystallized to give a required compound.

Sub 2 Synthesis:

A-1N (200 mmol) and bromodiphenylfluorene (DPF-Br) (79.4 g 200 mmol) were mixed with toluene (1000 mL), and added with Pd(dba)2 (6 g, 14 mmol), P(t-Bu)3 (1.4 g, 7 mol), and NaOtBu (29.6 g, 300 mmol), followed by reflux-stirring for 24 hours. After the reaction was completed, the reaction product was extracted with ether and water. The organic layer was dried with MgSO₄ and concentrated. Then, the produced organic layer was purified by silica gel column and recrystallized to give a required compound.

Sub 1+Sub 2 Synthesis:

Sub 1 (100 mmol) and dibromo diphenyl (156 g, 50 mmol) were mixed with toluene (1000 mL), and added with Pd(dba)2 (3 g, 7 mmol), P(t-Bu)3 (0.7 g, 3.5 mol), and NaOtBu (14.8 g, 150 mmol), followed by reflux-stirring for 24 hours.

After the reaction was completed, the reaction product was extracted with ether and water. The organic layer was dried with MgSO₄ and concentrated. Then, the produced organic layer was purified by silica gel column and recrystallized to give a required compound.

Then, the compound (50 mmol) was added with Sub 2 (50 mmol), Pd(dba)2 (3 g, 7 mmol), P(t-Bu)3 (0.7 g, 3.5 mol), and NaOtBu (14.8 g, 150 mmol), followed by reflux-stirring for 24 hours.

After the reaction was completed, the reaction product was extracted with ether and water. The organic layer was dried with MgSO₄ and concentrated. Then, the produced organic layer was purified by silica gel column and recrystallized to give a required compound.

Then, the compound was measured by HRMS [m/z 856.01 (M+)].

Compound (1-3-4-2) Synthesis Method.

Sub 1 synthesis was carried out in the same manner as described in Sub 1 synthesis used in the synthesis method of the compound (1-3-4-1).

Sub 2 Synthesis:

A-2N (200 mmol) and bromodiphenylfluorene (DPF-Br) (79.4 g 200 mmol) were mixed with toluene (1000 mL), and added with Pd(dba)2 (6 g, 14 mmol), P(t-Bu)3 (1.4 g, 7 mol), and NaOtBu (29.6 g, 300 mmol), followed by reflux-stirring for 24 hours. After the reaction was completed, the reaction product was extracted with ether and water. The organic layer was dried with MgSO₄ and concentrated. Then, the produced organic layer was purified by silica gel column and recrystallized to give a required compound.

Sub 1+Sub 2 Synthesis:

Sub 1 (100 mmol) and dibromo diphenyl (156 g, 50 mmol) were mixed with toluene (1000 mL), and added with Pd(dba)2 (3 g, 7 mmol), P(t-Bu)3 (0.7 g, 3.5 mol), and NaOtBu (14.8 g, 150 mmol), followed by reflux-stirring for 24 hours.

After the reaction was completed, the reaction product was extracted with ether and water. The organic layer was dried with MgSO₄ and concentrated. Then, the produced organic layer was purified by silica gel column and recrystallized to give a required compound.

Then, the compound (50 mmol) was added with Sub 2 (50 mmol), Pd(dba)2 (3 g, 7 mmol), P(t-Bu)3 (0.7 g, 3.5 mol), and NaOtBu (14.8 g, 150 mmol), followed by reflux-stirring for 24 hours.

After the reaction was completed, the reaction product was extracted with ether and water. The organic layer was dried with MgSO₄ and concentrated. Then, the produced organic layer was purified by silica gel column and recrystallized to give a required compound.

Then, the compound was measured by HRMS [m/z 906.42 (M+)].

Compound (1-3-4-3) Synthesis Method.

Sub 1 synthesis was carried out in the same manner as described in Sub 1 synthesis used in the synthesis method of the compound (1-3-4-1).

Sub 2 Synthesis:

A-3N (200 mmol) and bromodiphenylfluorene (DPF-Br) (79.4 g 200 mmol) were mixed with toluene (1000 mL), and added with Pd(dba)2 (6 g, 14 mmol), P(t-Bu)3 (1.4 g, 7 mol), and NaOtBu (29.6 g, 300 mmol), followed by reflux-stirring for 24 hours. After the reaction was completed, the reaction product was extracted with ether and water. The organic layer was dried with MgSO₄ and concentrated. Then, the produced organic layer was purified by silica gel column and recrystallized to give a required compound.

Sub 1+Sub 2 Synthesis:

Sub 1 (100 mmol) and dibromo diphenyl (156 g, 50 mmol) were mixed with toluene (1000 mL), and added with Pd(dba)2 (3 g, 7 mmol), P(t-Bu)3 (0.7 g, 3.5 mol), and NaOtBu (14.8 g, 150 mmol), followed by reflux-stirring for 24 hours.

After the reaction was completed, the reaction product was extracted with ether and water. The organic layer was dried with MgSO₄ and concentrated. Then, the produced organic layer was purified by silica gel column and recrystallized to give a required compound.

Then, the compound (50 mmol) was added with Sub 2 (50 mmol), Pd(dba)2 (3 g, 7 mmol), P(t-Bu)3 (0.7 g, 3.5 mol), and NaOtBu (14.8 g, 150 mmol), followed by reflux-stirring for 24 hours.

After the reaction was completed, the reaction product was extracted with ether and water. The organic layer was dried with MgSO₄ and concentrated. Then, the produced organic layer was purified by silica gel column and recrystallized to give a required compound.

Then, the compound was measured by HRMS [m/z 906.72 (M+)].

Compound (1-3-4-4) Synthesis Method.

Sub 1 synthesis was carried out in the same manner as described in Sub 1 synthesis used in the synthesis method of the compound (1-3-4-1).

Sub 2 Synthesis:

A-4N (200 mmol) and bromodiphenylfluorene (DPF-Br) (79.4 g 200 mmol) were mixed with toluene (1000 mL), and added with Pd(dba)2 (6 g, 14 mmol), P(t-Bu)3 (1.4 g, 7 mol), and NaOtBu (29.6 g, 300 mmol), followed by reflux-stirring for 24 hours. After the reaction was completed, the reaction product was extracted with ether and water. The organic layer was dried with MgSO₄ and concentrated. Then, the produced organic layer was purified by silica gel column and recrystallized to give a required compound.

Sub 1+Sub 2 Synthesis:

Sub 1 (100 mmol) and dibromo diphenyl (156 g, 50 mmol) were mixed with toluene (1000 mL), and added with Pd(dba)2 (3 g, 7 mmol), P(t-Bu)3 (0.7 g, 3.5 mol), and NaOtBu (14.8 g, 150 mmol), followed by reflux-stirring for 24 hours.

After the reaction was completed, the reaction product was extracted with ether and water. The organic layer was dried with MgSO₄ and concentrated. Then, the produced organic layer was purified by silica gel column and recrystallized to give a required compound.

Then, the compound (50 mmol) was added with Sub 2 (50 mmol), Pd(dba)2 (3 g, 7 mmol), P(t-Bu)3 (0.7 g, 3.5 mol), and NaOtBu (14.8 g, 150 mmol), followed by reflux-stirring for 24 hours.

After the reaction was completed, the reaction product was extracted with ether and water. The organic layer was dried with MgSO₄ and concentrated. Then, the produced organic layer was purified by silica gel column and recrystallized to give a required compound.

Then, the compound was measured by HRMS [m/z 932.12 (M+)].

Compound (1-3-4-5) Synthesis Method.

Sub 1 synthesis was carried out in the same manner as described in Sub 1 synthesis used in the synthesis method of the compound (1-3-4-1).

Sub 2 Synthesis:

A-5N (200 mmol) and bromodiphenylfluorene (DPF-Br) (79.4 g 200 mmol) were mixed with toluene (1000 mL), and added with Pd(dba)2 (6 g, 14 mmol), P(t-Bu)3 (1.4 g, 7 mol), and NaOtBu (29.6 g, 300 mmol), followed by reflux-stirring for 24 hours. After the reaction was completed, the reaction product was extracted with ether and water. The organic layer was dried with MgSO₄ and concentrated. Then, the produced organic layer was purified by silica gel column and recrystallized to give a required compound.

Sub 1+Sub 2 Synthesis:

Sub 1 (100 mmol) and dibromo diphenyl (156 g, 50 mmol) were mixed with toluene (1000 mL), and added with Pd(dba)2 (3 g, 7 mmol), P(t-Bu)3 (0.7 g, 3.5 mol), and NaOtBu (14.8 g, 150 mmol), followed by reflux-stirring for 24 hours.

After the reaction was completed, the reaction product was extracted with ether and water. The organic layer was dried with MgSO₄ and concentrated. Then, the produced organic layer was purified by silica gel column and recrystallized to give a required compound.

Then, the compound (50 mmol) was added with Sub 2 (50 mmol), Pd(dba)2 (3 g, 7 mmol), P(t-Bu)3 (0.7 g, 3.5 mol), and NaOtBu (14.8 g, 150 mmol), followed by reflux-stirring for 24 hours.

After the reaction was completed, the reaction product was extracted with ether and water. The organic layer was dried with MgSO₄ and concentrated. Then, the produced organic layer was purified by silica gel column and recrystallized to give a required compound.

Then, the compound was measured by HRMS [m/z 982.16 (M+)].

Compound (1-3-4-6) Synthesis Method.

Sub 1 synthesis was carried out in the same manner as described in Sub 1 synthesis used in the synthesis method of the compound (1-3-4-1).

Sub 2 Synthesis:

A-6N (200 mmol) and bromodiphenylfluorene (DPF-Br) (79.4 g 200 mmol) were mixed with toluene (1000 mL), and added with Pd(dba)2 (6 g, 14 mmol), P(t-Bu)3 (1.4 g, 7 mol), and NaOtBu (29.6 g, 300 mmol), followed by reflux-stirring for 24 hours. After the reaction was completed, the reaction product was extracted with ether and water. The organic layer was dried with MgSO₄ and concentrated. Then, the produced organic layer was purified by silica gel column and recrystallized to give a required compound.

Sub 1+Sub 2 Synthesis:

Sub 1 (100 mmol) and dibromo diphenyl (156 g, 50 mmol) were mixed with toluene (1000 mL), and added with Pd(dba)2 (3 g, 7 mmol), P(t-Bu)3 (0.7 g, 3.5 mol), and NaOtBu (14.8 g, 150 mmol), followed by reflux-stirring for 24 hours.

After the reaction was completed, the reaction product was extracted with ether and water. The organic layer was dried with MgSO₄ and concentrated. Then, the produced organic layer was purified by silica gel column and recrystallized to give a required compound.

Then, the compound (50 mmol) was added with Sub 2 (50 mmol), Pd(dba)2 (3 g, 7 mmol), P(t-Bu)3 (0.7 g, 3.5 mol), and NaOtBu (14.8 g, 150 mmol), followed by reflux-stirring for 24 hours.

After the reaction was completed, the reaction product was extracted with ether and water. The organic layer was dried with MgSO₄ and concentrated. Then, the produced organic layer was purified by silica gel column and recrystallized to give a required compound.

Then, the compound was measured by HRMS [m/z 981.16 (M+)].

Compound (1-3-4-7) Synthesis Method.

Sub 1 synthesis was carried out in the same manner as described in Sub 1 synthesis used in the synthesis method of the compound (1-3-4-1).

Sub 2 Synthesis:

A-7N (200 mmol) and bromodiphenylfluorene (DPF-Br) (79.4 g 200 mmol) were mixed with toluene (1000 mL), and added with Pd(dba)2 (6 g, 14 mmol), P(t-Bu)3 (1.4 g, 7 mol), and NaOtBu (29.6 g, 300 mmol), followed by reflux-stirring for 24 hours. After the reaction was completed, the reaction product was extracted with ether and water. The organic layer was dried with MgSO₄ and concentrated. Then, the produced organic layer was purified by silica gel column and recrystallized to give a required compound.

Sub 1+Sub 2 Synthesis:

Sub 1 (100 mmol) and dibromo diphenyl (156 g, 50 mmol) were mixed with toluene (1000 mL), and added with Pd(dba)2 (3 g, 7 mmol), P(t-Bu)3 (0.7 g, 3.5 mol), and NaOtBu (14.8 g, 150 mmol), followed by reflux-stirring for 24 hours.

After the reaction was completed, the reaction product was extracted with ether and water. The organic layer was dried with MgSO₄ and concentrated. Then, the produced organic layer was purified by silica gel column and recrystallized to give a required compound.

Then, the compound (50 mmol) was added with Sub 2 (50 mmol), Pd(dba)2 (3 g, 7 mmol), P(t-Bu)3 (0.7 g, 3.5 mol), and NaOtBu (14.8 g, 150 mmol), followed by reflux-stirring for 24 hours.

After the reaction was completed, the reaction product was extracted with ether and water. The organic layer was dried with MgSO₄ and concentrated. Then, the produced organic layer was purified by silica gel column and recrystallized to give a required compound.

Then, the compound was measured by HRMS [m/z 982.72 (M+)].

Compound (1-3-4-8) Synthesis Method.

Sub 1 synthesis was carried out in the same manner as described in Sub 1 synthesis used in the synthesis method of the compound (1-3-4-1).

Sub 2 Synthesis:

A-8N (200 mmol) and bromodiphenylfluorene (DPF-Br) (79.4 g 200 mmol) were mixed with toluene (1000 mL), and added with Pd(dba)2 (6 g, 14 mmol), P(t-Bu)3 (1.4 g, 7 mol), and NaOtBu (29.6 g, 300 mmol), followed by reflux-stirring for 24 hours. After the reaction was completed, the reaction product was extracted with ether and water. The organic layer was dried with MgSO₄ and concentrated. Then, the produced organic layer was purified by silica gel column and recrystallized to give a required compound.

Sub 1+Sub 2 Synthesis:

Sub 1 (100 mmol) and dibromo diphenyl (156 g, 50 mmol) were mixed with toluene (1000 mL), and added with Pd(dba)2 (3 g, 7 mmol), P(t-Bu)3 (0.7 g, 3.5 mol), and NaOtBu (14.8 g, 150 mmol), followed by reflux-stirring for 24 hours.

After the reaction was completed, the reaction product was extracted with ether and water. The organic layer was dried with MgSO₄ and concentrated. Then, the produced organic layer was purified by silica gel column and recrystallized to give a required compound.

Then, the compound (50 mmol) was added with Sub 2 (50 mmol), Pd(dba)2 (3 g, 7 mmol), P(t-Bu)3 (0.7 g, 3.5 mol), and NaOtBu (14.8 g, 150 mmol), followed by reflux-stirring for 24 hours.

After the reaction was completed, the reaction product was extracted with ether and water. The organic layer was dried with MgSO₄ and concentrated. Then, the produced organic layer was purified by silica gel column and recrystallized to give a required compound.

Then, the compound was measured by HRMS [m/z 982.56 (M+)].

Compound (1-4-4-1) Synthesis Method.

Sub 1 Synthesis:

amino compound (A-4N, amino compound) (200 mmol) and bromo compound (A-4B, 200 mmol) were mixed with toluene (1000 mL), and added with Pd(dba)2 (6 g, 14 mmol), P(t-Bu)3 (1.4 g, 7 mol), and NaOtBu (29.6 g, 300 mmol), followed by reflux-stirring for 24 hours. After the reaction was completed, the reaction product was extracted with ether and water. The organic layer was dried with MgSO₄ and concentrated. Then, the produced organic layer was purified by silica gel column and recrystallized to give a required compound.

Sub 2 Synthesis:

A-1N (200 mmol) and bromodiphenylfluorene (DPF-Br) (79.4 g 200 mmol) were mixed with toluene (1000 mL), and added with Pd(dba)2 (6 g, 14 mmol), P(t-Bu)3 (1.4 g, 7 mol), and NaOtBu (29.6 g, 300 mmol), followed by reflux-stirring for 24 hours. After the reaction was completed, the reaction product was extracted with ether and water. The organic layer was dried with MgSO₄ and concentrated. Then, the produced organic layer was purified by silica gel column and recrystallized to give a required compound.

Sub 1+Sub 2 Synthesis:

Sub 1 (100 mmol) and dibromo diphenyl (156 g, 50 mmol) were mixed with toluene (1000 mL), and added with Pd(dba)2 (3 g, 7 mmol), P(t-Bu)3 (0.7 g, 3.5 mol), and NaOtBu (14.8 g, 150 mmol), followed by reflux-stirring for 24 hours.

After the reaction was completed, the reaction product was extracted with ether and water. The organic layer was dried with MgSO₄ and concentrated. Then, the produced organic layer was purified by silica gel column and recrystallized to give a required compound.

Then, the compound (50 mmol) was added with Sub 2 (50 mmol), Pd(dba)2 (3 g, 7 mmol), P(t-Bu)3 (0.7 g, 3.5 mol), and NaOtBu (14.8 g, 150 mmol), followed by reflux-stirring for 24 hours.

After the reaction was completed, the reaction product was extracted with ether and water. The organic layer was dried with MgSO₄ and concentrated. Then, the produced organic layer was purified by silica gel column and recrystallized to give a required compound.

Then, the compound was measured by HRMS [m/z 883.05 (M+)].

Compound (1-4-4-2) Synthesis Method.

Sub 1 synthesis was carried out in the same manner as described in Sub 1 synthesis used in the synthesis method of the compound (1-4-4-2).

Sub 2 Synthesis:

A-2N (200 mmol) and bromodiphenylfluorene (DPF-Br) (79.4 g 200 mmol) were mixed with toluene (1000 mL), and added with Pd(dba)2 (6 g, 14 mmol), P(t-Bu)3 (1.4 g, 7 mol), and NaOtBu (29.6 g, 300 mmol), followed by reflux-stirring for 24 hours. After the reaction was completed, the reaction product was extracted with ether and water. The organic layer was dried with MgSO₄ and concentrated. Then, the produced organic layer was purified by silica gel column and recrystallized to give a required compound.

Sub 1+Sub 2 Synthesis:

Sub 1 (100 mmol) and dibromo diphenyl (156 g, 50 mmol) were mixed with toluene (1000 mL), and added with Pd(dba)2 (3 g, 7 mmol), P(t-Bu)3 (0.7 g, 3.5 mol), and NaOtBu (14.8 g, 150 mmol), followed by reflux-stirring for 24 hours.

After the reaction was completed, the reaction product was extracted with ether and water. The organic layer was dried with MgSO₄ and concentrated. Then, the produced organic layer was purified by silica gel column and recrystallized to give a required compound.

Then, the compound (50 mmol) was added with Sub 2 (50 mmol), Pd(dba)2 (3 g, 7 mmol), P(t-Bu)3 (0.7 g, 3.5 mol), and NaOtBu (14.8 g, 150 mmol), followed by reflux-stirring for 24 hours.

After the reaction was completed, the reaction product was extracted with ether and water. The organic layer was dried with MgSO₄ and concentrated. Then, the produced organic layer was purified by silica gel column and recrystallized to give a required compound.

Then, the compound was measured by HRMS [m/z 932.21 (M+)].

Compound (1-4-4-3) Synthesis Method.

Sub 1 synthesis was carried out in the same manner as described in Sub 1 synthesis used in the synthesis method of the compound (1-4-4-1).

Sub 2 Synthesis:

A-3N (200 mmol) and bromodiphenylfluorene (DPF-Br) (79.4 g 200 mmol) were mixed with toluene (1000 mL), and added with Pd(dba)2 (6 g, 14 mmol), P(t-Bu)3 (1.4 g, 7 mol), and NaOtBu (29.6 g, 300 mmol), followed by reflux-stirring for 24 hours. After the reaction was completed, the reaction product was extracted with ether and water. The organic layer was dried with MgSO₄ and concentrated. Then, the produced organic layer was purified by silica gel column and recrystallized to give a required compound.

Sub 1+Sub 2 Synthesis:

Sub 1 (100 mmol) and dibromo diphenyl (156 g, 50 mmol) were mixed with toluene (1000 mL), and added with Pd(dba)2 (3 g, 7 mmol), P(t-Bu)3 (0.7 g, 3.5 mol), and NaOtBu (14.8 g, 150 mmol), followed by reflux-stirring for 24 hours.

After the reaction was completed, the reaction product was extracted with ether and water. The organic layer was dried with MgSO₄ and concentrated. Then, the produced organic layer was purified by silica gel column and recrystallized to give a required compound.

Then, the compound (50 mmol) was added with Sub 2 (50 mmol), Pd(dba)2 (3 g, 7 mmol), P(t-Bu)3 (0.7 g, 3.5 mol), and NaOtBu (14.8 g, 150 mmol), followed by reflux-stirring for 24 hours.

After the reaction was completed, the reaction product was extracted with ether and water. The organic layer was dried with MgSO₄ and concentrated. Then, the produced organic layer was purified by silica gel column and recrystallized to give a required compound.

Then, the compound was measured by HRMS [m/z 932.84 (M+)].

Compound (1-4-4-4) Synthesis Method.

Sub 1 synthesis was carried out in the same manner as described in Sub 1 synthesis used in the synthesis method of the compound (1-4-4-1).

Sub 2 Synthesis:

A-4N (200 mmol) and bromodiphenylfluorene (DPF-Br) (79.4 g 200 mmol) were mixed with toluene (1000 mL), and added with Pd(dba)2 (6 g, 14 mmol), P(t-Bu)3 (1.4 g, 7 mol), and NaOtBu (29.6 g, 300 mmol), followed by reflux-stirring for 24 hours. After the reaction was completed, the reaction product was extracted with ether and water. The organic layer was dried with MgSO₄ and concentrated. Then, the produced organic layer was purified by silica gel column and recrystallized to give a required compound.

Sub 1+Sub 2 Synthesis:

Sub 1 (100 mmol) and dibromo diphenyl (156 g, 50 mmol) were mixed with toluene (1000 mL), and added with Pd(dba)2 (3 g, 7 mmol), P(t-Bu)3 (0.7 g, 3.5 mol), and NaOtBu (14.8 g, 150 mmol), followed by reflux-stirring for 24 hours.

After the reaction was completed, the reaction product was extracted with ether and water. The organic layer was dried with MgSO₄ and concentrated. Then, the produced organic layer was purified by silica gel column and recrystallized to give a required compound.

Then, the compound (50 mmol) was added with Sub 2 (50 mmol), Pd(dba)2 (3 g, 7 mmol), P(t-Bu)3 (0.7 g, 3.5 mol), and NaOtBu (14.8 g, 150 mmol), followed by reflux-stirring for 24 hours.

After the reaction was completed, the reaction product was extracted with ether and water. The organic layer was dried with MgSO₄ and concentrated. Then, the produced organic layer was purified by silica gel column and recrystallized to give a required compound.

Then, the compound was measured by HRMS [m/z 958.22 (M+)].

Compound (1-4-4-5) Synthesis Method.

Sub 1 synthesis was carried out in the same manner as described in Sub 1 synthesis used in the synthesis method of the compound (1-4-4-1).

Sub 2 Synthesis:

A-5N (200 mmol) and bromodiphenylfluorene (DPF-Br) (79.4 g 200 mmol) were mixed with toluene (1000 mL), and added with Pd(dba)2 (6 g, 14 mmol), P(t-Bu)3 (1.4 g, 7 mol), and NaOtBu (29.6 g, 300 mmol), followed by reflux-stirring for 24 hours. After the reaction was completed, the reaction product was extracted with ether and water. The organic layer was dried with MgSO₄ and concentrated. Then, the produced organic layer was purified by silica gel column and recrystallized to give a required compound.

Sub 1+Sub 2 Synthesis:

Sub 1 (100 mmol) and dibromo diphenyl (156 g, 50 mmol) were mixed with toluene (1000 mL), and added with Pd(dba)2 (3 g, 7 mmol), P(t-Bu)3 (0.7 g, 3.5 mol), and NaOtBu (14.8 g, 150 mmol), followed by reflux-stirring for 24 hours.

After the reaction was completed, the reaction product was extracted with ether and water. The organic layer was dried with MgSO₄ and concentrated. Then, the produced organic layer was purified by silica gel column and recrystallized to give a required compound.

Then, the compound (50 mmol) was added with Sub 2 (50 mmol), Pd(dba)2 (3 g, 7 mmol), P(t-Bu)3 (0.7 g, 3.5 mol), and NaOtBu (14.8 g, 150 mmol), followed by reflux-stirring for 24 hours.

After the reaction was completed, the reaction product was extracted with ether and water. The organic layer was dried with MgSO₄ and concentrated. Then, the produced organic layer was purified by silica gel column and recrystallized to give a required compound.

Then, the compound was measured by HRMS [m/z 1009.32 (M+)].

Compound (1-4-4-6) Synthesis Method.

Sub 1 synthesis was carried out in the same manner as described in Sub 1 synthesis used in the synthesis method of the compound (1-4-4-1).

Sub 2 Synthesis:

A-6N (200 mmol) and bromodiphenylfluorene (DPF-Br) (79.4 g 200 mmol) were mixed with toluene (1000 mL), and added with Pd(dba)2 (6 g, 14 mmol), P(t-Bu)3 (1.4 g, 7 mol), and NaOtBu (29.6 g, 300 mmol), followed by reflux-stirring for 24 hours. After the reaction was completed, the reaction product was extracted with ether and water. The organic layer was dried with MgSO₄ and concentrated. Then, the produced organic layer was purified by silica gel column and recrystallized to give a required compound.

Sub 1+Sub 2 Synthesis:

Sub 1 (100 mmol) and dibromo diphenyl (156 g, 50 mmol) were mixed with toluene (1000 mL), and added with Pd(dba)2 (3 g, 7 mmol), P(t-Bu)3 (0.7 g, 3.5 mol), and NaOtBu (14.8 g, 150 mmol), followed by reflux-stirring for 24 hours.

After the reaction was completed, the reaction product was extracted with ether and water. The organic layer was dried with MgSO₄ and concentrated. Then, the produced organic layer was purified by silica gel column and recrystallized to give a required compound.

Then, the compound (50 mmol) was added with Sub 2 (50 mmol), Pd(dba)2 (3 g, 7 mmol), P(t-Bu)3 (0.7 g, 3.5 mol), and NaOtBu (14.8 g, 150 mmol), followed by reflux-stirring for 24 hours.

After the reaction was completed, the reaction product was extracted with ether and water. The organic layer was dried with MgSO₄ and concentrated. Then, the produced organic layer was purified by silica gel column and recrystallized to give a required compound.

Then, the compound was measured by HRMS [m/z 1008.72 (M+)].

Compound (1-4-4-7) Synthesis Method.

Sub 1 synthesis was carried out in the same manner as described in Sub 1 synthesis used in the synthesis method of the compound (1-4-4-1).

Sub 2 Synthesis:

A-7N (200 mmol) and bromodiphenylfluorene (DPF-Br) (79.4 g 200 mmol) were mixed with toluene (1000 mL), and added with Pd(dba)2 (6 g, 14 mmol), P(t-Bu)3 (1.4 g, 7 mol), and NaOtBu (29.6 g, 300 mmol), followed by reflux-stirring for 24 hours. After the reaction was completed, the reaction product was extracted with ether and water. The organic layer was dried with MgSO₄ and concentrated. Then, the produced organic layer was purified by silica gel column and recrystallized to give a required compound.

Sub 1+Sub 2 Synthesis:

Sub 1 (100 mmol) and dibromo diphenyl (156 g, 50 mmol) were mixed with toluene (1000 mL), and added with Pd(dba)2 (3 g, 7 mmol), P(t-Bu)3 (0.7 g, 3.5 mol), and NaOtBu (14.8 g, 150 mmol), followed by reflux-stirring for 24 hours.

After the reaction was completed, the reaction product was extracted with ether and water. The organic layer was dried with MgSO₄ and concentrated. Then, the produced organic layer was purified by silica gel column and recrystallized to give a required compound.

Then, the compound (50 mmol) was added with Sub 2 (50 mmol), Pd(dba)2 (3 g, 7 mmol), P(t-Bu)3 (0.7 g, 3.5 mol), and NaOtBu (14.8 g, 150 mmol), followed by reflux-stirring for 24 hours.

After the reaction was completed, the reaction product was extracted with ether and water. The organic layer was dried with MgSO₄ and concentrated. Then, the produced organic layer was purified by silica gel column and recrystallized to give a required compound.

Then, the compound was measured by HRMS [m/z 1008.99 (M+)].

Compound (1-4-4-8) Synthesis Method.

Sub 1 synthesis was carried out in the same manner as described in Sub 1 synthesis used in the synthesis method of the compound (1-4-4-1).

Sub 2 Synthesis:

A-7N (200 mmol) and bromodiphenylfluorene (DPF-Br) (79.4 g 200 mmol) were mixed with toluene (1000 mL), and added with Pd(dba)2 (6 g, 14 mmol), P(t-Bu)3 (1.4 g, 7 mol), and NaOtBu (29.6 g, 300 mmol), followed by reflux-stirring for 24 hours. After the reaction was completed, the reaction product was extracted with ether and water. The organic layer was dried with MgSO₄ and concentrated. Then, the produced organic layer was purified by silica gel column and recrystallized to give a required compound.

Sub 1+Sub 2 Synthesis:

Sub 1 (100 mmol) and dibromo diphenyl (156 g, 50 mmol) were mixed with toluene (1000 mL), and added with Pd(dba)2 (3 g, 7 mmol), P(t-Bu)3 (0.7 g, 3.5 mol), and NaOtBu (14.8 g, 150 mmol), followed by reflux-stirring for 24 hours.

After the reaction was completed, the reaction product was extracted with ether and water. The organic layer was dried with MgSO₄ and concentrated. Then, the produced organic layer was purified by silica gel column and recrystallized to give a required compound.

Then, the compound (50 mmol) was added with Sub 2 (50 mmol), Pd(dba)2 (3 g, 7 mmol), P(t-Bu)3 (0.7 g, 3.5 mol), and NaOtBu (14.8 g, 150 mmol), followed by reflux-stirring for 24 hours.

After the reaction was completed, the reaction product was extracted with ether and water. The organic layer was dried with MgSO₄ and concentrated. Then, the produced organic layer was purified by silica gel column and recrystallized to give a required compound.

Then, the compound was measured by HRMS [m/z 1007.92 (M+)].

Compounds (2-1-1-1) to (2-4-4-8) were synthesized under the same conditions as those in the compounds (1-1-1-1) to (1-4-4-8), except that instead of bromodiphenyl fluorene, bromo diphenyl spiro fluorene was used.

Compounds (3-1-1-1) to (3-4-4-8) were synthesized under the same conditions as those in the compounds (1-1-1-1) to (1-4-4-8), except that instead of bromodiphenyl fluorene, bromo diphenyl benzo fluorene was used.

Compounds (4-1-1-1) to (4-4-4-8) were synthesized under the same conditions as those in the compounds (1-1-1-1) to (1-4-4-8), except that instead of bromodiphenyl fluorene, bromo diphenyl benzo spiro fluorene was used.

Comparison Test

In order to compare the synthesized compounds in view of heat resistance and device characteristics, diphenyl amine compounds (Comparative Examples 1 and 2) and fluorene compounds (Comparative Examples 3, 4, and 5) were synthesized in the conventionally known method (Solid state Comm. 144, 343, 2007). Then, an organic electro-luminescence element was manufactured through a conventional method by using the synthesized compounds in a light emitting host material or a hole transport layer of a light emitting layer.

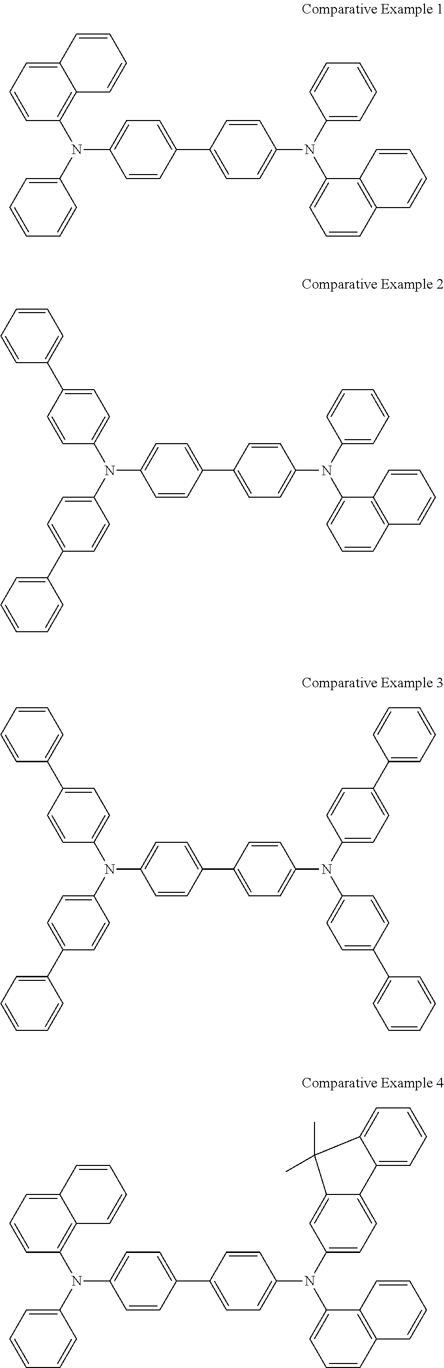 [SMILES: c1ccc(N(c2ccc(-c3ccc(N(c4ccccc4)c4cccc5ccccc45)cc3)cc2)c2cccc3ccccc23)cc1 ; c1ccc(-c2ccc(N(c3ccc(-c4ccccc4)cc3)c3ccc(-c4ccc(N(c5ccccc5)c5cccc6ccccc56)cc4)cc3)cc2)cc1 ; c1ccc(-c2ccc(N(c3ccc(-c4ccccc4)cc3)c3ccc(-c4ccc(N(c5ccc(-c6ccccc6)cc5)c5ccc(-c6ccccc6)cc5)cc4)cc3)cc2)cc1 ; CC1(C)c2ccccc2-c2ccc(N(c3ccc(-c4ccc(N(c5ccccc5)c5cccc6ccccc56)cc4)cc3)c3cccc4ccccc34)cc21]

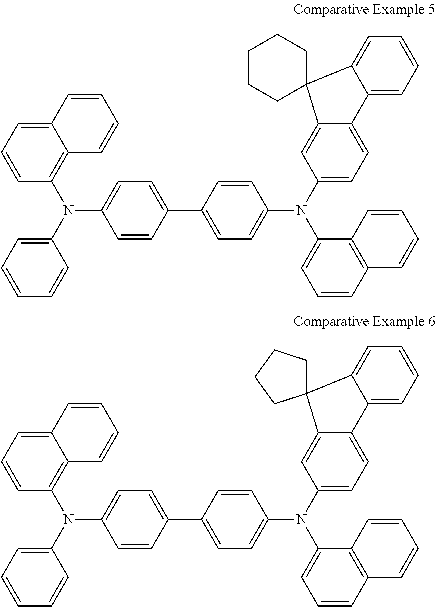 [SMILES: c1ccc(N(c2ccc(-c3ccc(N(c4ccc5c(c4)C4(CCCCC4)c4ccccc4-5)c4cccc5ccccc45)cc3)cc2)c2cccc3ccccc23)cc1 ; c1ccc(N(c2ccc(-c3ccc(N(c4ccc5c(c4)C4(CCCC4)c4ccccc4-5)c4cccc5ccccc45)cc3)cc2)c2cccc3ccccc23)cc1]

First, on an ITO layer (anode) formed on a glass substrate, a copper phthalocyanine (hereinafter, referred to as CuPc) film as a hole injection layer was vacuum-deposited with a thickness of 10 nm. Then, on this film, the compounds according to Examples and Comparative Examples were vacuum-deposited as hole transport layers with a thickness of 20 nm. Then, a comparison test was carried out.

Then, in the comparison test, BD-052X (Idemitsu) was used as a light emitting dopant, and 9,10-di-(naphthalene-2-anthracene)=AND] was used as a host material, and the dopping concentration was fixed at 4%. Then, as an electron injection layer, tris(8-quinolinol)aluminum was film-formed with a thickness of 40 nm. Next, LiF (alkali-metal halide) was deposited with a thickness of 0.2 nm, and Al was deposited with a thickness of 150 nm. The Al/LiF was used as a cathode while the organic electro-luminescence element was fabricated.

The organic electronic elements fabricated according to Examples and Comparative Examples were applied with a forward bias DC voltage while an electro-luminescence (EL) characteristic was measured by PR-650 (photoresearch). As a result, T95 life span was measured by a life span measuring machine (mcscience) at a reference luminance of 1000 cd/m².

According to an embodiment of the present invention, a heat resistance measuring method includes the steps of: measuring an initial purity of a target compound, for example, any one of compounds represented by Formulas 1 to 4 or Tables 1 to 4; leaving the compound at a reference temperature or more for a reference time or more; measuring a purity of the compound; and measuring the difference (decrease) from a specific peak area observed after measurement of the initial purity, to the specific peak area observed after measurement of the purity.

Also, in order to measure the heat resistance of a material, into a 4*1 cm ample (samwoo science), 0.15 g of the material was injected, and then the air was removed through pressure reduction. After the cap portion was sealed, the ample was left in a 400° C. compact muffle furnace (MTI) for 24 hours. Then, the change in purity between before and after the ample was left was measured by HPLC.

TABLE 7

| | Operating | Efficiency | Life | Heat |
|---|---|---|---|---|
| Compound | voltage(V) | (cd/A) | span(time) | resistnace |
| Comp. Example 1 | 6.82 | 5.4 | 120.22 | 1.05% |
| Comp. Example 2 | 6.71 | 5.3 | 132.43 | 1.46% |
| Comp. Example 3 | 7.29 | 6.1 | 133.11 | 1.31% |
| Comp. Example 4 | 4.91 | 6.8 | 145.56 | 17.50% |
| Comp. Example 5 | 5.82 | 3.2 | 76.56 | 22.50% |
| Comp. Example 6 | 5.72 | 3.5 | 51.2 | 26.40% |

Comparative Examples noted in Table 7 showed a reduction of an operating voltage due to a fluorene derivative. However, in the heat resistance test (deformation test), Comparative Example 4 to Comparative Example 6, which have hydrogen at a position adjacent to a fluorene linking group, showed a very low heat resistance.

Meanwhile, as noted in Table 8, the inventive compounds according to Examples were significantly excellent in heat resistance and operating characteristics.

TABLE 8

| | Operating | | | Heat |
|---|---|---|---|---|
| Compound | voltage | Efficiency | Life span | resistance |
| 1-1-1-1 | 5.49 | 6.54 | 220.65 | 1.32% |
| 1-1-1-2 | 5.49 | 6.91 | 247.53 | 1.23% |
| 1-1-1-3 | 4.75 | 6.47 | 243.79 | 1.29% |
| 1-1-1-4 | 5.21 | 6.87 | 247.41 | 1.23% |
| 1-1-1-5 | 4.63 | 6.21 | 263.23 | 1.15% |
| 1-1-1-6 | 4.59 | 6.56 | 247.07 | 1.45% |
| 1-1-1-7 | 5.07 | 6.91 | 261.86 | 1.08% |
| 1-1-1-8 | 4.92 | 6.66 | 233.70 | 1.19% |
| 1-1-2-1 | 4.70 | 6.97 | 254.92 | 1.31% |
| 1-1-2-2 | 4.87 | 6.14 | 275.59 | 1.11% |
| 1-1-2-3 | 5.46 | 6.03 | 242.12 | 1.50% |
| 1-1-2-4 | 4.94 | 6.16 | 245.19 | 1.13% |
| 1-1-2-5 | 5.03 | 6.54 | 232.78 | 1.33% |
| 1-1-2-6 | 4.52 | 6.24 | 243.23 | 1.13% |
| 1-1-2-7 | 4.50 | 6.09 | 275.67 | 1.08% |
| 1-1-2-8 | 4.54 | 6.00 | 224.27 | 1.26% |
| 1-1-3-1 | 4.44 | 6.07 | 237.38 | 1.31% |
| 1-1-3-2 | 4.18 | 6.64 | 251.34 | 1.45% |
| 1-1-3-3 | 4.14 | 6.32 | 260.80 | 1.24% |
| 1-1-3-4 | 4.19 | 6.30 | 240.66 | 1.43% |
| 1-1-3-5 | 4.23 | 6.38 | 221.76 | 1.48% |
| 1-1-3-6 | 4.20 | 6.87 | 244.30 | 1.02% |
| 1-1-3-7 | 4.29 | 6.21 | 263.02 | 1.15% |
| 1-1-3-8 | 4.22 | 6.24 | 244.09 | 1.46% |
| 1-1-4-1 | 4.01 | 6.70 | 238.56 | 1.12% |
| 1-1-4-2 | 4.04 | 6.87 | 278.06 | 1.12% |
| 1-1-4-3 | 4.19 | 6.72 | 225.61 | 1.12% |
| 1-1-4-4 | 4.09 | 6.53 | 223.79 | 1.48% |
| 1-1-4-5 | 4.04 | 6.54 | 243.15 | 1.23% |
| 1-1-4-6 | 4.10 | 6.80 | 269.64 | 1.27% |
| 1-1-4-7 | 4.26 | 6.46 | 240.80 | 1.45% |
| 1-1-4-8 | 4.08 | 6.67 | 232.77 | 1.08% |
| 1-2-2-1 | 3.26 | 6.47 | 227.43 | 1.29% |
| 1-2-2-2 | 3.03 | 6.84 | 231.56 | 1.24% |
| 1-2-2-3 | 3.24 | 6.12 | 266.97 | 1.44% |
| 1-2-2-4 | 3.11 | 6.38 | 261.18 | 1.36% |
| 1-2-2-5 | 3.13 | 6.80 | 240.74 | 1.43% |
| 1-2-2-6 | 3.10 | 6.28 | 220.66 | 1.18% |
| 1-2-2-7 | 3.05 | 6.92 | 231.89 | 1.02% |
| 1-2-2-8 | 3.15 | 6.92 | 242.60 | 1.48% |
| 1-2-3-1 | 3.41 | 6.20 | 257.78 | 1.10% |
| 1-2-3-2 | 3.22 | 6.12 | 259.85 | 1.48% |
| 1-2-3-3 | 3.12 | 6.43 | 269.57 | 1.03% |
| 1-2-3-4 | 3.38 | 6.34 | 272.60 | 1.12% |
| 1-2-3-5 | 3.12 | 6.34 | 227.02 | 1.18% |
| 1-2-3-6 | 3.29 | 6.50 | 239.19 | 1.36% |
| 1-2-3-7 | 3.01 | 6.37 | 252.81 | 1.24% |
| 1-2-3-8 | 3.23 | 6.84 | 250.13 | 1.35% |
| 1-2-4-1 | 3.17 | 6.33 | 233.95 | 1.40% |
| 1-2-4-2 | 3.33 | 6.44 | 255.25 | 1.32% |
| 1-2-4-3 | 3.38 | 6.74 | 262.24 | 1.26% |
| 1-2-4-4 | 3.01 | 6.75 | 277.05 | 1.38% |
| 1-2-4-5 | 3.37 | 6.72 | 245.47 | 1.26% |
| 1-2-4-6 | 3.38 | 6.50 | 247.34 | 1.50% |
| 1-2-4-7 | 3.12 | 6.58 | 239.04 | 1.01% |
| 1-2-4-8 | 3.41 | 6.35 | 222.11 | 1.20% |
| 1-3-3-1 | 3.31 | 6.96 | 255.91 | 1.22% |
| 1-3-3-2 | 3.24 | 6.33 | 255.83 | 1.35% |
| 1-3-3-3 | 3.32 | 6.24 | 255.23 | 1.50% |
| 1-3-3-4 | 3.18 | 6.02 | 269.41 | 1.12% |
| 1-3-3-5 | 3.27 | 6.42 | 228.98 | 1.35% |
| 1-3-3-6 | 3.34 | 6.31 | 254.55 | 1.48% |
| 1-3-3-7 | 3.20 | 6.75 | 246.05 | 1.16% |
| 1-3-3-8 | 3.24 | 6.60 | 245.95 | 1.30% |
| 1-3-4-1 | 3.14 | 6.98 | 253.23 | 1.02% |
| 1-3-4-2 | 3.25 | 6.98 | 248.19 | 1.38% |
| 1-3-4-3 | 3.05 | 6.80 | 259.12 | 1.07% |
| 1-3-4-4 | 3.41 | 6.09 | 251.35 | 1.14% |
| 1-3-4-5 | 3.32 | 6.67 | 222.98 | 1.08% |
| 1-3-4-6 | 3.41 | 6.03 | 275.98 | 1.20% |
| 1-3-4-7 | 3.02 | 6.18 | 220.62 | 1.26% |
| 1-3-4-8 | 3.13 | 6.50 | 276.94 | 1.37% |
| 1-4-4-1 | 3.05 | 6.01 | 236.41 | 1.26% |
| 1-4-4-2 | 3.48 | 6.33 | 238.35 | 1.44% |
| 1-4-4-3 | 3.08 | 6.41 | 259.38 | 1.09% |
| 1-4-4-4 | 3.08 | 6.30 | 234.25 | 1.27% |
| 1-4-4-5 | 3.32 | 6.13 | 258.07 | 1.11% |
| 1-4-4-6 | 3.06 | 6.90 | 272.02 | 1.32% |
| 1-4-4-7 | 3.27 | 6.20 | 256.68 | 1.16% |
| 1-4-4-8 | 3.26 | 6.29 | 260.63 | 1.46% |
| 2-1-1-1 | 4.48 | 6.47 | 242.55 | 1.17% |
| 2-1-1-2 | 4.37 | 6.37 | 226.58 | 1.46% |
| 2-1-1-3 | 4.38 | 6.74 | 230.26 | 1.48% |
| 2-1-1-4 | 4.01 | 6.49 | 230.22 | 1.16% |
| 2-1-1-5 | 4.13 | 6.66 | 257.85 | 1.30% |
| 2-1-1-6 | 4.21 | 6.10 | 247.75 | 1.46% |
| 2-1-1-7 | 4.37 | 6.79 | 273.24 | 1.23% |
| 2-1-1-8 | 4.23 | 6.04 | 227.40 | 1.49% |
| 2-1-2-1 | 4.49 | 6.15 | 248.87 | 1.33% |
| 2-1-2-2 | 4.21 | 6.27 | 232.48 | 1.26% |
| 2-1-2-3 | 4.35 | 6.33 | 250.22 | 1.19% |
| 2-1-2-4 | 4.31 | 6.48 | 277.83 | 1.36% |
| 2-1-2-5 | 4.44 | 6.94 | 263.90 | 1.42% |
| 2-1-2-6 | 4.45 | 6.97 | 221.99 | 1.08% |
| 2-1-2-7 | 4.24 | 6.98 | 243.81 | 1.04% |
| 2-1-2-8 | 4.12 | 6.98 | 254.63 | 1.30% |
| 2-1-3-1 | 4.01 | 6.14 | 255.06 | 1.31% |
| 2-1-3-2 | 4.21 | 6.53 | 235.70 | 1.17% |
| 2-1-3-3 | 4.14 | 6.24 | 271.78 | 1.09% |
| 2-1-3-4 | 4.22 | 6.26 | 245.72 | 1.18% |
| 2-1-3-5 | 4.24 | 6.17 | 246.36 | 1.30% |
| 2-1-3-6 | 4.47 | 6.82 | 277.96 | 1.38% |
| 2-1-3-7 | 4.18 | 6.32 | 231.45 | 1.16% |
| 2-1-3-8 | 4.21 | 6.11 | 277.26 | 1.28% |
| 2-1-4-1 | 4.17 | 6.91 | 257.12 | 1.04% |
| 2-1-4-2 | 4.50 | 6.79 | 250.80 | 1.41% |
| 2-1-4-3 | 4.32 | 6.86 | 226.04 | 1.34% |
| 2-1-4-4 | 4.41 | 6.74 | 274.55 | 1.48% |
| 2-1-4-5 | 4.06 | 6.90 | 238.24 | 1.30% |
| 2-1-4-6 | 4.02 | 6.95 | 232.72 | 1.23% |
| 2-1-4-7 | 4.08 | 6.07 | 272.07 | 1.01% |
| 2-1-4-8 | 4.20 | 6.69 | 243.82 | 1.15% |
| 2-2-2-1 | 3.34 | 6.86 | 243.32 | 1.45% |
| 2-2-2-2 | 3.22 | 6.87 | 241.90 | 1.26% |
| 2-2-2-3 | 3.14 | 6.20 | 246.87 | 1.43% |
| 2-2-2-4 | 3.26 | 6.70 | 247.31 | 1.42% |
| 2-2-2-5 | 3.03 | 6.14 | 279.73 | 1.12% |
| 2-2-2-6 | 3.17 | 6.17 | 248.15 | 1.38% |
| 2-2-2-7 | 3.17 | 6.12 | 255.05 | 1.19% |
| 2-2-2-8 | 3.25 | 6.13 | 245.32 | 1.44% |
| 2-2-3-1 | 3.13 | 6.65 | 256.27 | 1.18% |
| 2-2-3-2 | 3.43 | 6.99 | 271.65 | 1.16% |
| 2-2-3-3 | 3.40 | 6.42 | 226.30 | 1.39% |
| 2-2-3-4 | 3.07 | 6.93 | 266.82 | 1.22% |
| 2-2-3-5 | 3.40 | 6.65 | 277.29 | 1.49% |
| 2-2-3-6 | 3.08 | 6.74 | 276.92 | 1.16% |
| 2-2-3-7 | 3.23 | 6.86 | 271.91 | 1.10% |
| 2-2-3-8 | 3.37 | 6.49 | 245.36 | 1.22% |
| 2-2-4-1 | 3.08 | 6.28 | 241.55 | 1.21% |
| 2-2-4-2 | 3.04 | 6.79 | 243.27 | 1.20% |
| 2-2-4-3 | 3.22 | 6.81 | 238.68 | 1.42% |
| 2-2-4-4 | 3.04 | 6.95 | 276.57 | 1.34% |
| 2-2-4-5 | 3.10 | 6.75 | 276.57 | 1.27% |
| 2-2-4-6 | 3.04 | 6.32 | 257.88 | 1.50% |
| 2-2-4-7 | 3.15 | 6.97 | 244.73 | 1.42% |
| 2-2-4-8 | 3.41 | 6.64 | 244.19 | 1.38% |
| 2-3-3-1 | 3.31 | 6.61 | 225.44 | 1.12% |
| 2-3-3-2 | 3.24 | 6.20 | 274.75 | 1.30% |
| 2-3-3-3 | 3.29 | 6.93 | 248.27 | 1.36% |
| 2-3-3-4 | 3.15 | 6.94 | 225.20 | 1.20% |
| 2-3-3-5 | 3.18 | 6.48 | 242.45 | 1.21% |
| 2-3-3-6 | 3.34 | 6.64 | 270.68 | 1.04% |
| 2-3-3-7 | 3.47 | 6.29 | 220.58 | 1.34% |
| 2-3-3-8 | 3.18 | 6.47 | 223.53 | 1.00% |
| 2-3-4-1 | 3.15 | 6.24 | 225.37 | 1.43% |
| 2-3-4-2 | 3.24 | 6.25 | 223.65 | 1.11% |
| 2-3-4-3 | 3.50 | 6.31 | 269.83 | 1.46% |
| 2-3-4-4 | 3.44 | 6.49 | 230.65 | 1.46% |
| 2-3-4-5 | 3.31 | 6.98 | 224.06 | 1.45% |
| 2-3-4-6 | 3.06 | 6.48 | 237.08 | 1.26% |
| 2-3-4-7 | 3.15 | 6.15 | 238.21 | 1.37% |
| 2-3-4-8 | 3.17 | 6.17 | 256.42 | 1.37% |
| 2-4-4-1 | 3.44 | 6.26 | 244.99 | 1.25% |
| 2-4-4-2 | 3.31 | 6.54 | 254.69 | 1.19% |
| 2-4-4-3 | 3.17 | 6.49 | 264.75 | 1.03% |
| 2-4-4-4 | 3.32 | 6.05 | 278.93 | 1.38% |
| 2-4-4-5 | 3.26 | 6.56 | 257.10 | 1.13% |
| 2-4-4-6 | 3.44 | 6.97 | 255.61 | 1.07% |
| 2-4-4-7 | 3.27 | 6.42 | 277.45 | 1.29% |
| 2-4-4-8 | 3.36 | 6.94 | 247.87 | 1.39% |
| 3-1-1-1 | 4.02 | 6.44 | 228.81 | 1.35% |
| 3-1-1-2 | 4.34 | 6.75 | 240.47 | 1.29% |
| 3-1-1-3 | 4.20 | 6.68 | 260.42 | 1.21% |
| 3-1-1-4 | 4.18 | 6.11 | 229.77 | 1.19% |
| 3-1-1-5 | 4.16 | 6.46 | 257.50 | 1.29% |
| 3-1-1-6 | 4.29 | 6.51 | 221.53 | 1.49% |
| 3-1-1-7 | 4.40 | 6.55 | 240.05 | 1.06% |
| 3-1-1-8 | 4.47 | 6.48 | 270.82 | 1.08% |
| 3-1-2-1 | 4.44 | 6.32 | 225.23 | 1.47% |
| 3-1-2-2 | 4.17 | 6.66 | 242.04 | 1.27% |
| 3-1-2-3 | 4.22 | 6.54 | 222.10 | 1.19% |
| 3-1-2-4 | 4.09 | 6.85 | 266.07 | 1.20% |
| 3-1-2-5 | 4.14 | 6.24 | 239.83 | 1.23% |
| 3-1-2-6 | 4.33 | 6.91 | 258.05 | 1.48% |
| 3-1-2-7 | 4.45 | 6.43 | 249.57 | 1.18% |
| 3-1-2-8 | 4.02 | 6.93 | 271.47 | 1.27% |
| 3-1-3-1 | 4.10 | 6.85 | 240.42 | 1.25% |
| 3-1-3-2 | 4.25 | 6.60 | 274.93 | 1.18% |
| 3-1-3-3 | 4.48 | 6.35 | 239.98 | 1.35% |
| 3-1-3-4 | 4.31 | 6.13 | 224.08 | 1.21% |
| 3-1-3-5 | 4.42 | 6.70 | 250.98 | 1.07% |
| 3-1-3-6 | 4.14 | 6.99 | 233.95 | 1.06% |
| 3-1-3-7 | 4.32 | 6.64 | 279.77 | 1.49% |
| 3-1-3-8 | 4.30 | 6.76 | 255.19 | 1.32% |
| 3-1-4-1 | 4.04 | 6.97 | 249.39 | 1.12% |
| 3-1-4-2 | 4.03 | 6.33 | 261.98 | 1.14% |
| 3-1-4-3 | 4.05 | 6.24 | 264.80 | 1.04% |
| 3-1-4-4 | 4.32 | 6.94 | 256.91 | 1.41% |
| 3-1-4-5 | 4.02 | 6.56 | 251.97 | 1.41% |
| 3-1-4-6 | 4.29 | 6.94 | 239.62 | 1.07% |
| 3-1-4-7 | 4.09 | 6.28 | 266.82 | 1.41% |
| 3-1-4-8 | 4.31 | 7.00 | 243.44 | 1.28% |
| 3-2-2-1 | 3.41 | 6.54 | 225.03 | 1.34% |
| 3-2-2-2 | 3.41 | 6.96 | 250.03 | 1.09% |
| 3-2-2-3 | 3.19 | 6.19 | 278.02 | 1.25% |
| 3-2-2-4 | 3.29 | 6.03 | 245.25 | 1.41% |
| 3-2-2-5 | 3.35 | 6.14 | 230.26 | 1.07% |
| 3-2-2-6 | 3.08 | 6.60 | 257.13 | 1.38% |
| 3-2-2-7 | 3.22 | 6.10 | 251.23 | 1.50% |
| 3-2-2-8 | 3.29 | 6.92 | 256.42 | 1.44% |
| 3-2-3-1 | 3.29 | 6.33 | 245.30 | 1.38% |
| 3-2-3-2 | 3.40 | 6.98 | 224.61 | 1.46% |
| 3-2-3-3 | 3.37 | 6.39 | 255.58 | 1.31% |
| 3-2-3-4 | 3.40 | 6.30 | 263.89 | 1.27% |
| 3-2-3-5 | 3.45 | 6.84 | 230.06 | 1.32% |
| 3-2-3-6 | 3.46 | 6.11 | 261.41 | 1.47% |
| 3-2-3-7 | 3.41 | 6.91 | 237.11 | 1.25% |
| 3-2-3-8 | 3.12 | 6.43 | 244.77 | 1.24% |
| 3-2-4-1 | 3.29 | 6.07 | 262.47 | 1.30% |
| 3-2-4-2 | 3.13 | 6.25 | 226.63 | 1.48% |
| 3-2-4-3 | 3.35 | 6.80 | 259.08 | 1.40% |
| 3-2-4-4 | 3.30 | 6.85 | 248.50 | 1.21% |
| 3-2-4-5 | 3.45 | 6.75 | 276.23 | 1.25% |
| 3-2-4-6 | 3.38 | 6.66 | 238.15 | 1.20% |
| 3-2-4-7 | 3.37 | 6.89 | 260.73 | 1.47% |
| 3-2-4-8 | 3.29 | 6.96 | 259.51 | 1.42% |
| 3-3-3-1 | 3.33 | 6.29 | 270.12 | 1.24% |
| 3-3-3-2 | 3.30 | 6.87 | 230.47 | 1.07% |
| 3-3-3-3 | 3.35 | 6.07 | 233.12 | 1.24% |
| 3-3-3-4 | 3.47 | 6.20 | 228.92 | 1.35% |
| 3-3-3-5 | 3.30 | 6.76 | 267.68 | 1.04% |
| 3-3-3-6 | 3.49 | 6.71 | 220.84 | 1.29% |
| 3-3-3-7 | 3.12 | 6.29 | 263.94 | 1.31% |
| 3-3-3-8 | 3.24 | 6.13 | 241.37 | 1.43% |
| 3-3-4-1 | 3.31 | 6.01 | 251.33 | 1.24% |
| 3-3-4-2 | 3.24 | 6.24 | 231.22 | 1.11% |
| 3-3-4-3 | 3.22 | 6.33 | 240.05 | 1.47% |
| 3-3-4-4 | 3.38 | 6.65 | 220.62 | 1.25% |
| 3-3-4-5 | 3.29 | 6.37 | 257.28 | 1.19% |
| 3-3-4-6 | 3.27 | 6.10 | 224.98 | 1.21% |
| 3-3-4-7 | 3.04 | 6.69 | 244.89 | 1.17% |
| 3-3-4-8 | 3.27 | 6.89 | 223.89 | 1.28% |
| 3-4-4-1 | 3.34 | 6.06 | 221.43 | 1.12% |
| 3-4-4-2 | 3.31 | 6.08 | 271.93 | 1.43% |
| 3-4-4-3 | 3.32 | 6.94 | 259.17 | 1.30% |
| 3-4-4-4 | 3.26 | 6.73 | 253.55 | 1.37% |
| 3-4-4-5 | 3.02 | 6.86 | 248.22 | 1.11% |
| 3-4-4-6 | 3.40 | 6.68 | 243.48 | 1.45% |
| 3-4-4-7 | 3.13 | 6.88 | 273.10 | 1.04% |
| 3-4-4-8 | 3.02 | 6.99 | 277.82 | 1.39% |

| Compound | Formula | R1 | R2 | R3 |
|---|---|---|---|---|
| 4-1-1-1 | 4.45 | 6.76 | 220.71 | 1.27% |
| 4-1-1-2 | 4.33 | 6.83 | 257.83 | 1.12% |
| 4-1-1-3 | 4.05 | 6.91 | 256.18 | 1.19% |
| 4-1-1-4 | 4.04 | 6.13 | 224.34 | 1.06% |
| 4-1-1-5 | 4.43 | 6.57 | 239.30 | 1.09% |
| 4-1-1-6 | 4.40 | 6.79 | 251.10 | 1.11% |
| 4-1-1-7 | 4.26 | 6.23 | 220.31 | 1.38% |
| 4-1-1-8 | 4.38 | 6.40 | 255.83 | 1.16% |
| 4-1-2-1 | 4.36 | 6.97 | 263.33 | 1.38% |
| 4-1-2-2 | 4.45 | 6.78 | 223.98 | 1.43% |
| 4-1-2-3 | 4.29 | 6.15 | 269.22 | 1.14% |
| 4-1-2-4 | 4.17 | 6.28 | 239.65 | 1.05% |
| 4-1-2-5 | 4.25 | 6.47 | 273.17 | 1.36% |
| 4-1-2-6 | 4.18 | 6.42 | 253.25 | 1.30% |
| 4-1-2-7 | 4.38 | 6.84 | 257.65 | 1.32% |
| 4-1-2-8 | 4.00 | 6.46 | 252.41 | 1.22% |
| 4-1-3-1 | 4.13 | 6.80 | 267.06 | 1.36% |
| 4-1-3-2 | 4.17 | 6.06 | 250.58 | 1.33% |
| 4-1-3-3 | 4.31 | 6.02 | 229.73 | 1.26% |
| 4-1-3-4 | 4.44 | 6.08 | 270.59 | 1.18% |
| 4-1-3-5 | 4.44 | 6.52 | 278.57 | 1.04% |
| 4-1-3-6 | 4.38 | 6.36 | 272.31 | 1.44% |
| 4-1-3-7 | 4.46 | 6.14 | 238.69 | 1.20% |
| 4-1-3-8 | 4.05 | 6.75 | 241.93 | 1.40% |
| 4-1-4-1 | 4.48 | 6.35 | 235.68 | 1.02% |
| 4-1-4-2 | 4.25 | 6.62 | 242.03 | 1.18% |
| 4-1-4-3 | 4.32 | 6.32 | 270.91 | 1.19% |
| 4-1-4-4 | 4.18 | 6.43 | 254.11 | 1.42% |
| 4-1-4-5 | 4.12 | 6.47 | 228.19 | 1.21% |
| 4-1-4-6 | 4.49 | 6.31 | 250.37 | 1.26% |
| 4-1-4-7 | 4.34 | 6.13 | 261.87 | 1.08% |
| 4-1-4-8 | 4.49 | 6.12 | 278.41 | 1.22% |
| 4-2-2-1 | 3.12 | 6.22 | 240.10 | 1.12% |
| 4-2-2-2 | 3.24 | 6.24 | 259.25 | 1.35% |
| 4-2-2-3 | 3.40 | 6.83 | 246.11 | 1.06% |
| 4-2-2-4 | 3.18 | 6.11 | 278.37 | 1.43% |
| 4-2-2-5 | 3.30 | 6.35 | 249.96 | 1.10% |
| 4-2-2-6 | 3.44 | 6.87 | 276.57 | 1.13% |
| 4-2-2-7 | 3.12 | 6.85 | 235.46 | 1.37% |
| 4-2-2-8 | 3.22 | 6.52 | 274.54 | 1.16% |
| 4-2-3-1 | 3.42 | 6.17 | 270.30 | 1.34% |
| 4-2-3-2 | 3.46 | 6.17 | 230.37 | 1.08% |
| 4-2-3-3 | 3.39 | 6.82 | 276.59 | 1.29% |
| 4-2-3-4 | 3.01 | 6.48 | 265.92 | 1.15% |
| 4-2-3-5 | 3.10 | 6.06 | 265.12 | 1.30% |
| 4-2-3-6 | 3.44 | 6.40 | 244.38 | 1.08% |
| 4-2-3-7 | 3.04 | 6.09 | 220.43 | 1.37% |
| 4-2-3-8 | 3.24 | 6.14 | 228.22 | 1.44% |
| 4-2-4-1 | 3.31 | 6.97 | 237.20 | 1.06% |
| 4-2-4-2 | 3.49 | 6.95 | 248.68 | 1.42% |
| 4-2-4-3 | 3.14 | 6.83 | 233.16 | 1.22% |
| 4-2-4-4 | 3.02 | 6.76 | 261.40 | 1.18% |
| 4-2-4-5 | 3.07 | 6.91 | 259.71 | 1.18% |
| 4-2-4-6 | 3.01 | 6.27 | 275.00 | 1.37% |
| 4-2-4-7 | 3.01 | 6.69 | 261.40 | 1.38% |
| 4-2-4-8 | 3.49 | 6.36 | 250.88 | 1.15% |
| 4-3-3-1 | 3.27 | 6.80 | 228.57 | 1.40% |
| 4-3-3-2 | 3.04 | 6.13 | 221.57 | 1.03% |
| 4-3-3-3 | 3.45 | 6.96 | 250.43 | 1.29% |
| 4-3-3-4 | 3.41 | 6.66 | 276.85 | 1.39% |
| 4-3-3-5 | 3.45 | 6.09 | 258.37 | 1.27% |
| 4-3-3-6 | 3.45 | 6.99 | 240.65 | 1.33% |
| 4-3-3-7 | 3.17 | 6.14 | 240.11 | 1.45% |
| 4-3-3-8 | 3.33 | 6.86 | 264.86 | 1.01% |
| 4-3-4-1 | 3.16 | 6.91 | 270.70 | 1.28% |
| 4-3-4-2 | 3.46 | 6.80 | 278.17 | 1.45% |
| 4-3-4-3 | 3.36 | 6.03 | 262.47 | 1.19% |
| 4-3-4-4 | 3.30 | 6.24 | 247.11 | 1.17% |
| 4-3-4-5 | 3.35 | 6.76 | 278.38 | 1.18% |
| 4-3-4-6 | 3.35 | 7.00 | 262.90 | 1.46% |
| 4-3-4-7 | 3.12 | 6.73 | 223.90 | 1.49% |
| 4-3-4-8 | 3.31 | 6.31 | 272.16 | 1.09% |
| 4-4-4-1 | 3.47 | 6.39 | 271.99 | 1.08% |
| 4-4-4-2 | 3.34 | 6.10 | 222.65 | 1.16% |
| 4-4-4-3 | 3.49 | 6.53 | 254.82 | 1.37% |
| 4-4-4-4 | 3.35 | 6.04 | 254.17 | 1.43% |
| 4-4-4-5 | 3.21 | 6.21 | 245.57 | 1.15% |
| 4-4-4-6 | 3.07 | 6.88 | 261.76 | 1.48% |
| 4-4-4-7 | 3.48 | 6.66 | 277.06 | 1.06% |
| 4-4-4-8 | 3.23 | 6.35 | 279.71 | 1.42% |

As described above, it was found that compounds (1-1-1-1) to (4-4-4-8) according to Tables 1 to 4 were significantly excellent in heat resistance and operating characteristics as noted in Table 8. Meanwhile, in the compounds (1-1-1-1) to (4-4-4-8) according to Tables 1 to 4, R₁, R₂, and R₃ each, as described above, may be independently substituted with at least one selected from the group including hydrogen, halogen, an amino group, a nitrile group, a nitro group, a C₁˜C₂₀ alkyl group, a C₁˜C₂₀ alkoxy group, a C₁˜C₂₀ alkylamine group, a C₁˜C₂₀ alkylthiophene group, a C₆˜C₂₀ aryl thiophene group, a C₂˜C₂₀ alkenyl group, a C₂˜C₂₀ alkynyl group, a C₃˜C₂₀ cycloalkyl group, a C₆˜C₂₀ aryl group substituted with deuterium, a C₆˜C₂₀ aryl group, a C₈˜C₂₀ arylalkenyl group, a silane group, a boron group, a germanium group, and a C₅˜C₂₀ heterocyclic group, and it was found these compounds showed in actuality the same effects as those in Table 6. Accordingly, test results of Table 8 of these substituted compounds are also included in this specification. For example, in a case where in A-1N of Table 5, one hydrogen in a phenyl group was substituted with a nitro group, the same effect as that of compound (1-1-1-1) was achieved.

In other words, when there is a fluorene substituent, the compounds of Formulas 1 to 4 where there is no hydrogen in the carbon adjacent to fluorene showed a high heat resistance. Accordingly, the compounds (1-1-1-1) to (4-4-4-8) according to Tables 1 to 4, where R₁, R₂, and R₃ each are independently substituted with halogen, an amino group, or the like, showed in actuality the same effect as those in Table 6.

In a case where Examples are compared to Comparative Examples, when a compound has a fluorene substituent, the operating voltage was reduced by 2˜3 V. Also, the compounds of Formulas 1 to 4 where there is no hydrogen in the carbon adjacent to fluorene showed a high heat resistance. Also, they showed a life span of twice or more longer than the compounds of Comparative Examples.

From these characteristics, it can be found that the compounds according to Examples can significantly increase a life span, operating characteristics, and manufacturing efficiency of an organic electronic element.

The above described compound may be used in an organic material layer of an organic electronic element. In other words, the organic electronic element may have a first electrode, one or more organic material layers including the above described compound, and a second electrode which are sequentially layered. Herein, the inventive compounds may be used in at least one of organic material layers of an organic electronic element, for example, a hole injection layer, a hole transport layer, a light emitting layer, an electron transport layer and an electron injection layer. The light emitting layer may include the compound as a light emitting host material. Also, the hole injection layer and/or the hole transport layer may include the compounds.

Meanwhile, the present invention provides a terminal which includes a display device and a control part for driving the display device, the display device including the above described organic electronic element. The terminal means a wired/wireless communication terminal which is currently used or will be used in the future. The above described terminal according to the present invention may be a mobile communication terminal such as a cellular phone, and may include all kinds of terminals such as a PDA, an electronic dictionary, a PMP, a remote control, a navigation unit, a game player, various kinds of TVs, and various kinds of computers.

The organic electronic elements may include, for example, an organic light emitting diode (OLED), an organic solar cell, an organic photo conductor (OPC) drum, an organic transistor (organic TFT), and the like.

When the organic electronic element including a compound represented by Formula 1 to Formula 4 was tested, it was found that it has a high hole mobility, a high heat resistance, and a long life span, and requires a low operating voltage.

Meanwhile, the inventive compound may be used in a soluble process. In other words, through a soluble process of the inventive compound, an organic material layer of an organic electronic element can be formed. In other words, when the compound is used as an organic material layer, the organic material layer may be manufactured with a smaller number of layers by using various polymer materials by means of a soluble process or a solvent process (e.g., spin coating, dip coating, doctor blading, screen printing, inkjet printing or thermal transfer) instead of deposition.

Although a preferred embodiment of the present invention has been described for illustrative purposes, those skilled in the art will appreciate that various modifications, additions and substitutions are possible, without departing from the scope and spirit of the invention as disclosed in the accompanying claims. Therefore, the embodiments disclosed in the present invention are intended to illustrate the scope of the technical idea of the present invention, and the scope of the present invention is not limited by the embodiment. The scope of the present invention shall be construed on the basis of the accompanying claims in such a manner that all of the technical ideas included within the scope equivalent to the claims belong to the present invention.

### CROSS-REFERENCE TO RELATED APPLICATION

This application claims priority from and the benefit under 35 U.S.C. §119(a) of Korean Patent Application No. 10-2011-0013876, filed on Feb. 16, 2011, which is hereby incorporated by reference for all purposes as if fully set forth herein.

1. A compound represented by any one of Formulas below 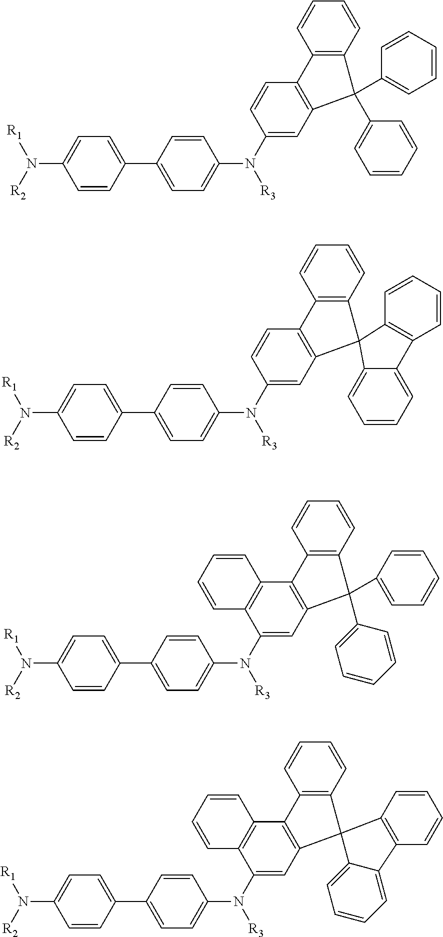
wherein in Formulas, R₁, R₂, and R₃ each are independently
a C₆˜C₂₀ aryl group substituted or unsubstituted with at least one group selected from the group including hydrogen, halogen, an amino group, a nitrile group, a nitro group, a C₁˜C₂₀ alkyl group, a C₁˜C₂₀ alkoxy group, a C₁˜C₂₀ alkylamine group, a C₁˜C₂₀ alkylthiophene group, a C₆˜C₂₀ arylthiophene group, a C₂˜C₂₀ alkenyl group, a C₂˜C₂₀ alkynyl group, a C₃˜C₂₀ cycloalkyl group, a C₆˜C₂₀ aryl group substituted with deuterium, a C₆˜C₂₀ aryl group, a C₈˜C₂₀ arylalkenyl group, a silane group, a boron group, a germanium group, and a C₅˜C₂₀ heterocyclic group; and
a C₆˜C₂₀ aryl thiophene group substituted or unsubstituted with at least one group selected from the group including hydrogen, halogen, an amino group, a nitrile group, a nitro group, a C₁˜C₂₀ alkyl group, a C₁˜C₂₀ alkoxy group, a C₁˜C₂₀ alkylamine group, a C₁˜C₂₀ alkylthiophene group, a C₆˜C₂₀ aryl thiophene group, a C₂˜C₂₀ alkenyl group, a C₂˜C₂₀ alkynyl group, a C₃˜C₂₀ cycloalkyl group, a C₆˜C₂₀ aryl group substituted with deuterium, a C₆˜C₂₀ aryl group, a C₈˜C₂₀ arylalkenyl group, a silane group, a boron group, a germanium group, and a C₅˜C₂₀ heterocyclic group.

2. The compound as claimed in claim 1, wherein in R₁ and R₂, adjacent substituents are combined with each other to form a saturated or unsaturated cycle.

3. The compound as claimed in claim 1, wherein R₁, R₂, and R₃ each are at least one selected from the group including A-1 to A-8 below.

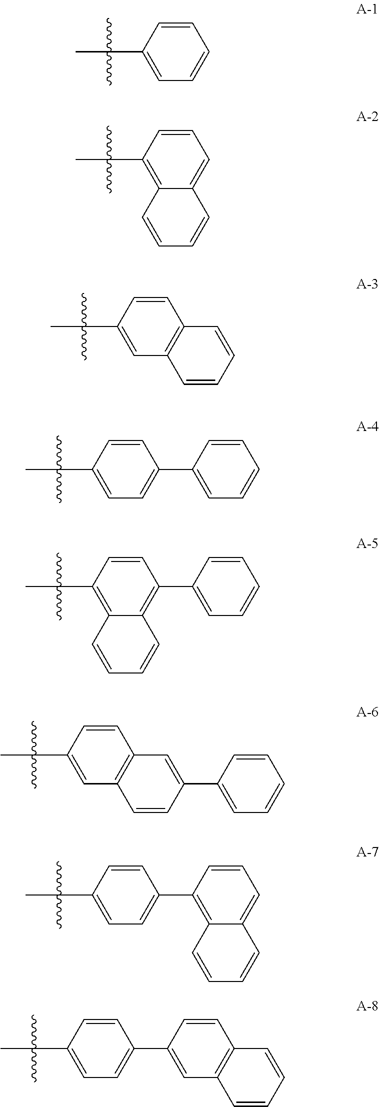

4. The compound as claimed in claim 3, wherein in the compound represented by any one of Formulas 1 to 4, R₁, R₂, and R₃ each are any one of materials noted in Table below.

| Compound | Formula | R1 | R2 | R3 |
|---|---|---|---|---|
| 1-1-1-1 | Formula 1 | A-1 | A-1 | A-1 |
| 1-1-1-2 | Formula 1 | A-1 | A-1 | A-2 |
| 1-1-1-3 | Formula 1 | A-1 | A-1 | A-3 |
| 1-1-1-4 | Formula 1 | A-1 | A-1 | A-4 |
| 1-1-1-5 | Formula 1 | A-1 | A-1 | A-5 |
| 1-1-1-6 | Formula 1 | A-1 | A-1 | A-6 |
| 1-1-1-7 | Formula 1 | A-1 | A-1 | A-7 |
| 1-1-1-8 | Formula 1 | A-1 | A-1 | A-8 |
| 1-1-2-1 | Formula 1 | A-1 | A-2 | A-1 |
| 1-1-2-2 | Formula 1 | A-1 | A-2 | A-2 |
| 1-1-2-3 | Formula 1 | A-1 | A-2 | A-3 |
| 1-1-2-4 | Formula 1 | A-1 | A-2 | A-4 |
| 1-1-2-5 | Formula 1 | A-1 | A-2 | A-5 |
| 1-1-2-6 | Formula 1 | A-1 | A-2 | A-6 |
| 1-1-2-7 | Formula 1 | A-1 | A-2 | A-7 |
| 1-1-2-8 | Formula 1 | A-1 | A-2 | A-8 |
| 1-1-3-1 | Formula 1 | A-1 | A-3 | A-1 |
| 1-1-3-2 | Formula 1 | A-1 | A-3 | A-2 |
| 1-1-3-3 | Formula 1 | A-1 | A-3 | A-3 |
| 1-1-3-4 | Formula 1 | A-1 | A-3 | A-4 |
| 1-1-3-5 | Formula 1 | A-1 | A-3 | A-5 |
| 1-1-3-6 | Formula 1 | A-1 | A-3 | A-6 |
| 1-1-3-7 | Formula 1 | A-1 | A-3 | A-7 |
| 1-1-3-8 | Formula 1 | A-1 | A-3 | A-8 |
| 1-1-4-1 | Formula 1 | A-1 | A-4 | A-1 |
| 1-1-4-2 | Formula 1 | A-1 | A-4 | A-2 |
| 1-1-4-3 | Formula 1 | A-1 | A-4 | A-3 |
| 1-1-4-4 | Formula 1 | A-1 | A-4 | A-4 |
| 1-1-4-5 | Formula 1 | A-1 | A-4 | A-5 |
| 1-1-4-6 | Formula 1 | A-1 | A-4 | A-6 |
| 1-1-4-7 | Formula 1 | A-1 | A-4 | A-7 |
| 1-1-4-8 | Formula 1 | A-1 | A-4 | A-8 |
| 1-2-2-1 | Formula 1 | A-2 | A-2 | A-1 |
| 1-2-2-2 | Formula 1 | A-2 | A-2 | A-2 |
| 1-2-2-3 | Formula 1 | A-2 | A-2 | A-3 |
| 1-2-2-4 | Formula 1 | A-2 | A-2 | A-4 |
| 1-2-2-5 | Formula 1 | A-2 | A-2 | A-5 |
| 1-2-2-6 | Formula 1 | A-2 | A-2 | A-6 |
| 1-2-2-7 | Formula 1 | A-2 | A-2 | A-7 |
| 1-2-2-8 | Formula 1 | A-2 | A-2 | A-8 |
| 1-2-3-1 | Formula 1 | A-2 | A-3 | A-1 |
| 1-2-3-2 | Formula 1 | A-2 | A-3 | A-2 |
| 1-2-3-3 | Formula 1 | A-2 | A-3 | A-3 |
| 1-2-3-4 | Formula 1 | A-2 | A-3 | A-4 |
| 1-2-3-5 | Formula 1 | A-2 | A-3 | A-5 |
| 1-2-3-6 | Formula 1 | A-2 | A-3 | A-6 |
| 1-2-3-7 | Formula 1 | A-2 | A-3 | A-7 |
| 1-2-3-8 | Formula 1 | A-2 | A-3 | A-8 |
| 1-2-4-1 | Formula 1 | A-2 | A-4 | A-1 |
| 1-2-4-2 | Formula 1 | A-2 | A-4 | A-2 |
| 1-2-4-3 | Formula 1 | A-2 | A-4 | A-3 |
| 1-2-4-4 | Formula 1 | A-2 | A-4 | A-4 |
| 1-2-4-5 | Formula 1 | A-2 | A-4 | A-5 |
| 1-2-4-6 | Formula 1 | A-2 | A-4 | A-6 |
| 1-2-4-7 | Formula 1 | A-2 | A-4 | A-7 |
| 1-2-4-8 | Formula 1 | A-2 | A-4 | A-8 |
| 1-3-3-1 | Formula 1 | A-3 | A-3 | A-1 |
| 1-3-3-2 | Formula 1 | A-3 | A-3 | A-2 |
| 1-3-3-3 | Formula 1 | A-3 | A-3 | A-3 |
| 1-3-3-4 | Formula 1 | A-3 | A-3 | A-4 |
| 1-3-3-5 | Formula 1 | A-3 | A-3 | A-5 |
| 1-3-3-6 | Formula 1 | A-3 | A-3 | A-6 |
| 1-3-3-7 | Formula 1 | A-3 | A-3 | A-7 |
| 1-3-3-8 | Formula 1 | A-3 | A-3 | A-8 |
| 1-3-4-1 | Formula 1 | A-3 | A-4 | A-1 |
| 1-3-4-2 | Formula 1 | A-3 | A-4 | A-2 |
| 1-3-4-3 | Formula 1 | A-3 | A-4 | A-3 |
| 1-3-4-4 | Formula 1 | A-3 | A-4 | A-4 |
| 1-3-4-5 | Formula 1 | A-3 | A-4 | A-5 |
| 1-3-4-6 | Formula 1 | A-3 | A-4 | A-6 |
| 1-3-4-7 | Formula 1 | A-3 | A-4 | A-7 |
| 1-4-4-1 | Formula 1 | A-4 | A-4 | A-1 |
| 1-4-4-2 | Formula 1 | A-4 | A-4 | A-2 |
| 1-4-4-3 | Formula 1 | A-4 | A-4 | A-3 |
| 1-4-4-4 | Formula 1 | A-4 | A-4 | A-4 |
| 1-4-4-5 | Formula 1 | A-4 | A-4 | A-5 |
| 1-4-4-6 | Formula 1 | A-4 | A-4 | A-6 |
| 1-4-4-7 | Formula 1 | A-4 | A-4 | A-7 |
| 1-4-4-8 | Formula 1 | A-4 | A-4 | A-8 |
| 2-1-1-1 | Formula 2 | A-1 | A-1 | A-1 |
| 2-1-1-2 | Formula 2 | A-1 | A-1 | A-2 |
| 2-1-1-3 | Formula 2 | A-1 | A-1 | A-3 |
| 2-1-1-4 | Formula 2 | A-1 | A-1 | A-4 |
| 2-1-1-5 | Formula 2 | A-1 | A-1 | A-5 |
| 2-1-1-6 | Formula 2 | A-1 | A-1 | A-6 |
| 2-1-1-7 | Formula 2 | A-1 | A-1 | A-7 |
| 2-1-1-8 | Formula 2 | A-1 | A-1 | A-8 |
| 2-1-2-1 | Formula 2 | A-1 | A-2 | A-1 |
| 2-1-2-2 | Formula 2 | A-1 | A-2 | A-2 |
| 2-1-2-3 | Formula 2 | A-1 | A-2 | A-3 |
| 2-1-2-4 | Formula 2 | A-1 | A-2 | A-4 |
| 2-1-2-5 | Formula 2 | A-1 | A-2 | A-5 |
| 2-1-2-6 | Formula 2 | A-1 | A-2 | A-6 |
| 2-1-2-7 | Formula 2 | A-1 | A-2 | A-7 |
| 2-1-2-8 | Formula 2 | A-1 | A-2 | A-8 |
| 2-1-3-1 | Formula 2 | A-1 | A-3 | A-1 |
| 2-1-3-2 | Formula 2 | A-1 | A-3 | A-2 |
| 2-1-3-3 | Formula 2 | A-1 | A-3 | A-3 |
| 2-1-3-4 | Formula 2 | A-1 | A-3 | A-4 |
| 2-1-3-5 | Formula 2 | A-1 | A-3 | A-5 |
| 2-1-3-6 | Formula 2 | A-1 | A-3 | A-6 |
| 2-1-3-7 | Formula 2 | A-1 | A-3 | A-7 |
| 2-1-3-8 | Formula 2 | A-1 | A-3 | A-8 |
| 2-1-4-1 | Formula 2 | A-1 | A-4 | A-1 |
| 2-1-4-2 | Formula 2 | A-1 | A-4 | A-2 |
| 2-1-4-3 | Formula 2 | A-1 | A-4 | A-3 |
| 2-1-4-4 | Formula 2 | A-1 | A-4 | A-4 |
| 2-1-4-5 | Formula 2 | A-1 | A-4 | A-5 |
| 2-1-4-6 | Formula 2 | A-1 | A-4 | A-6 |
| 2-1-4-7 | Formula 2 | A-1 | A-4 | A-7 |
| 2-1-4-8 | Formula 2 | A-1 | A-4 | A-8 |
| 2-2-2-1 | Formula 2 | A-2 | A-2 | A-1 |
| 2-2-2-2 | Formula 2 | A-2 | A-2 | A-2 |
| 2-2-2-3 | Formula 2 | A-2 | A-2 | A-3 |
| 2-2-2-4 | Formula 2 | A-2 | A-2 | A-4 |
| 2-2-2-5 | Formula 2 | A-2 | A-2 | A-5 |
| 2-2-2-6 | Formula 2 | A-2 | A-2 | A-6 |
| 2-2-2-7 | Formula 2 | A-2 | A-2 | A-7 |
| 2-2-2-8 | Formula 2 | A-2 | A-2 | A-8 |
| 2-2-3-1 | Formula 2 | A-2 | A-3 | A-1 |
| 2-2-3-2 | Formula 2 | A-2 | A-3 | A-2 |
| 2-2-3-3 | Formula 2 | A-2 | A-3 | A-3 |
| 2-2-3-4 | Formula 2 | A-2 | A-3 | A-4 |
| 2-2-3-5 | Formula 2 | A-2 | A-3 | A-5 |
| 2-2-3-6 | Formula 2 | A-2 | A-3 | A-6 |
| 2-2-3-7 | Formula 2 | A-2 | A-3 | A-7 |
| 2-2-3-8 | Formula 2 | A-2 | A-3 | A-8 |
| 2-2-4-1 | Formula 2 | A-2 | A-4 | A-1 |
| 2-2-4-2 | Formula 2 | A-2 | A-4 | A-2 |
| 2-2-4-3 | Formula 2 | A-2 | A-4 | A-3 |
| 2-2-4-4 | Formula 2 | A-2 | A-4 | A-4 |
| 2-2-4-5 | Formula 2 | A-2 | A-4 | A-5 |
| 2-2-4-6 | Formula 2 | A-2 | A-4 | A-6 |
| 2-2-4-7 | Formula 2 | A-2 | A-4 | A-7 |
| 2-2-4-8 | Formula 2 | A-2 | A-4 | A-8 |
| 2-3-3-1 | Formula 2 | A-3 | A-3 | A-1 |
| 2-3-3-2 | Formula 2 | A-3 | A-3 | A-2 |
| 2-3-3-3 | Formula 2 | A-3 | A-3 | A-3 |
| 2-3-3-4 | Formula 2 | A-3 | A-3 | A-4 |
| 2-3-3-5 | Formula 2 | A-3 | A-3 | A-5 |
| 2-3-3-6 | Formula 2 | A-3 | A-3 | A-6 |
| 2-3-3-7 | Formula 2 | A-3 | A-3 | A-7 |
| 2-3-3-8 | Formula 2 | A-3 | A-3 | A-8 |
| 2-3-4-1 | Formula 2 | A-3 | A-4 | A-1 |
| 2-3-4-2 | Formula 2 | A-3 | A-4 | A-2 |
| 2-3-4-3 | Formula 2 | A-3 | A-4 | A-3 |
| 2-3-4-4 | Formula 2 | A-3 | A-4 | A-4 |
| 2-3-4-5 | Formula 2 | A-3 | A-4 | A-5 |
| 2-3-4-6 | Formula 2 | A-3 | A-4 | A-6 |
| 2-3-4-7 | Formula 2 | A-3 | A-4 | A-7 |
| 2-3-4-8 | Formula 2 | A-3 | A-4 | A-8 |
| 2-4-4-1 | Formula 2 | A-4 | A-4 | A-1 |
| 2-4-4-2 | Formula 2 | A-4 | A-4 | A-2 |
| 2-4-4-3 | Formula 2 | A-4 | A-4 | A-3 |
| 2-4-4-4 | Formula 2 | A-4 | A-4 | A-4 |
| 2-4-4-5 | Formula 2 | A-4 | A-4 | A-5 |
| 2-4-4-6 | Formula 2 | A-4 | A-4 | A-6 |
| 2-4-4-7 | Formula 2 | A-4 | A-4 | A-7 |
| 2-4-4-8 | Formula 2 | A-4 | A-4 | A-8 |
| 3-1-1-1 | Formula 3 | A-1 | A-1 | A-1 |
| 3-1-1-2 | Formula 3 | A-1 | A-1 | A-2 |
| 3-1-1-3 | Formula 3 | A-1 | A-1 | A-3 |
| 3-1-1-4 | Formula 3 | A-1 | A-1 | A-4 |
| 3-1-1-5 | Formula 3 | A-1 | A-1 | A-5 |
| 3-1-1-6 | Formula 3 | A-1 | A-1 | A-6 |
| 3-1-1-7 | Formula 3 | A-1 | A-1 | A-7 |
| 3-1-1-8 | Formula 3 | A-1 | A-1 | A-8 |
| 3-1-2-1 | Formula 3 | A-1 | A-2 | A-1 |
| 3-1-2-2 | Formula 3 | A-1 | A-2 | A-2 |
| 3-1-2-3 | Formula 3 | A-1 | A-2 | A-3 |
| 3-1-2-4 | Formula 3 | A-1 | A-2 | A-4 |
| 3-1-2-5 | Formula 3 | A-1 | A-2 | A-5 |
| 3-1-2-6 | Formula 3 | A-1 | A-2 | A-6 |
| 3-1-2-7 | Formula 3 | A-1 | A-2 | A-7 |
| 3-1-2-8 | Formula 3 | A-1 | A-2 | A-8 |
| 3-1-3-1 | Formula 3 | A-1 | A-3 | A-1 |
| 3-1-3-2 | Formula 3 | A-1 | A-3 | A-2 |
| 3-1-3-3 | Formula 3 | A-1 | A-3 | A-3 |
| 3-1-3-4 | Formula 3 | A-1 | A-3 | A-4 |
| 3-1-3-5 | Formula 3 | A-1 | A-3 | A-5 |
| 3-1-3-6 | Formula 3 | A-1 | A-3 | A-6 |
| 3-1-3-7 | Formula 3 | A-1 | A-3 | A-7 |
| 3-1-3-8 | Formula 3 | A-1 | A-3 | A-8 |
| 3-1-4-1 | Formula 3 | A-1 | A-4 | A-1 |
| 3-1-4-2 | Formula 3 | A-1 | A-4 | A-2 |
| 3-1-4-3 | Formula 3 | A-1 | A-4 | A-3 |
| 3-1-4-4 | Formula 2 | A-1 | A-4 | A-4 |
| 3-1-4-5 | Formula 3 | A-1 | A-4 | A-5 |
| 3-1-4-6 | Formula 3 | A-1 | A-4 | A-6 |
| 3-1-4-7 | Formula 3 | A-1 | A-4 | A-7 |
| 3-1-4-8 | Formula 3 | A-1 | A-4 | A-8 |
| 3-2-2-1 | Formula 2 | A-2 | A-2 | A-1 |
| 3-2-2-2 | Formula 2 | A-2 | A-2 | A-2 |
| 3-2-2-3 | Formula 2 | A-2 | A-2 | A-3 |
| 3-2-2-4 | Formula 2 | A-2 | A-2 | A-4 |
| 3-2-2-5 | Formula 2 | A-2 | A-2 | A-5 |
| 3-2-2-6 | Formula 2 | A-2 | A-2 | A-6 |
| 3-2-2-7 | Formula 2 | A-2 | A-2 | A-7 |
| 3-2-2-8 | Formula 2 | A-2 | A-2 | A-8 |
| 3-2-3-1 | Formula 2 | A-2 | A-3 | A-1 |
| 3-2-3-2 | Formula 2 | A-2 | A-3 | A-2 |
| 3-2-3-3 | Formula 2 | A-2 | A-3 | A-3 |
| 3-2-3-4 | Formula 2 | A-2 | A-3 | A-4 |
| 3-2-3-5 | Formula 2 | A-2 | A-3 | A-5 |
| 3-2-3-6 | Formula 2 | A-2 | A-3 | A-6 |
| 3-2-3-7 | Formula 2 | A-2 | A-3 | A-7 |
| 3-2-3-8 | Formula 2 | A-2 | A-3 | A-8 |
| 3-2-4-1 | Formula 2 | A-2 | A-4 | A-1 |
| 3-2-4-2 | Formula 2 | A-2 | A-4 | A-2 |
| 3-2-4-3 | Formula 2 | A-2 | A-4 | A-3 |
| 3-2-4-4 | Formula 2 | A-2 | A-4 | A-4 |
| 3-2-4-5 | Formula 2 | A-2 | A-4 | A-5 |
| 3-2-4-6 | Formula 2 | A-2 | A-4 | A-6 |
| 3-2-4-7 | Formula 2 | A-2 | A-4 | A-7 |
| 3-2-4-8 | Formula 2 | A-2 | A-4 | A-8 |
| 3-3-3-1 | Formula 3 | A-3 | A-3 | A-1 |
| 3-3-3-2 | Formula 3 | A-3 | A-3 | A-2 |
| 3-3-3-3 | Formula 3 | A-3 | A-3 | A-3 |
| 3-3-3-4 | Formula 3 | A-3 | A-3 | A-4 |
| 3-3-3-5 | Formula 3 | A-3 | A-3 | A-5 |
| 3-3-3-6 | Formula 3 | A-3 | A-3 | A-6 |
| 3-3-3-7 | Formula 3 | A-3 | A-3 | A-7 |
| 3-3-3-8 | Formula 3 | A-3 | A-3 | A-8 |
| 3-3-4-1 | Formula 3 | A-3 | A-4 | A-1 |
| 3-3-4-2 | Formula 3 | A-3 | A-4 | A-2 |
| 3-3-4-3 | Formula 3 | A-3 | A-4 | A-3 |
| 3-3-4-4 | Formula 3 | A-3 | A-4 | A-4 |
| 3-3-4-5 | Formula 3 | A-3 | A-4 | A-5 |
| 3-3-4-6 | Formula 3 | A-3 | A-4 | A-6 |
| 3-3-4-7 | Formula 3 | A-3 | A-4 | A-7 |
| 3-3-4-8 | Formula 3 | A-3 | A-4 | A-8 |
| 3-4-4-1 | Formula 2 | A-4 | A-4 | A-1 |
| 3-4-4-2 | Formula 2 | A-4 | A-4 | A-2 |
| 3-4-4-3 | Formula 2 | A-4 | A-4 | A-3 |
| 3-4-4-4 | Formula 2 | A-4 | A-4 | A-4 |
| 3-4-4-5 | Formula 2 | A-4 | A-4 | A-5 |
| 3-4-4-6 | Formula 2 | A-4 | A-4 | A-6 |
| 3-4-4-7 | Formula 2 | A-4 | A-4 | A-7 |
| 3-4-4-8 | Formula 2 | A-4 | A-4 | A-8 |
| 4-1-1-1 | Formula 4 | A-1 | A-1 | A-1 |
| 4-1-1-2 | Formula 4 | A-1 | A-1 | A-2 |
| 4-1-1-3 | Formula 4 | A-1 | A-1 | A-3 |
| 4-1-1-4 | Formula 4 | A-1 | A-1 | A-4 |
| 4-1-1-5 | Formula 4 | A-1 | A-1 | A-5 |
| 4-1-1-6 | Formula 4 | A-1 | A-1 | A-6 |
| 4-1-1-7 | Formula 4 | A-1 | A-1 | A-7 |
| 4-1-1-8 | Formula 4 | A-1 | A-1 | A-8 |
| 4-1-2-1 | Formula 4 | A-1 | A-2 | A-1 |
| 4-1-2-2 | Formula 4 | A-1 | A-2 | A-2 |
| 4-1-2-3 | Formula 4 | A-1 | A-2 | A-3 |
| 4-1-2-4 | Formula 4 | A-1 | A-2 | A-4 |
| 4-1-2-5 | Formula 4 | A-1 | A-2 | A-5 |
| 4-1-2-6 | Formula 4 | A-1 | A-2 | A-6 |
| 4-1-2-7 | Formula 4 | A-1 | A-2 | A-7 |
| 4-1-2-8 | Formula 4 | A-1 | A-2 | A-8 |
| 4-1-3-1 | Formula 4 | A-1 | A-3 | A-1 |
| 4-1-3-2 | Formula 4 | A-1 | A-3 | A-2 |
| 4-1-3-3 | Formula 4 | A-1 | A-3 | A-3 |
| 4-1-3-4 | Formula 4 | A-1 | A-3 | A-4 |
| 4-1-3-5 | Formula 4 | A-1 | A-3 | A-5 |
| 4-1-3-6 | Formula 4 | A-1 | A-3 | A-6 |
| 4-1-3-7 | Formula 4 | A-1 | A-3 | A-7 |
| 4-1-3-8 | Formula 4 | A-1 | A-3 | A-8 |
| 4-1-4-1 | Formula 4 | A-1 | A-4 | A-1 |
| 4-1-4-2 | Formula 4 | A-1 | A-4 | A-2 |
| 4-1-4-3 | Formula 4 | A-1 | A-4 | A-3 |
| 4-1-4-4 | Formula 4 | A-1 | A-4 | A-4 |
| 4-1-4-5 | Formula 4 | A-1 | A-4 | A-5 |
| 4-1-4-6 | Formula 4 | A-1 | A-4 | A-6 |
| 4-1-4-7 | Formula 4 | A-1 | A-4 | A-7 |
| 4-1-4-8 | Formula 4 | A-1 | A-4 | A-8 |
| 4-2-2-1 | Formula 2 | A-2 | A-2 | A-1 |
| 4-2-2-2 | Formula 2 | A-2 | A-2 | A-2 |
| 4-2-2-3 | Formula 2 | A-2 | A-2 | A-3 |
| 4-2-2-4 | Formula 2 | A-2 | A-2 | A-4 |
| 4-2-2-5 | Formula 2 | A-2 | A-2 | A-5 |
| 4-2-2-6 | Formula 2 | A-2 | A-2 | A-6 |
| 4-2-2-7 | Formula 2 | A-2 | A-2 | A-7 |
| 4-2-2-8 | Formula 2 | A-2 | A-2 | A-8 |
| 4-2-3-1 | Formula 2 | A-2 | A-3 | A-1 |
| 4-2-3-2 | Formula 2 | A-2 | A-3 | A-2 |
| 4-2-3-3 | Formula 2 | A-2 | A-3 | A-3 |
| 4-2-3-4 | Formula 2 | A-2 | A-3 | A-4 |
| 4-2-3-5 | Formula 2 | A-2 | A-3 | A-5 |
| 4-2-3-6 | Formula 2 | A-2 | A-3 | A-6 |
| 4-2-3-7 | Formula 2 | A-2 | A-3 | A-7 |
| 4-2-3-8 | Formula 2 | A-2 | A-3 | A-8 |
| 4-2-4-1 | Formula 2 | A-2 | A-4 | A-1 |
| 4-2-4-2 | Formula 2 | A-2 | A-4 | A-2 |
| 4-2-4-3 | Formula 2 | A-2 | A-4 | A-3 |
| 4-2-4-4 | Formula 2 | A-2 | A-4 | A-4 |
| 4-2-4-5 | Formula 2 | A-2 | A-4 | A-5 |
| 4-2-4-6 | Formula 2 | A-2 | A-4 | A-6 |
| 4-2-4-7 | Formula 2 | A-2 | A-4 | A-7 |
| 4-2-4-8 | Formula 2 | A-2 | A-4 | A-8 |
| 4-3-3-1 | Formula 4 | A-3 | A-3 | A-1 |
| 4-3-3-2 | Formula 4 | A-3 | A-3 | A-2 |
| 4-3-3-3 | Formula 4 | A-3 | A-3 | A-3 |
| 4-3-3-4 | Formula 4 | A-3 | A-3 | A-4 |
| 4-3-3-5 | Formula 4 | A-3 | A-3 | A-5 |
| 4-3-3-6 | Formula 4 | A-3 | A-3 | A-6 |
| 4-3-3-7 | Formula 4 | A-3 | A-3 | A-7 |
| 4-3-3-8 | Formula 4 | A-3 | A-3 | A-8 |
| 4-3-4-1 | Formula 4 | A-3 | A-4 | A-1 |
| 4-3-4-2 | Formula 4 | A-3 | A-4 | A-2 |
| 4-3-4-3 | Formula 4 | A-3 | A-4 | A-3 |
| 4-3-4-4 | Formula 4 | A-3 | A-4 | A-4 |
| 4-3-4-5 | Formula 4 | A-3 | A-4 | A-5 |
| 4-3-4-6 | Formula 4 | A-3 | A-4 | A-6 |
| 4-3-4-7 | Formula 4 | A-3 | A-4 | A-7 |
| 4-3-4-8 | Formula 4 | A-3 | A-4 | A-8 |
| 4-4-4-1 | Formula 2 | A-4 | A-4 | A-1 |
| 4-4-4-2 | Formula 2 | A-4 | A-4 | A-2 |
| 4-4-4-3 | Formula 2 | A-4 | A-4 | A-3 |
| 4-4-4-4 | Formula 2 | A-4 | A-4 | A-4 |
| 4-4-4-5 | Formula 2 | A-4 | A-4 | A-5 |
| 4-4-4-6 | Formula 2 | A-4 | A-4 | A-6 |
| 4-4-4-7 | Formula 2 | A-4 | A-4 | A-7 |
| 4-4-4-8 | Formula 2 | A-4 | A-4 | A-8 |

5. The organic electronic element comprising one or more organic material layers comprising the compound as claimed in claim 1.

6. The organic electronic element as claimed in claim 5, wherein the organic electronic element is an organic light emitting element in which a first electrode, said one or more organic material layers, and a second electrode are sequentially layered.

7. The organic electronic element as claimed in claim 5, wherein the organic material layers are formed by a soluble process of the compound.

8. The organic electronic element as claimed in claim 5, wherein the organic material layers comprise any one of a hole injection layer, a hole transport layer, a light emitting layer, an electron transport layer, and an electron injection layer.

9. The organic electronic element as claimed in claim 8, wherein the light emitting layer comprises the compound as a light emitting host material or the hole injection layer and/or the hole transport layer comprise the compound.

10. An electronic device comprising a display device and a control part for driving the display device, the display device comprising the organic electronic element as claimed in claim 9.

11. The electronic device as claimed in claim 10, wherein the organic electronic element is any one of an organic light emitting diode (OLED), an organic solar cell, an organic photo conductor (OPC) drum, and an organic transistor (organic TFT).

12. The organic electronic element comprising one or more organic material layers comprising the compound as claimed in claim 2.

13. The organic electronic element comprising one or more organic material layers comprising the compound as claimed in claim 3.

14. The organic electronic element comprising one or more organic material layers comprising the compound as claimed in claim 4.
